SEQUENCE LISTING (23 sequences)

SEQ ID NO: 1 - protein, 90 aa, Unknown
  Description of Unknown: Silk fibroin polypeptide hydrophobic block sequence
  MISC_FEATURE (1)..(90): This sequence may encompass 5-15 “Gly Ala Gly Ala Gly Ser” repeating units
GAGAGSGAGAGSGAGAGSGAGAGSGAGAGSGAGAGSGAGAGSGAGAGSGAGAGSGAGAGSGAGAGSGAGAGSGAGAGSGAGAGSGAGAGS

SEQ ID NO: 2 - protein, 30 aa, Unknown
  Description of Unknown: Silk fibroin polypeptide hydrophobic block sequence
  MOD_RES (2)..(2): Val, Ile, or Ala
  MOD_RES (4)..(4): Val, Ile, or Ala
  MOD_RES (6)..(6): Val, Ile, or Ala
  MOD_RES (8)..(8): Val, Ile, or Ala
  MOD_RES (10)..(10): Val, Ile, or Ala
  MOD_RES (12)..(12): Val, Ile, or Ala
  MOD_RES (14)..(14): Val, Ile, or Ala
  MOD_RES (16)..(16): Val, Ile, or Ala
  MOD_RES (18)..(18): Val, Ile, or Ala
  MOD_RES (20)..(20): Val, Ile, or Ala
  MOD_RES (22)..(22): Val, Ile, or Ala
  MOD_RES (24)..(24): Val, Ile, or Ala
  MOD_RES (26)..(26): Val, Ile, or Ala
  MOD_RES (28)..(28): Val, Ile, or Ala
  MOD_RES (30)..(30): Val, Ile, or Ala
  MISC_FEATURE (1)..(30): This sequence may encompass 5-15 “Gly Xaa” repeating units, wherein Xaa is Val, Ile or Ala
GXGXGXGXGXGXGXGXGXGXGXGXGXGXGX

SEQ ID NO: 3 - protein, 4 aa, Unknown
  Description of Unknown: Silk fibroin polypeptide hydrophobic block sequence
GAAS

SEQ ID NO: 4 - protein, 15 aa, Unknown
  Description of Unknown: Silk fibroin polypeptide hydrophobic block sequence
  MISC_FEATURE (1)..(2): This region may encompass 1-2 residues
  MISC_FEATURE (3)..(15): This region may encompass 11-13 residues
SSAAAAAAAAAAAAA

SEQ ID NO: 5 - protein, 8 aa, Unknown
  Description of Unknown: Silk fibroin polypeptide hydrophobic block sequence
  MISC_FEATURE (2)..(5): This region may encompass 1-4 residues
  MOD_RES (2)..(5): Any amino acid
  MOD_RES (8)..(8): Any amino acid
GXXXXGGX

SEQ ID NO: 6 - protein, 4 aa, Unknown
  Description of Unknown: Silk fibroin polypeptide hydrophobic block sequence
  MOD_RES (4)..(4): Ala, Ser, Tyr, Arg, Asp, Val, or Trp
GGGX

SEQ ID NO: 7 - protein, 12 aa, Unknown
  Description of Unknown: Silk fibroin polypeptide hydrophobic block sequence
  MISC_FEATURE (1)..(2): This region may encompass 1-2 residues
  MISC_FEATURE (3)..(6): This region may encompass 1-4 residues
  MISC_FEATURE (7)..(8): This region may encompass 1-2 residues
  MISC_FEATURE (9)..(12): This region may encompass 1-4 residues
  MISC_FEATURE (1)..(12): This sequence may encompass 1-2 “(Ser1-2Ala1- 4)” repeating units
SSAAAASSAAAA

SEQ ID NO: 8 - protein, 6 aa, Unknown
  Description of Unknown: Silk fibroin polypeptide hydrophobic block sequence
GLGGLG

SEQ ID NO: 9 - protein, 6 aa, Unknown
  Description of Unknown: Silk fibroin polypeptide hydrophobic block sequence
  MOD_RES (2)..(2): Leu, Ile, Val, or Pro
  MOD_RES (5)..(5): Leu, Ile, Val, or Pro
GXGGXG

SEQ ID NO: 10 - protein, 15 aa, Unknown
  Description of Unknown: Silk fibroin polypeptide hydrophobic block sequence
  MISC_FEATURE (3)..(14): This region may encompass 1-4 “Gly Gly Xaa” repeating units
  MOD_RES (5)..(5): Tyr, Val, Ser, or Ala
  MOD_RES (8)..(8): Tyr, Val, Ser, or Ala
  MOD_RES (11)..(11): Tyr, Val, Ser, or Ala
  MOD_RES (14)..(14): Tyr, Val, Ser, or Ala
GPGGXGGXGGXGGXY

SEQ ID NO: 11 - protein, 5 aa, Unknown
  Description of Unknown: Silk fibroin polypeptide hydrophobic block sequence
GRGGA

SEQ ID NO: 12 - protein, 13 aa, Unknown
  Description of Unknown: Silk fibroin polypeptide hydrophobic block sequence
  MISC_FEATURE (4)..(10): This region may encompass 6-7 residues
GAGAAAAAAAGGA

SEQ ID NO: 13 - protein, 8 aa, Unknown
  Description of Unknown: Silk fibroin polypeptide hydrophobic block sequence
  MOD_RES (3)..(3): Gln, Tyr, Leu, Ala, Ser, or Arg
  MOD_RES (5)..(5): Gln, Tyr, Leu, Ala, Ser, or Arg
  MOD_RES (7)..(8): Gln, Tyr, Leu, Ala, Ser, or Arg
GGXGXGXX

SEQ ID NO: 14 - protein, 16 aa, Unknown
  Description of Unknown: Silk fibroin polypeptide hydrophilic spacer sequence
TGSSGFGPYVNGGYSG

SEQ ID NO: 15 - protein, 8 aa, Unknown
  Description of Unknown: Silk fibroin polypeptide hydrophilic spacer sequence
YEYAWSSE

SEQ ID NO: 16 - protein, 7 aa, Unknown
  Description of Unknown: Silk fibroin polypeptide hydrophilic spacer sequence
SDFGTGS

SEQ ID NO: 17 - protein, 7 aa, Unknown
  Description of Unknown: Silk fibroin polypeptide hydrophilic spacer sequence
RRAGYDR

SEQ ID NO: 18 - protein, 8 aa, Unknown
  Description of Unknown: Silk fibroin polypeptide hydrophilic spacer sequence
EVIVIDDR

SEQ ID NO: 19 - protein, 18 aa, Unknown
  Description of Unknown: Silk fibroin polypeptide hydrophilic spacer sequence
TTIIEDLDITIDGADGPI

SEQ ID NO: 20 - protein, 8 aa, Unknown
  Description of Unknown: Silk fibroin polypeptide hydrophilic spacer sequence
TISEELTI

SEQ ID NO: 21 - skipped

SEQ ID NO: 22 - protein, 5 aa, Unknown
  Description of Unknown: Silk fibroin motif
  MOD_RES (4)..(5): Any amino acid
GPGXX

SEQ ID NO: 23 - protein, 5 aa, Artificial Sequence
  Description of Artificial Sequence: Synthetic peptide
YIGSR

(19) United States
(12) Patent Application Publication
(10) Pub. No.: US 2019/0187331 A1
(43) Pub. Date: Jun. 20, 2019

(54) Patterned Silk Inverse Opal Photonic Crystals with Tunable, Geometrically Defined Structural Color

(71) Applicant: Trustees of Tufts College, Medford, MA (US)

(72) Inventors: Fiorenzo G. Omenetto, Lexington, MA (US); Yu Wang, Medford, MA (US)

(21) Appl. No.: 16/319,466

(22) PCT Filed: Aug. 1, 2017
(86) PCT No.: PCT/US2017/044953

§ 371 Date: Jan. 21, 2019

Related U.S. Application Data
(60) Provisional application No. 62/369,630, filed on Aug. 1, 2016.

(51) Int. Cl. G02B 1/00; C30B 29/58; B33Y 70/00; B29D 11/00; C08H 1/00

(52) U.S. Cl. CPC G02B 1/005; C30B 29/58; B33Y 10/00; B29D 11/0074; C08H 1/00; B33Y 70/00

(57) ABSTRACT

The present disclosure relates to patterned photonic crystals. Provided photonic crystals are large scale silk inverse opals with tunable, geometrically defined structural color. Provided photonic crystals exhibit structural color or a photonic band gap (“PBG”). Provided photonic crystals are is found to be highly sensitive to water vapor and UV irradiation. Provided multicolored photonic macro- or micro-patterns are shown by selectively applying water vapor or UV irradiation through a shadow mask. The present disclosure also provides methods for making and using the same.

### CROSS REFERENCED TO RELATED APPLICATIONS

This international patent application claims the benefit of priority under 35 U.S.C. 119(e) of U.S. provisional patent application No. 62/369,630, filed Aug. 1, 2016, entitled “PATTERNED SILK INVERSE OPAL PHOTONIC CRYSTALS WITH TUNABLE, GEOMETRICALLY DEFINED STRUCTURAL COLOR”, the contents of which is hereby incorporated by reference in its entirety herein.

### GOVERNMENT SUPPORT

This invention was made with government support under grant No. N00014-13-1-0596 awarded by the Office of Naval Research. The government has certain rights in the invention.

### BACKGROUND

Structural proteins from naturally occurring materials have been an inspiring template for material design and synthesis at multiple scales. The ability to control the assembly and conformation of such materials offers the opportunity to define fabrication approaches that recapitulate the dimensional hierarchy and structure-function relationships found in Nature. Silk fibroin, collected from the domesticated Bombyx mori (B. mori) silkworm, has been widely investigated for decades as a biomaterial for biomedical applications because of its biocompatibility and biodegradability. (See Omenetto et al., 329 Science, 528 (2010); see also Scheibel, et al., 55 Biotechnol. Appl. Biochem., 155 (2010)). Recently, silk fibroin has also been shown to be a candidate for optical applications due to its excellent combination of transparency, low surface roughness, nanoscale processability, and mechanical durability. (See Tao et al., 24 Adv. Mater., 2824 (2012). These properties enable a variety of fabrication strategies such as hard-template, soft lithography, nanoimprinting, electron-beam lithography, and inkjet printing to be applicable to silk fibroin to fabricate a range of optical and photonic components, including 3D photonic crystals (see Kim et al., 6 Nat. Photonics, 817 (2012); see also Diao et al., 23 Adv. Funct. Mater., 5373 (2013)); microlens arrays (see Lawrence et al., 9 Biomacromolecules, 1214 (2008); microprism arrays (see Tao et al., 109 Proc. Natl. Acad. Sci. U.S.A., 19584 (2012); one- and two-dimensional diffraction gratings (see Kim et al., 9 Nat. Nanotech., 306 (2014); waveguides (see Parker et al., 21 Adv. Mater., 2411 (2009), high-Q resonators (see Xu et al., 24 Opt. Express, 20825 (2016); and lasers (see Choi et al., 15 Lab Chip, 642 (2015); see also Caixeiro et al., 4 Adv. Opt. Mater., 998 (2016)). Further exploiting the potentials of silk fibroin as an optical material will not only lead to the development of new optical devices, but also preferably interface optics with the biological world.

### SUMMARY

Among other things, the present disclosure provides articles of manufacture, for example, in some embodiments, the present disclosure provides inverse opals. In some embodiments, the present disclosure provides silk inverse opals (SIOs). In some embodiments, the present disclosure provides patterned silk inverse opals.

In some embodiments, silk inverse opal photonic crystals with tunable, geometrically defined structural color. The present disclosure also provides methods of making and using these.

Provided articles are useful, for example, as materials and devices for applications such as optics, electronics, and sensors.

The present disclosure encompasses a recognition that control over structural color in inverse opals is or can be manipulated or tuned. In some embodiments, a wavelength of structural color in an inverse opal can be manipulated or tuned.

In some embodiments, provided articles of manufacture include silk inverse opals that exhibit structural color when exposed to incident electromagnetic radiation. In some embodiments silk inverse opals include nanoscale periodic cavities characterized by their lattice constants. In some embodiments, a lattice constant for at least some of these nanoscale periodic cavities is smaller in at least one dimension following exposure to water vapor or ultra violet radiation. In some embodiments, exhibited structural color of exposed silk inverse opals is blue shifted.

In some embodiments, silk inverse opals provided herein are or comprise amorphous silk fibroin. In some embodiments, silk inverse opals as provided herein are or comprise silk fibroin characterized by a presence of β-sheet formation. In some embodiments, silk inverse opals as provided herein are or comprise degraded silk polypeptide chains.

In some embodiments, silk inverse opals as provided herein include periodic nanoscale cavities. In some embodiments, cavities are spherical in shape. In some embodiments, periodic nanoscale cavities have an average diameter in a range of about 100 nm to about 600 nm. In some embodiments, periodic nanoscale cavities have an average diameter in a range of about 200 nm to about 300 nm. In some embodiments, periodic nanoscale cavities have an average lattice constant in a range of about 100 nm to about 600 nm.

In some embodiments, the present disclosure provides mechanically flexible inverse opals. In some embodiments, provided articles are highly flexible or resistant to cracking. In some embodiments, when mechanically flexible inverse opals are bent they do not crack or do not show macroscale cracks. In some embodiments, when mechanically flexible inverse opals are bent they return to a substantially original shape or configuration. In some embodiments, when mechanically flexible inverse opals return to a substantially original shape or configuration, their exhibited structural colors are the same or substantially the same as before bending. In some embodiments, silk inverse opal materials as provided herein are capable of a bend radius in excess of 90°.

In some embodiments, provided silk inverse opals are biocompatible and biodegradable, bioresorbable, cytocompatible, and able to stabilize biologically labile compounds, such as enzymes as well as other additives, agents, and/or functional moieties.

In some embodiments, the present disclosure provides large scale silk inverse opals. In some embodiments, the present disclosure provides centimeter length scale inverse opals.

In some embodiments, silk inverse opal size is dependent on substrate size. In some embodiments, silk inverse opal size is dependent on a size of its nanoscale periodic cavities. In some embodiments, silk inverse opal size is dependent on template size. In some embodiments a template includes a crystalline lattice of arranged spheres used to form an inverse opal structure.

In some embodiments, silk inverse opals are multi-dimensional. In some embodiments, large structures include multiple layers. In some embodiments, large structures as provided herein include a combination of multiple films or layers. In some embodiments, provided silk inverse opals are colloidally assembled 3D nanostructures.

In some embodiments, for example, large scale colloidal crystal multilayers with controllable number of layers are prepared by layer-by-layer (LbL) scooping transfer of a floating monolayer at a water/air interface. In some embodiments, silk solution is cast or pour onto into a template and allowed to solidify into an amorphous silk film. In some embodiments, silk inverse opals are macro defect-free. In some embodiments, silk inverse opals have a face-centered cubic structure. In some embodiments, silk inverse opals exhibit vertical anisotropic shrinkage in its (111) plane. In some embodiments, articles of manufacture as provided herein show no trace of solvent used in template removal.

In some embodiments, methods of forming an article include preparing a silk fibroin solution, inducing a plurality of spherical units to self-assemble into a lattice having at least one layer, applying the silk fibroin solution to the lattice such that the silk fibroin solution fills voids between the plurality spherical units, drying the silk fibroin solution into a silk film, removing the plurality of spherical units, and exposing the article to water vapor or ultra violet radiation.

In some embodiments, silk inverse opals as provided herein exhibit structural color. In some embodiments, provided silk inverse opals are characterized by a controllable photonic lattice. In some embodiments, provided silk inverse opals are characterized by predefined spectral behavior spanning more than the entire visible range. In some embodiments, provided silk inverse opals are multispectral silk inverse opals. In some embodiments, structural color is controllable or tunable in a range from the ultra violet to the infrared.

In some embodiments, the present disclosure provides methods to control, manipulate, and/or reconfigure protein (e.g. silk) conformation in inverse opal structures. In some embodiments, controlling, manipulating, and/or reconfiguring includes structural changes. In some embodiments, wavelength of an inverse opal can be tuned by changing an inverse opals' geometry. In some embodiments, wavelength of an inverse opal can be tuned by changing an inverse opals' index of refraction.

In some embodiments, structural color or photonic band gap (PBG) is highly sensitive to water vapor and UV irradiation. In some embodiments, silk inverse opal structures that are associated with structural color are sensitive to water vapor and UV irradiation. In some embodiments, spherical shaped cavities shrink or compress to form oblate cavities following an exposure to water vapor or UV radiation.

In some embodiments, a wavelength of an inverse opal can be tuned by changing its geometry. In some embodiments, water and/or moisture affects structural properties of silk. In some embodiments, interaction between silk proteins and water molecules leads to beta-sheet formation when a film is exposed to water vapor. In some embodiments, nanoscale periodic cavities of a silk inverse opal are present in multiple layered articles. In some embodiments, when exposed to water vapor, such articles exhibit uniform anisotropic shrinkage in their cavities. In some embodiments, when SIOs are exposed to water vapor, their structural color is gradually blue-shifted with an increase of water vapor treating time. A color shift is shown to occur in a few seconds.

In some embodiments, wavelength of an inverse opal can be tuned by changing an inverse opals' geometry. In some embodiments, ultra violet radiation affects structural properties of silk. In some embodiments, interaction between silk proteins and ultra violet radiation leads to degradation of silk polypeptide chains. In some embodiments, such chains are reorganized. In some embodiments, when exposed to UV radiation, such articles exhibit non-uniform anisotropic shrinkage in their cavities. In some embodiments, when silk inverse opals are exposed to ultra violet radiation, their structural color is gradually blue-shifted with increasing exposure time.

In some embodiments, exposure times as provided herein are finely tunable so that results of exposure are also tunable. That is, in some embodiments, anisotropic shrinkage and lattice constant are finely tunable. In some embodiments, blue shifting of a wavelength of structural color is finely tunable.

In some embodiments, following exposure, silk in an exposed silk inverse opal is crosslinked. In some embodiment, a change in lattice constant and a resultant blue shift of a silk inverse opal are irreversible.

In some embodiments, methods of generating high-resolution multicolor patterns include selectively applying water vapor or UV irradiation through a shadow mask to silk inverse opals as provided herein. In some embodiments, methods include placing a stencil over a silk film prior to exposing. In some embodiments, a stencil is patterned or comprises a pattern.

In some embodiments, wavelength of an inverse opal can be tuned by changing an inverse opals' index of refraction. In some embodiments, adding a liquid to a silk inverse opal will result in a red-shift in its structural color.

In some embodiments, tuning of colorimetric responses is demonstrated by filling an SIO structure with liquids. In some embodiments, tuning of a colorimetric response in silk inverse opals is demonstrated by filling a SIO structure with liquids having different molecular sizes. In some embodiments, a different liquid in an SIO structure results in different structural color.

In some embodiments, theoretical simulations are paired with experimental results of the spectral responses of SIOs.

### BRIEF DESCRIPTION OF THE DRAWING

The foregoing and other objects, aspects, features, and advantages of the present disclosure will become more apparent and better understood by referring to the following description taken in conjunction with the accompanying figures in which:

FIG. 1 shows a mechanism and fabrication steps for provided patterned silk inverse opals. FIG. 1 at panel (A) shows a schematic of proposed silk fibroin modifications induced by water vapor (WV) and UV light. FIG. 1 at panel B shows a schematic of preparation of large scale patterned silk inverse opals. FIG. 1 at panel B(i) shows monodisperse PS spheres deposited onto a water surface using a hydrophilic substrate. FIG. 1 at panel B(ii) shows PS spheres that self-assemble and form a crystalline monolayer at a water/air interface. FIG. 1 at panel B(iii) shows PS colloidal crystals with controllable layers generated by repeating a scooping transfer of PS monolayer from the water/air interface to the PS sphere-coated substrate. FIG. 1 at panel B(iv) shows an aqueous silk solution obtained from cocoons of the B. mori silkworm. FIG. 1 at panel B(v), shows a silk/PS composite film formed by infiltrating a PS template with silk solution and drying. FIG. 1 at panel B(vi) shows silk inverse opals obtained by immersing a composite film into toluene to dissolve PS spheres. FIG. 1 at panel B(vii) shows patterned silk inverse opals formed by selectively exposing SIO to WV or UV light. The silk inverse opal contracts uniformly anisotropically with WV treatment or non-uniformly anisotropically after UV irradiation.

FIG. 2 shows large scale SIOs. FIG. 2 at panel A shows a surface SEM image of SIOs templated from the colloidal crystals composed of PS spheres with diameter of 210 nm. FIG. 2 at panel B shows a surface SEM image of SIOs templated from the colloidal crystals composed of PS spheres with diameter of 300 nm. FIG. 2 at panel C shows a cross-sectional SEM image of SIOs templated from the colloidal crystals composed of PS spheres with diameter of 210 nm. FIG. 2 at panel D shows a cross-sectional SEM image of SIOs templated from the colloidal crystals composed of PS spheres with diameter of 300 nm. Insets show detailed structure underneath the top air cavities (inset scale bar=200 nm). FIG. 2 at panel E shows photographs of SIOs obtained from the three-layered colloidal crystals formed by 210 nm PS spheres. Image was collected in the direction perpendicular to the SIO film. FIG. 2 at panel F shows photographs of SIOs obtained from the three-layered colloidal crystals formed by 300 nm PS spheres. Image was collected in the direction perpendicular to the SIO film. FIG. 2 at panel G shows measured (left) and simulated (right) reflectance spectra of SIOs Λ=300 nm with different layers. The spectra are normalized such that the maximum value of the five-layer curve is equal to one. FIG. 2 at panel G has the same legend for both spectra. FIG. 2 at panel H shows a 50 μm thick bent SIO film Λ=300 nm showing different structural colors at different parts. FIG. 2 at panel I shows a SIO strip derived from a SIO film Λ=300 nm before (left) and after knotting (right). A contour of a knot is highlighted by lines and arrows.

FIG. 3 shows patterned SIO using water vapor. FIG. 3 at panel A shows photographs of patterned SIOs by water vapor treatment for 1 second (leftmost panel), 2, 3, and 5 seconds (rightmost panel). SIO is exposed to water vapor through a porous shadow mask. FIG. 3 at panel B shows a top-view of optical microscopy images of micropatterned SIOs captured in reflection mode. Water vapor treatment for 1 second (leftmost panel), 2, 3, and 5 seconds (rightmost panel). FIG. 3 at panel C shows cross-sectional images of water vapor treated SIOs. Water vapor treatment for 1 second (leftmost panel), 2, 3, and 5 seconds (rightmost panel). SIOs are uniformly compressed during water vapor treatment. FIG. 3 at panel D shows FTIR spectra of SIOs after water vapor (WV) treatment for different time. Spectrum after water vapor treatment for 1 hour shows a shoulder peak at 1621 cm⁻¹, indicating formation of β-sheet conformation. FIG. 3 at panel E shows measured (top) and simulated (bottom) reflectance spectra of water vapor treated SIOs. Reflectance peaks are gradually blue-shifted with an increase of treating time. FIG. 3 at panel E has the same legend for both spectra. FIG. 3 at panel F shows three different stencil designs used to create a floral pattern on SIO by selectively a exposing part of an SIO to water vapor for different times (left) and a corresponding photograph of a patterned SIO (right).

FIG. 4 shows UV induced color change of SIO. FIG. 4 at panel A shows photographs of SIOs as a function of different duration of UV irradiation. SIOs show different structural colors at varying irradiation times. FIG. 4 at panel B shows measured (top) and simulated (bottom) reflectance spectra collected from UV irradiated SIOs. Reflectance peaks are gradually blue-shifted with an increase of irradiation time. FIG. 4 at panel C shows time dependence of stop-band position shift under UV irradiation. FIG. 4 at panel D shows typical cross-sectional SEM images of SIO after UV irradiation. SIOs shrink unevenly during irradiation. FIG. 4 at panel E shows FTIR spectra of SIO before and after UV irradiation. Amide I bands of all samples are centerd at 1638 cm⁻¹ and absorption peaks of exposed SIO decrease with increasing time of irradiation. FIG. 4 at panel F show shadow masks designed to produce butterfly pattern on SIO by exposing masked SIO to UV for different times (left) and a corresponding photograph of patterned SIO (right).

FIG. 5 shows an optical response of a patterned SIO film to liquids. FIG. 5 at panel A shows photographs of patterned SIO in air. FIG. 5 at panel B shows photographs of patterned SIO in isopropanol. FIG. 5 at panel C shows photographs of patterned SIO in methanol. Variations show clear changes in structural color. FIG. 5 at panel D shows reflectance spectra of native SIOs. FIG. 5 at panel E shows reflectance spectra of water vapor treated SIOs. Reflectance peaks are red-shifted when liquid is deposited on an SIO. Red shifting is increased with a decrease of molecular size of liquid.

FIG. 6 shows a cross-section of a dielectric function distribution as modelled by RCWA for a Λ=302 nm SIO. ABC stacking of fcc crystals along the [111] direction can be clearly seen. In each layer, a sphere was approximated by a stacking of uniform cylinders, in order for the SM method to apply.

FIG. 7 shows a modeled refractive index (n) from a spectroscopic ellipsometry measurement for silk film. Sample was measured after casting with no additional treatment.

FIG. 8 shows a schematic diagram of a morphology change of SIO in the [111] direction after water vapor or UV treatment. Each layer of SIO shows the same CF (h/h₀) after water vapor treatment. An SIO structure is non-uniformly compressed after UV irradiation and each layer shows different CF value. Layer 1, Layer 2, and Layer 3 are defined as top, middle and bottom layers of a three-layered SIO, and a bottom layer contacts with a silk substrate.

FIG. 9 shows crystalline PS nanosphere monolayer array. FIG. 9 at panel A shows a photograph of crystalline PS monolayer at an air/water interface. Colloidal crystals grow over a large scale with assistance of SDS. FIG. 9 at panel B shows SEM images of PS nanosphere monolayer array on a substrate. Nanospheres are stacked in a close-packed hexagon structure and such an arrangement is highly ordered on a large-scale. A diameter of a PS nanosphere is 300 nm.

FIG. 10 shows FTIR spectra of an amorphous silk film, an SIO, and a crystalline SIO. Amide I bands of amorphous silk film and SIO are centerd at 1638 cm⁻¹, indicating a presence of water in the material and a typical random coil conformation of an amorphous protein. After methanol treatment, the spectrum is centerd at 1621 cm⁻¹, indicating β-sheet conformation of cross-linked protein.

FIG. 11 shows measured absolute reflectance spectra of SIOs with different layers. FIG. 11 at panel A shows Λ=210 nm. FIG. 11 at panel B shows Λ=300 nm.

FIG. 12 shows angular dependence of SIOs. FIG. 12 as panel A shows a schematic illustration of SIO viewed at different angles. θ is defined as viewing angle or incident angle. FIG. 12 as panel B shows photographs of SIOs with Λ=210 nm at different viewing angles. FIG. 12 as panel C shows photographs of SIOs with Λ=300 nm at different viewing angles. Different color could be observed with different viewing angles. Color is blue shifted gradually with an increase of viewing angle. FIG. 12 as panel D shows measured reflectance spectra of SIO Λ=300 nm at different incident angles. FIG. 12 as panel E shows angle dependence of stop-band position.

FIG. 13 shows colorless patterns on SIO with initial Λ=300 nm induced by water vapor treatment for 10 seconds.

FIG. 14 shows surface SEM images of SIOs with initial Λ=300 nm treated by water vapor for the denoted time. Arrows indicate center-to-center distance between two neighboring air cavities, which remains unchanged during water vapor treatment, suggesting no lateral shrinkage.

FIG. 15 shows a comparison between theoretical values and experimental results for water vapor treated SIOs. FIG. 15 at panel A shows a comparison between normalized experimental (red) and simulated (blue) reflectance spectra for a Λ=302 nm SIO exposed to water vapor for 0 seconds. FIG. 15 at panel B shows a comparison between normalized experimental (red) and simulated (blue) reflectance spectra for a Λ=302 nm SIO exposed to water vapor for 1 seconds. FIG. 15 at panel C shows a comparison between normalized experimental (red) and simulated (blue) reflectance spectra for a Λ=302 nm SIO exposed to water vapor for 2 seconds. FIG. 15 at panel D shows a comparison between normalized experimental (red) and simulated (blue) reflectance spectra for a Λ=302 nm SIO exposed to water vapor for 3 seconds. FIG. 15 at panel E shows a comparison between normalized experimental (red) and simulated (blue) reflectance spectra for a Λ=302 nm SIO exposed to water vapor for 5 seconds. The theoretical model based on uniform vertical compression of the SIO correctly reproduces the width of the stop band. The theoretical spectra also show further peaks which cannot be found in the experimental plot, this is likely due to scattering by defects and imperfections of the SIO matrix, which scales with the fourth power of the wavelength. FIG. 15 at panel F shows a comparison between calculated CF values from SEM images and theoretical values used for a simulation. Theoretical CFs fit in well with those calculated from SEM images.

FIG. 16 shows reflectance spectra of water vapor treated SIOs (initial Λ=300 nm) with five sphere layers. Reflectance peaks are gradually blue-shifted with an increase of treating time.

FIG. 17 shows a reflectance spectrum change of five-layered SIO with initial Λ=210 nm induced by water vapor. A reflectance peak of water vapor treated SIO is blue-shifted compared to that of initial SIO. (Inset: image of patterned SIO by water vapor).

FIG. 18 shows optical properties of UV irradiated SIOs (initial Λ=300 nm) with five sphere layers. FIG. 18 at panel A shows reflectance spectra of UV treated SIO. Reflectance peaks are gradually blue-shifted with an increase of treating time. FIG. 18 at panel B shows time dependence of stop-band position shift under UV exposure.

FIG. 19 shows surface morphology variation of SIOs with initial Λ=300 nm induced by UV. FIG. 19 at panel A shows surface SEM images of SIOs before and after UV exposure for denoted time. Average diameter of air cavities increases with an increase of exposure time. Arrows in indicate small protrusions around cavities, which fade away with increasing irradiation time. FIG. 19 at panel B shows AFM images of surface of SIOs before and after UV exposure for denoted time. FIG. 19 at panel C shows surface roughness calculated from AFM images increases with increasing exposure time.

FIG. 20 shows a comparison between normalized experimental (red) and simulated (blue) reflectance spectra for a Λ=302 nm SIO on an infinite silk substrate exposed to UV light for different periods of time. The theoretical model based on non-uniform vertical compressions of SIO layers accurately reproduces a width of a stop band.

FIG. 21 shows a comparison between normalized experimental (red) and simulated (blue) reflectance spectra for SIOs on an infinite silk substrate infiltrated with liquids. FIG. 21 at panel A shows native SIOs in air. The lattice constant is Λ=302 nm for the uninfiltrated SIO. FIG. 21 at panel B shows water vapor patterned SIOs in air. The compression factor is 0.76 for patterned SIO in air. FIG. 21 at panel C shows native SIOs in isopropanol. The lattice constant is Λ=307 nm for the SIO in isopropanol. FIG. 21 at panel D shows water vapor patterned SIOs in isopropanol. The compression factor is 0.76 for patterned SIO in isopropanol. FIG. 21 at panel E shows native SIOs in methanol. The lattice constant is Λ=336 nm for the SIO in methanol. FIG. 21 at panel F shows water vapor patterned SIOs in methanol. The compression factor is 0.81 for patterned SIO in methanol. Low peak-to-background ratios for simulated data in liquids are due to weak refractive-index contrast (MC) between silk and liquids. Sharper reflectance peaks for experimental results in liquids are probably due to partial evaporation of liquid, which increases MC and therefore enhances a stop-band.

FIG. 22 shows optical response of five-layered patterned SIO with initial Λ=210 nm in liquids. FIG. 22 at panel A shows a photograph of patterned SIO in air showing structural color changes. FIG. 22 at panel B shows a photograph of patterned SIO in isopropanol showing structural color changes. FIG. 22 at panel C shows a photograph of patterned SIO in methanol showing structural color changes. FIG. 22 at panel D shows a reflectance spectra response of native SIOs. FIG. 22 at panel E shows a reflectance spectra response of water vapor treated SIOs.

### DEFINITIONS

In order for the present disclosure to be more readily understood, certain terms are first defined below. Additional definitions for the following terms and other terms are set forth throughout the specification.

The present specification describes certain inventions relating to so-called “three-dimensional (3D) printing”, which can be distinguished from “two-dimensional (2D) printing” in that, the printed product has significant mass in three dimensions (i.e., has length, width, and height) and/or significant volume. By contrast, 2D printing generates printed products (e.g., droplets, sheets, layers) that, although rigorously three-dimensional in that they exist in three-dimensional space, are characterized in that one dimension is significantly small as compared with the other two. By analogy, those skilled in the art will appreciate that an article with dimensions of a piece of paper could reasonably be considered to be a “2D” article relative to a wooden block (e.g., a 2×4×2 block of wood), which would be considered a “3D” article. Those of ordinary skill will therefore readily appreciate the distinction between 2D printing and 3D printing, as those terms are used herein. In many embodiments, 3D printing is achieved through multiple applications of certain 2D printing technologies, having appropriate components and attributes as described herein.

In this application, unless otherwise clear from context, the term “a” may be understood to mean “at least one.” As used in this application, the term “or” may be understood to mean “and/or.” In this application, the terms “comprising” and “including” may be understood to encompass itemized components or steps whether presented by themselves or together with one or more additional components or steps. Unless otherwise stated, the terms “about” and “approximately” may be understood to permit standard variation as would be understood by those of ordinary skill in the art. Where ranges are provided herein, the endpoints are included. As used in this application, the term “comprise” and variations of the term, such as “comprising” and “comprises,” are not intended to exclude other additives, components, integers or steps.

As used in this application, the terms “about” and “approximately” are used as equivalents. Any numerals used in this application with or without about/approximately are meant to cover any normal fluctuations appreciated by one of ordinary skill in the relevant art. In certain embodiments, the term “approximately” or “about” refers to a range of values that fall within 25%, 20%, 19%, 18%, 17%, 16%, 15%, 14%, 13%, 12%, 11%, 10%, 9%, 8%, 7%, 6%, 5%, 4%, 3%, 2%, 1%, or less in either direction (greater than or less than) of the stated reference value unless otherwise stated or otherwise evident from the context (except where such number would exceed 100% of a possible value).

“Associated”: As used herein, the term “associated” typically refers to two or more entities in physical proximity with one another, either directly or indirectly (e.g., via one or more additional entities that serve as a linking agent), to form a structure that is sufficiently stable so that the entities remain in physical proximity under relevant conditions, e.g., physiological conditions. In some embodiments, associated entities are covalently linked to one another. In some embodiments, associated entities are non-covalently linked. In some embodiments, associated entities are linked to one another by specific non-covalent interactions (i.e., by interactions between interacting ligands that discriminate between their interaction partner and other entities present in the context of use, such as, for example: streptavidin/avidin interactions, antibody/antigen interactions, etc.). Alternatively or additionally, a sufficient number of weaker non-covalent interactions can provide sufficient stability for moieties to remain associated. Exemplary non-covalent interactions include, but are not limited to, affinity interactions, metal coordination, physical adsorption, host-guest interactions, hydrophobic interactions, pi stacking interactions, hydrogen bonding interactions, van der Waals interactions, magnetic interactions, electrostatic interactions, dipole-dipole interactions, etc.

“Biocompatible:” As used herein, the term “biocompatible” is intended to describe any material which does not elicit a substantial detrimental response in vivo.

“Biodegradable”: As used herein, the term “biodegradable” is used to refer to materials that, when introduced into cells, are broken down by cellular machinery (e.g., enzymatic degradation) or by hydrolysis into components that cells can either reuse or dispose of without significant toxic effect(s) on the cells. In certain embodiments, components generated by breakdown of a biodegradable material do not induce inflammation and/or other adverse effects in vivo. In some embodiments, biodegradable materials are enzymatically broken down. Alternatively or additionally, in some embodiments, biodegradable materials are broken down by hydrolysis. In some embodiments, biodegradable polymeric materials break down into their component and/or into fragments thereof (e.g., into monomeric or submonomeric species). In some embodiments, breakdown of biodegradable materials (including, for example, biodegradable polymeric materials) includes hydrolysis of ester bonds. In some embodiments, breakdown of materials (including, for example, biodegradable polymeric materials) includes cleavage of urethane linkages. Exemplary biodegradable polymers include, for example, polymers of hydroxy acids such as lactic acid and glycolic acid, including but not limited to poly(hydroxyl acids), poly(lactic acid)(PLA), poly(glycolic acid)(PGA), poly(lactic-co-glycolic acid)(PLGA), and copolymers with PEG, polyanhydrides, poly(ortho)esters, polyesters, polyurethanes, poly(butyric acid), poly(valeric acid), poly(caprolactone), poly(hydroxyalkanoates, poly(lactide-co-caprolactone), blends and copolymers thereof. Many naturally occurring polymers are also biodegradable, including, for example, proteins such as albumin, collagen, gelatin and prolamines, for example, zein, and polysaccharides such as alginate, cellulose derivatives and polyhydroxyalkanoates, for example, polyhydroxybutyrate blends and copolymers thereof. Those of ordinary skill in the art will appreciate or be able to determine when such polymers are biocompatible and/or biodegradable derivatives thereof (e.g., related to a parent polymer by substantially identical structure that differs only in substitution or addition of particular chemical groups as is known in the art).

“Comparable”: As used herein, the term “comparable”, as used herein, refers to two or more agents, entities, situations, sets of conditions, etc. that may not be identical to one another but that are sufficiently similar to permit comparison therebetween so that conclusions may reasonably be drawn based on differences or similarities observed. Those of ordinary skill in the art will understand, in context, what degree of identity is required in any given circumstance for two or more such agents, entities, situations, sets of conditions, etc. to be considered comparable.

“Conjugated”: As used herein, the terms “conjugated,” “linked,” “attached,” and “associated with,” when used with respect to two or more moieties, means that the moieties are physically associated or connected with one another, either directly or via one or more additional moieties that serves as a linking agent, to form a structure that is sufficiently stable so that the moieties remain physically associated under the conditions in which structure is used. Typically the moieties are attached either by one or more covalent bonds or by a mechanism that involves specific binding. Alternately, a sufficient number of weaker interactions can provide sufficient stability for moieties to remain physically associated.

“Hydrophilic”: As used herein, the term “hydrophilic” and/or “polar” refers to a tendency to mix with, or dissolve easily in, water.

“Hydrophobic”: As used herein, the term “hydrophobic” and/or “non-polar”, refers to a tendency to repel, not combine with, or an inability to dissolve easily in, water.

“Hygroscopic”: As used herein, the term “hygroscopic”

“Hydrolytically degradable”: As used herein, the term “hydrolytically degradable” is used to refer to materials that degrade by hydrolytic cleavage. In some embodiments, hydrolytically degradable materials degrade in water. In some embodiments, hydrolytically degradable materials degrade in water in the absence of any other agents or materials. In some embodiments, hydrolytically degradable materials degrade completely by hydrolytic cleavage, e.g., in water. By contrast, the term “non-hydrolytically degradable” typically refers to materials that do not fully degrade by hydrolytic cleavage and/or in the presence of water (e.g., in the sole presence of water).

As used herein, the term “identity” refers to the overall relatedness between polymeric molecules, e.g., between nucleic acid molecules (e.g., DNA molecules and/or RNA molecules) and/or between polypeptide molecules. In some embodiments, polymeric molecules are considered to be “substantially identical” to one another if their sequences are at least 25%, 30%, 35%, 40%, 45%, 50%, 55%, 60%, 65%, 70%, 75%, 80%, 85%, 90%, 95%, or 99% identical. Calculation of the percent identity of two nucleic acid or polypeptide sequences, for example, can be performed by aligning the two sequences for optimal comparison purposes (e.g., gaps can be introduced in one or both of a first and a second sequences for optimal alignment and non-identical sequences can be disregarded for comparison purposes). In certain embodiments, the length of a sequence aligned for comparison purposes is at least 30%, at least 40%, at least 50%, at least 60%, at least 70%, at least 80%, at least 90%, at least 95%, or substantially 100% of the length of a reference sequence. The nucleotides at corresponding positions are then compared. When a position in the first sequence is occupied by the same residue (e.g., nucleotide or amino acid) as the corresponding position in the second sequence, then the molecules are identical at that position. The percent identity between the two sequences is a function of the number of identical positions shared by the sequences, taking into account the number of gaps, and the length of each gap, which needs to be introduced for optimal alignment of the two sequences. The comparison of sequences and determination of percent identity between two sequences can be accomplished using a mathematical algorithm. For example, the percent identity between two nucleotide sequences can be determined using the algorithm of Meyers and Miller (CABIOS, 1989, 4: 11-17), which has been incorporated into the ALIGN program (version 2.0). In some exemplary embodiments, nucleic acid sequence comparisons made with the ALIGN program use a PAM120 weight residue table, a gap length penalty of 12 and a gap penalty of 4. The percent identity between two nucleotide sequences can, alternatively, be determined using the GAP program in the GCG software package using an NWSgapdna.CMP matrix.

The phrase “non-natural amino acid” refers to an entity having the chemical structure of an amino acid (i.e.:

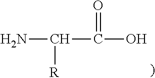

and therefore being capable of participating in at least two peptide bonds, but having an R group that differs from those found in nature. In some embodiments, non-natural amino acids may also have a second R group rather than a hydrogen, and/or may have one or more other substitutions on the amino or carboxylic acid moieties.

“Nucleic acid”: As used herein, the term “nucleic acid” as used herein, refers to a polymer of nucleotides. In some embodiments, a nucleic acid agent can be or comprise deoxyribonucleic acid (DNA), ribonucleic acid (RNA), peptide nucleic acid (PNA), morpholino nucleic acid, locked nucleic acid (LNA), glycol nucleic acid (GNA) and/or threose nucleic acid (TNA). In some embodiments, nucleic acid agents are or contain DNA; in some embodiments, nucleic acid agents are or contain RNA. In some embodiments, nucleic acid agents include naturally-occurring nucleotides (e.g., adenosine, thymidine, guanosine, cytidine, uridine, deoxyadenosine, deoxythymidine, deoxyguanosine, and deoxycytidine). Alternatively or additionally, in some embodiments, nucleic acid agents include non-naturally-occurring nucleotides including, but not limited to, nucleoside analogs (e.g., 2-aminoadenosine, 2-thiothymidine, inosine, pyrrolo-pyrimidine, 3-methyl adenosine, C5-propynylcytidine, C5-propynyluridine, C5-bromouridine, C5-fluorouridine, C5-iodouridine, C5-methylcytidine, 7-deazaadenosine, 7-deazaguanosine, 8-oxoadenosine, 8-oxoguanosine, O(6)-methylguanine, and 2-thiocytidine), chemically modified bases, biologically modified bases (e.g., methylated bases), intercalated bases, modified sugars (e.g., 2′-fluororibose, ribose, 2′-deoxyribose, arabinose, and hexose), or modified phosphate groups. In some embodiments, nucleic acid agents include phosphodiester backbone linkages; alternatively or additionally, in some embodiments, nucleic acid agents include one or more non-phosphodiester backbone linkages such as, for example, phosphorothioates and 5′-N-phosphoramidite linkages. In some embodiments, a nucleic acid agent is an oligonucleotide in that it is relatively short (e.g., less that about 5000, 4000, 3000, 2000, 1000, 900, 800, 700, 600, 500, 450, 400, 350, 300, 250, 200, 150, 100, 90, 80, 70, 60, 50, 45, 40, 35, 30, 25, 20, 15, 10 or fewer nucleotides in length).

“Physiological conditions”: As used herein, the phrase “physiological conditions” relates to the range of chemical (e.g., pH, ionic strength) and biochemical (e.g., enzyme concentrations) conditions likely to be encountered in the intracellular and extracellular fluids of tissues. For most tissues, the physiological pH ranges from about 6.8 to about 8.0 and a temperature range of about 20-40 degrees Celsius, about 25-40 degrees Celsius, about 30-40 degrees Celsius, about 35-40 degrees Celsius, about 37 degrees Celsius, atmospheric pressure of about 1. In some embodiments, physiological conditions utilize or include an aqueous environment (e.g., water, saline, Ringers solution, or other buffered solution); in some such embodiments, the aqueous environment is or comprises a phosphate buffered solution (e.g., phosphate-buffered saline).

The term “polypeptide”, as used herein, generally has its art-recognized meaning of a polymer of at least three amino acids, linked to one another by peptide bonds. In some embodiments, the term is used to refer to specific functional classes of polypeptides. For each such class, the present specification provides several examples of amino acid sequences of known exemplary polypeptides within the class; in some embodiments, such known polypeptides are reference polypeptides for the class. In such embodiments, the term “polypeptide” refers to any member of the class that shows significant sequence homology or identity with a relevant reference polypeptide. In many embodiments, such member also shares significant activity with the reference polypeptide. Alternatively or additionally, in many embodiments, such member also shares a particular characteristic sequence element with the reference polypeptide (and/or with other polypeptides within the class; in some embodiments with all polypeptides within the class). For example, in some embodiments, a member polypeptide shows an overall degree of sequence homology or identity with a reference polypeptide that is at least about 30-40%, and is often greater than about 50%, 60%, 70%, 80%, 90%, 91%, 92%, 93%, 94%, 95%, 96%, 97%, 98%, 99% or more and/or includes at least one region (i.e., a conserved region that may in some embodiments may be or comprise a characteristic sequence element) that shows very high sequence identity, often greater than 90% or even 95%, 96%, 97%, 98%, or 99%. Such a conserved region usually encompasses at least 3-4 and often up to 20 or more amino acids; in some embodiments, a conserved region encompasses at least one stretch of at least 2, 3, 4, 5, 6, 7, 8, 9, 10, 11, 12, 13, 14, 15 or more contiguous amino acids. In some embodiments, a useful polypeptide may comprise or consist of a fragment of a parent polypeptide. In some embodiments, a useful polypeptide as may comprise or consist of a plurality of fragments, each of which is found in the same parent polypeptide in a different spatial arrangement relative to one another than is found in the polypeptide of interest (e.g., fragments that are directly linked in the parent may be spatially separated in the polypeptide of interest or vice versa, and/or fragments may be present in a different order in the polypeptide of interest than in the parent), so that the polypeptide of interest is a derivative of its parent polypeptide. In some embodiments, a polypeptide may comprise natural amino acids, non-natural amino acids, or both. In some embodiments, a polypeptide may comprise only natural amino acids or only non-natural amino acids. In some embodiments, a polypeptide may comprise D-amino acids, L-amino acids, or both. In some embodiments, a polypeptide may comprise only D-amino acids. In some embodiments, a polypeptide may comprise only L-amino acids. In some embodiments, a polypeptide may include one or more pendant groups, e.g., modifying or attached to one or more amino acid side chains, and/or at the polypeptide's N-terminus, the polypeptide's C-terminus, or both. In some embodiments, a polypeptide may be cyclic. In some embodiments, a polypeptide is not cyclic. In some embodiments, a polypeptide is linear.

“Stable”: As used herein, the term “stable,” when applied to compositions means that the compositions maintain one or more aspects of their physical structure and/or activity over a period of time under a designated set of conditions. In some embodiments, the period of time is at least about one hour; in some embodiments, the period of time is about 5 hours, about 10 hours, about one (1) day, about one (1) week, about two (2) weeks, about one (1) month, about two (2) months, about three (3) months, about four (4) months, about five (5) months, about six (6) months, about eight (8) months, about ten (10) months, about twelve (12) months, about twenty-four (24) months, about thirty-six (36) months, or longer. In some embodiments, the period of time is within the range of about one (1) day to about twenty-four (24) months, about two (2) weeks to about twelve (12) months, about two (2) months to about five (5) months, etc. In some embodiments, the designated conditions are ambient conditions (e.g., at room temperature and ambient pressure). In some embodiments, the designated conditions are physiologic conditions (e.g., in vivo or at about 37 degrees Celsius for example in serum or in phosphate buffered saline). In some embodiments, the designated conditions are under cold storage (e.g., at or below about 4 degrees Celsius, −20 degrees Celsius, or −70 degrees Celsius). In some embodiments, the designated conditions are in the dark.

“Substantially”: As used herein, the term “substantially”, and grammatical equivalents, refer to the qualitative condition of exhibiting total or near-total extent or degree of a characteristic or property of interest. One of ordinary skill in the art will understand that biological and chemical phenomena rarely, if ever, go to completion and/or proceed to completeness or achieve or avoid an absolute result.

“Substantially free” As used herein, the term “substantially free” means that it is absent or present at a concentration below detection measured by a selected art-accepted means, or otherwise is present at a level that those skilled in the art would consider to be negligible in the relevant context.

“Sustained release”: As used herein, the term “sustained release” and in accordance with its art-understood meaning of release that occurs over an extended period of time. The extended period of time can be at least about 3 days, about 5 days, about 7 days, about 10 days, about 15 days, about 30 days, about 1 month, about 2 months, about 3 months, about 6 months, or even about 1 year. In some embodiments, sustained release is substantially burst-free. In some embodiments, sustained release involves steady release over the extended period of time, so that the rate of release does not vary over the extended period of time more than about 5%, about 10%, about 15%, about 20%, about 30%, about 40% or about 50%.

### DETAILED DESCRIPTION OF CERTAIN EMBODIMENTS

Among other things, the present disclosure provides articles of manufacture, such as patterned photonic crystals, patterned inverse opals, and methods of preparing and using such articles of manufacture.

The present disclosure encompasses a recognition that control over exhibited structural color of an inverse opal is or can be manipulated or tuned. In some embodiments, a wavelength of structural color for an inverse opal can be tuned.

In some embodiments, wavelength of an inverse opal can be tuned by changing an inverse opals' geometry. In some embodiments, wavelength of an inverse opal can be tuned by changing an inverse opals' index of refraction.

In some embodiments, the present disclosure provides inverse opals. In some embodiments, the present disclosure provides silk inverse opals (SIOs). In some embodiments, the present disclosure provides large scale (i.e. centimeter length scales) inverse opals. In some embodiments, the present disclosure provides inverse opals with tunable, geometrically defined structural color. In some embodiments, the present disclosure provides high quality, mechanically flexible inverse opals.

In some embodiments, the present disclosure provides methods to control protein conformation in inverse opal structures. In some embodiments, control includes conditions that permit nanoscale reconfiguration of a protein material. In some embodiments, inverse opals as provide herein are structurally reconfigured.

In some embodiments, reconfiguration of protein material offers a possibility to controllably affect optical lattices. In some embodiments, structural color of inverse opals is reconfigured either by water vapor exposure or by ultra violet radiation exposure. In some embodiments, multispectral photonic macro- or micro-patterns are demonstrated by selectively applying water vapor or UV irradiation through a shadow mask.

In some embodiments, the present disclosure provides patterned inverse opals structures. In some embodiments, the present disclosure includes methods of inducing controllable nanoscale conformation change of amorphous silk format to form patterns in inverse opals. In some embodiments, a pattern or patterns formed in an inverse opal results in changes in a photonic stop-band.

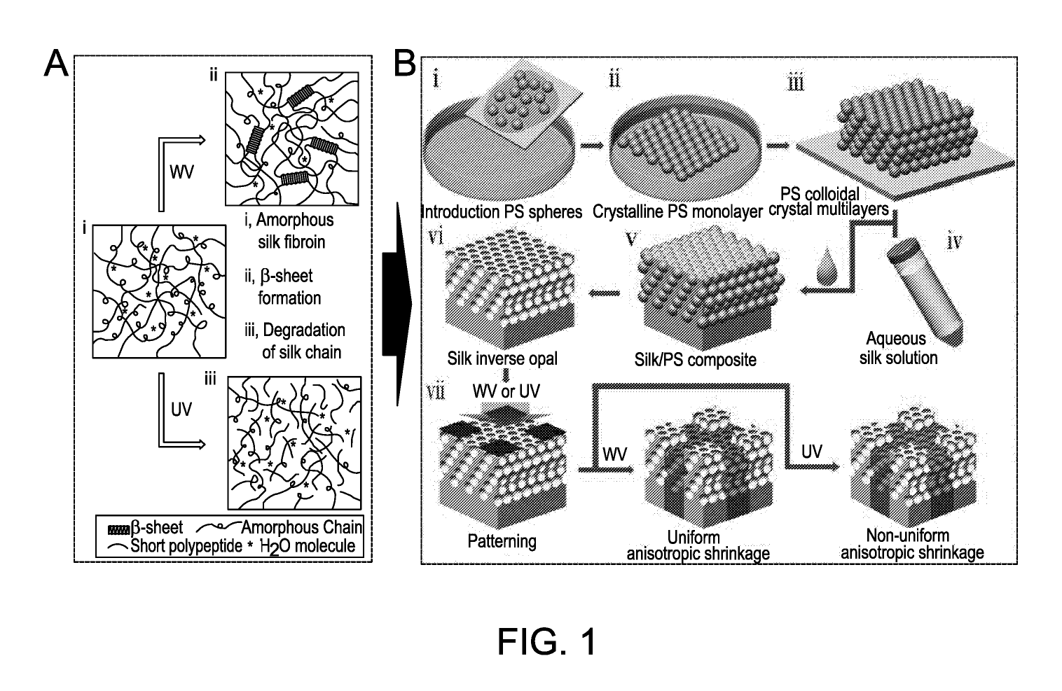

In some embodiments, water and/or moisture affects structural properties of protein materials. In some embodiments, water and/or moisture affects structural properties of silk materials. In some embodiments, water affects structural properties due to a strong interaction between silk proteins and water molecules. In some embodiments, strong interactions lead to beta-sheet formation when a silk film is exposed to water vapor (see Hu et al., 12 Biomacromolecules, 1686 (2011); see also FIG. 1 at panel A. In some embodiments, strong interactions lead to material dissolution (i.e. an amorphous, helix dominated silk structure) when a silk film is immersed in water.

In some embodiments, deep ultra violet light induces peptide chain scission and photodegradation of silk fibroin. In some embodiments, peptide chain scission and photodegradation is initiated at weaker C—N bonds. In some embodiments, peptide chain scission and photodegradation leads to molecular rearrangement of silk fibroin. (See Shao et al., 96 J. Appl. Polym. Sci., 1999 (2005) see also FIG. 1 at panel A).

In some embodiments, reconfiguration is theoretically predictive of SIOs using modeling. In some embodiments, good agreement is found between the calculated SIOs reflectance spectra and the measured SIO responses.

In some embodiments, the present disclosure provides tuning of a colorimetric response by filling an SIO structure with liquids. In some embodiments, tuning of a colorimetric response is affected with liquids having different molecular sizes.

The present disclosure propose a simpler and more effective solution for producing PhCs and SIOs with high resolution, strong reflectivity and controllability over the entire visible spectrum.

Photonic crystals (PhCs), first proposed in the late 1980s, are systems characterized by a periodic variation of the dielectric function in one or more dimensions, which can be exploited for controlling and manipulating the flow of light and generating bright iridescence through the definition of photonic band gaps (PBGs). (See Yablonovitch, 58 Phys. Rev. Lett., 2059 (1987); see also John, 11 Nat. Mater., 997 (2012)). Because of the periodic arrangement of the dielectric materials, PhC materials have a photonic band gap (PBG), prohibiting certain wavelengths or frequencies of light located in the PBG from propagating through the PhCs. This leads to yield iridescent structural colors if the bandgap falls within the visible range. (See Joannopoulos et al., 386 Nature, 143 (1997).

In recent years, three-dimensional (3D) colloidal PhCs and their inverse replica materials (inverse opals) have attracted considerable interest owing to their potential as key materials in the building blocks of various devices for applications in optics, electronics, and sensors. (See Holtz et al., 389 Nature, 829 (1997); see also Stein et al., 42 Chem. Soc. Rev., 2763 (2013); Armstrong et al., 3 J. Mater. Chem. C, 6109 (2015); and Phillips et al., 45 Chem. Soc. Rev., 281 (2016)).

So far, great progress has been made in fabricating 3D colloidal photonic structure through various techniques. (See Holland et al., 281 Science, 538 (1998); see also Jiang et al., 126 J. Am. Chem. Soc., 13778 (2004); Zhou et al., 20 Langmuir, 1524 (2004); van Blaaderen et al., 385 Nature, 321 (1997); Trau et al, 272 Science, 706 (1996); Oh et al., 21 J. Mater. Chem., 14167 (2011); and Hatton et al., 107 Proc. Natl. Acad. Sci. U.S.A., 10354 (2010)). Among them, layer-by-layer transfer technique has been proved to be an effective method to obtain large-scale, defect-free colloidal crystal multilayers. (See Oh et al., 21 J. Mater. Chem., 14167 (2011).

The design of patterned photonic structures through reconfiguration of intrinsic structural color has been a recently investigated topic given the promising applications of colloidal photonic structures in sensing and image displays. Several approaches, including printing, imprinting, photolithography, and others have been developed for the patterning of colloidal photonic structures through band gap adjustment. (See Hatton et al., 107 Proc. Natl. Acad. Sci. U.S.A., 10354 (2010); see also Fudouzi et al., 15 Adv. Mater., 892 (2003); Kim et al., 3 Nat. Photonics, 534 (2009); Yang et al., 51 Chem. Commun., 16972 (2015); Ding et al., 7 Nanoscale, 1857 (2015); and Lee et al., 26 Adv. Funct. Mater., 4587 (2016)).

Most of these approaches suffer from long process times and limited resolution. These drawbacks can be improved by means of magnetic tuning and lithographic fixing of color using superparamagnetic colloids dispersed in a photocurable resin, (see Kim et al., 3 Nat. Photonics, 534 (2009) but this approach results in poor reflectivity in the stop-band.

In most artificial inverse opals, the photonic band gap is very robust and extremely difficult to spectrally tune once the structure is fabricated. Most recently, multicolored micropatterns have been designed through thermal compression of UV exposed inverse opals. (See Lee et al., 26 Adv. Funct. Mater., 4587 (2016)). This procedure involves at least these processes: (i) UV irradiation of an infiltrated direct opal; (ii) removal of the direct structure; (iii) thermal annealing of the inverse opal. This approach requires high UV dose, which could limit some biological applications, and the structural stresses during opal post-processing affect the end optical quality of the structure ultimately limiting applications.

### Biopolymers

### Silk

In some embodiments, a polypeptide is or comprises a silk polypeptide, such as a silk fibroin polypeptide. In nature, silk is produced as protein fiber, typically made by specialized glands of animals, and often used in nest construction. Organisms that produce silk include the Hymenoptera (bees, wasps, and ants and other types of arthropods, most notably various arachnids such as spiders (e.g., spider silk), also produce silk. Silk fibers generated by insects and spiders represent the strongest natural fibers known and rival even synthetic high performance fibers.

The first reported examples of silk being used as a textile date to ancient China (see Elisseeff, “The Silk Roads: Highways of Culture and Commerce,” Berghahn Books/UNESCO, New York (2000); see also Vainker, “Chinese Silk: A Cultural History,” Rutgers University Press, Piscataway, N.J. (2004)); it has been highly prized in that industry ever since. Indeed, silk has been extensively investigated for its potential in textile, biomedical, photonic and electronic applications. Glossy and smooth, silk is favored by not only fashion designers but also tissue engineers because it is mechanically tough but degrades harmlessly inside the body, offering new opportunities as a highly robust and biocompatible material substrate (see Altman et al., Biomaterials, 24: 401 (2003); see also Sashina et al., Russ. J. Appl. Chem., 79: 869 (2006)). Thus, even among biocompatible polymers (and particularly among biocompatible polypeptides, including natural polypeptides), silk and silk polypeptides are of particular interest and utility.

Silk fibroin is a polypeptide, like collagen, but with a unique feature: it is produced from the extrusion of an amino-acidic solution by a living complex organism (while collagen is produced in the extracellular space by self-assembly of cell-produced monomers).

Silk is naturally produced by various species, including, without limitation: Antheraea mylitta; Antheraea pernyi; Antheraea yamamai; Galleria mellonella; Bombyx mori; Bombyx mandarina; Galleria mellonella; Nephila clavipes; Nephila senegalensis; Gasteracantha mammosa; Argiope aurantia; Araneus diadematus; Latrodectus geometricus; Araneus bicentenarius; Tetragnatha versicolor; Araneus ventricosus; Dolomedes tenebrosus; Euagrus chisoseus; Plectreurys tristis; Argiope trifasciata; and Nephila madagascariensis. Embodiments of the present invention may utilize silk proteins from any such organism. In some embodiments, the present invention utilizes silk or silk proteins from a silkworm, such as Bombyx mori (e.g., from cocoons or glands thereof). In some embodiments, the present invention utilizes silks or silk proteins from a spider, such as Nephila clavipes (e.g., from nests/webs or glands thereof).

In general, silk polypeptides for use in accordance with the present invention may be or include natural silk polypeptides, or fragments or variants thereof. In some embodiments, such silk polypeptides may be utilized as natural silk, or may be prepared from natural silk or from organisms that produce it. Alternatively, silk polypeptides utilized in the present invention may be prepared through an artificial process, for example, involving genetic engineering of cells or organisms (e.g., genetically engineered bacteria, yeast, mammalian cells, non-human organisms, including animals, or transgenic plants) to produce a silk polypeptide, and/or by chemical synthesis.

In some particular embodiments, silk polypeptides are obtained from cocoons produced by a silkworm, in certain embodiments by the silkworm Bombyx mori; such cocoons are of particular interest as a source of silk polypeptide because they offer low-cost, bulk-scale production of silk polypeptides. Moreover, isolation methodologies have been developed that permit preparation of cocoon silk, and particularly of Bombyx mori cocoon silk in a variety of forms suitable for various commercial applications.

Silkworm cocoon silk contains two structural proteins, the fibroin heavy chain (˜350 kDa) and the fibroin light chain (˜25 kDa), which are associated with a family of non-structural proteins termed sericins, that glue the fibroin chains together in forming the cocoon. The heavy and light fibroin chains are linked by a disulfide bond at the C-terminus of the two subunits (see Takei, et al. J. Cell Biol., 105: 175, 1987; see also Tanaka, et al J. Biochem. 114: 1, 1993; Tanaka, et al Biochim. Biophys. Acta., 1432: 92, 1999; Kikuchi, et al Gene, 110: 151, 1992). The sericins are a high molecular weight, soluble glycoprotein constituent of silk which gives the stickiness to the material. These glycoproteins are hydrophilic and can be easily removed from cocoons by boiling in water. This process is often referred to as “degumming.” In some embodiments, silk polypeptide compositions utilized in accordance with the present invention are substantially free of sericins (e.g., contain no detectable sericin or contain sericin at a level that one of ordinary skill in the pertinent art will consider negligible for a particular use).

To give but one particular example, in some embodiments, silk polypeptide compositions for use in accordance with the present invention are prepared by processing cocoons spun by silkworm, Bombyx mori so that sericins are removed and silk polypeptides are solubilized. In some such embodiments, cocoons are boiled (e.g., for a specified length of time, often approximately 30 minutes) in an aqueous solution (e.g., of 0.02 M Na₂CO₃), then rinsed thoroughly with water to extract the glue-like sericin proteins. Extracted silk is then dissolved in a solvent, for example, LiBr (such as 9.3 M). A resulting silk fibroin solution can then be further processed for a variety of applications as described elsewhere herein.

In some embodiments, silk polypeptide compositions for use in the practice of the present invention comprise silk fibroin heavy chain polypeptides and/or silk fibroin light chain polypeptides; in some such embodiments, such compositions are substantially free of any other polypeptide. In some embodiments that utilize both a silk fibroin heavy chain polypeptide and a silk fibroin light chain polypeptide, the heavy and light chain polypeptides are linked to one another via at least one disulfide bond. In some embodiments, where the silk fibroin heavy and light chain polypeptides are present, they are linked via one, two, three or more disulfide bonds.

Exemplary natural silk polypeptides that may be useful in accordance with the present invention may be found in International Patent Publication Number WO 2011/130335, International Patent Publication Number WO 97/08315 and/or U.S. Pat. No. 5,245,012, the entire contents of each of which are incorporated herein by reference. Table 1, below, provides an exemplary list of silk-producing species and silk proteins:

TABLE 1

| | | | |
|---|---|---|---|
| Accession | Species | Producing gland | Protein |

Silkworms

| | | | |
|---|---|---|---|
| AAN28165 | Antheraea mylitta | Salivary | Fibroin |
| AAC32606 | Antheraea pernyi | Salivary | Fibroin |
| AAK83145 | Antheraea yamamai | Salivary | Fibroin |
| AAG10393 | Galleria mellonella | Salivary | Heavy-chain fibroin (N-terminal) |
| AAG10394 | Galleria mellonella | Salivary | Heavy-chain fibroin (C-terminal) |
| P05790 | Bombyx mori | Salivary | Fibroin heavy chain precursor, Fib-H, H-fibroin |
| CAA27612 | Bombyx mandarina | Salivary | Fibroin |
| Q26427 | Galleria mellonella | Salivary | Fibroin light chain precursor, Fib-L, L-fibroin, PG-1 |
| P21828 | Bombyx mori | Salivary | Fibroin light chain precursor, Fib-L, L-fibroin |

Spiders

| | | | |
|---|---|---|---|
| P19837 | Nephila clavipes | Major ampullate | Spidroin 1, dragline silk fibroin 1 |
| P46804 | Nephila clavipes | Major ampullate | Spidroin 2, dragline silk fibroin 2 |
| AAK30609 | Nephila senegalensis | Major ampullate | Spidroin 2 |
| AAK30601 | Gasteracantha mammosa | Major ampullate | Spidroin 2 |
| AAK30592 | Argiope aurantia | Major ampullate | Spidroin 2 |
| AAC47011 | Araneus diadematus | Major ampullate | Fibroin-4, ADF-4 |
| AAK30604 | Latrodectus geometricus | Major ampullate | Spidroin 2 |
| AAC04503 | Araneus bicentenarius | Major ampullate | Spidroin 2 |
| AAK30615 | Tetragnatha versicolor | Major ampullate | Spidroin 1 |
| AAN85280 | Araneus ventricosus | Major ampullate | Dragline silk protein-1 |
| AAN85281 | Araneus ventricosus | Major ampullate | Dragline silk protein-2 |
| AAC14589 | Nephila clavipes | Minor ampullate | MiSp1 silk protein |
| AAK30598 | Dolomedes tenebrosus | Ampullate | Fibroin 1 |
| AAK30599 | Dolomedes tenebrosus | Ampullate | Fibroin 2 |
| AAK30600 | Euagrus chisoseus | Combined | Fibroin 1 |
| AAK30610 | Plectreurys tristis | Larger ampule-shaped | Fibroin 1 |
| AAK30611 | Plectreurys tristis | Larger ampule-shaped | Fibroin 2 |
| AAK30612 | Pleclreurys tristis | Larger ampule-shaped | Fibroin 3 |
| AAK30613 | Plectreurys tristis | Larger ampule-shaped | Fibroin 4 |
| AAK30593 | Argiope trifasciata | Flagelliform | Silk protein |
| AAF36091 | Nephila madagascariensis | Flagelliform | Fibroin, silk protein (N-terminal) |
| AAF36092 | Nephila madagascariensis | Flagelliform | Silk protein (C-terminal) |
| AAC38846 | Nephila clavipes | Flagelliform | Fibroin, silk protein (N-terminal) |
| AAC38847 | Nephila clavipes | Flagelliform | Silk protein (C-terminal) |

An exemplary list of silk-producing species and silk proteins (adopted from Bini et al. (2003), J. Mol. Biol. 335(1): 27-40).

Silk fibroin polypeptides are characterized by a structure that typically reflects a modular arrangement of large hydrophobic blocks staggered by hydrophilic, acidic spacers, and, typically, flanked by shorter (˜100 amino acid), often highly conserved, terminal domains (at one or both of the N and C termini). In many embodiments, the hydrophobic blocks comprise or consist of alanine and/or glycine residues; in some embodiments alternating glycine and alanine; in some embodiments alanine alone. In many embodiments, the hydrophilic spacers comprise or consist of amino acids with bulky side-groups. Naturally occurring silk fibroin polypeptides often have high molecular weight (200 to 350 kDa or higher) with transcripts of 10,000 base pairs and higher and >3000 amino acids (reviewed in Omenetto and Kaplan (2010) Science 329: 528-531).

In some embodiments, core repeat sequences of the hydrophobic blocks found in silk fibroin polypeptides are represented by one or more of the following amino acid sequences and/or formulae:

(SEQ ID NO: 1)
(GAGAGS)5-15;
(SEQ ID NO: 2)
(GX)5-15 (X = V, I, A);
(SEQ ID NO: 3)
GAAS;
(SEQ ID NO: 4)
(S1-2A11-13);
(SEQ ID NO: 5)
GX1-4 GGX;
(SEQ ID NO: 6)
GGGX (X = A, S, Y, R, D V, W, R, D);
(SEQ ID NO: 7)
(S1-2A1-4)1-2;
(SEQ ID NO: 8)
GLGGLG;
(SEQ ID NO: 9)
GXGGXG (X = L, I, V, P);
GPX (X = L, Y, I);
(SEQ ID NO: 10)
(GP(GGX)1-4 Y)n (X = Y, V, S, A);
(SEQ ID NO: 11)
GRGGAn;
GGXn (X = A, T, V, S);
(SEQ ID NO: 12)
GAG(A)6-7GGA;
and
(SEQ ID NO: 13)
GGX GX GXX (X = Q, Y, L, A, S, R).

In some embodiments, a fibroin polypeptide contains multiple hydrophobic blocks, e.g., 3, 4, 5, 6, 7, 8, 9, 10, 11, 12, 13, 14, 15, 16, 17, 18, 19 and 20 hydrophobic blocks within the polypeptide. In some embodiments, a fibroin polypeptide contains between 4-17 hydrophobic blocks. In some embodiments, a fibroin polypeptide comprises at least one hydrophilic spacer sequence (“hydrophilic block”) that is about 4-50 amino acids in length. Non-limiting examples of such hydrophilic spacer sequences include:

(SEQ ID NO: 14)
TGSSGFGPYVNGGYSG;
(SEQ ID NO: 15)
YEYAWSSE;
(SEQ ID NO: 16)
SDFGTGS;
(SEQ ID NO: 17)
RRAGYDR;
(SEQ ID NO: 18)
EVIVIDDR;
(SEQ ID NO: 19)
TTIIEDLDITIDGADGPI
and
(SEQ ID NO: 20)
TISEELTI.

In certain embodiments, a fibroin polypeptide contains a hydrophilic spacer sequence that is a variant of any one of the representative spacer sequences listed above. In some embodiments, a variant spacer sequence shows at least 75%, at least 80%, at least 85%, at least 90%, or at least 95% identity to one or more of the hydrophilic spacer sequences listed above, which may be considered to be reference hydrophilic spacer sequences.

In some embodiments, a fibroin polypeptide suitable for the present invention does not contain any of the hydrophilic spacer sequences listed above; in some embodiments, such a fibroin polypeptide further does not contain any variant of such a hydrophilic spacer sequence.

It is generally believed that features of silk fibroin polypeptide structure contribute to the material properties and/or functional attributes of the polypeptide. For example, sequence motifs such as poly-alanine (polyA) and polyalanine-glycine (poly-AG) are inclined to be beta-sheet-forming; the presence of one or more hydrophobic blocks as described herein therefore may contribute to a silk polypeptide's ability to adopt a beta-sheet conformation, and/or the conditions under which such beta-sheet adoption occurs.

In some embodiments, the silk fiber can be an unprocessed silk fiber, e.g., raw silk or raw silk fiber. The term “raw silk” or “raw silk fiber” refers to silk fiber that has not been treated to remove sericin, and thus encompasses, for example, silk fibers taken directly from a cocoon. Thus, by unprocessed silk fiber is meant silk fibroin, obtained directly from the silk gland. When silk fibroin, obtained directly from the silk gland, is allowed to dry, the structure is referred to as silk I in the solid state. Thus, an unprocessed silk fiber comprises silk fibroin mostly in the silk I conformation (a helix dominated structure). A regenerated or processed silk fiber on the other hand comprises silk fibroin having a substantial silk II (a β-sheet dominated structure).

Inducing a conformational change in silk fibroin can facilitate formation of a solid-state silk fibroin and/or make the silk fibroin at least partially insoluble. Further, inducing formation of beta-sheet conformation structure in silk fibroin can prevent silk fibroin from contracting into a compact structure and/or forming an entanglement. In some embodiments, a conformational change in the silk fibroin can alter the crystallinity of the silk fibroin in the silk particles, such as increasing crystallinity of the silk fibroin, e.g., silk II beta-sheet crystallinity. In some embodiments, the conformation of the silk fibroin in the silk fibroin foam can be altered after formation.

In some embodiments, bio-ink compositions as disclosed herein cure to possess some degree of silk II beta-sheet crystallinity.

In some embodiments, bio-ink compositions that cure form printed articles with a high degree of silk II beta-sheet crystallinity. In some embodiments, bio-ink compositions that subsequently form printed articles with a high degree of silk II beta-sheet crystallinity are insoluble to solvents. In some embodiments, bio-ink compositions that subsequently form printed articles with a high degree of silk II beta-sheet crystallinity are insoluble to immersion in solvents. In some embodiments, bio-ink compositions that subsequently form printed articles with a high degree of silk II beta-sheet crystallinity are insoluble when layers of a bio-ink composition are subsequently printed, deposited, and/or extruded atop a printed article.

In some embodiments, bio-ink compositions that cure form printed articles with a low degree of silk II beta-sheet crystallinity. In some embodiments, bio-ink compositions that subsequently form printed articles with a low degree of silk II beta-sheet crystallinity are at least partially soluble to solvents. In some embodiments, bio-ink compositions that subsequently form printed articles with a low degree of silk II beta-sheet crystallinity are at least partially soluble when layers of a bio-ink composition are subsequently printed, deposited, and/or extruded atop a printed article.

In some embodiments, physical properties of silk fibroin can be modulated when selecting and/or altering a degree of crystallinity of silk fibroin. In some physical properties of silk fibroin include, for example, mechanical strength, degradability, and/or solubility. In some embodiments, inducing a conformational change in silk fibroin can alter the rate of release of an active agent from the silk matrix.

In some embodiments, a conformational change can be induced by any methods known in the art, including, but not limited to, alcohol immersion (e.g., ethanol, methanol), water annealing, water vapor annealing, heat annealing, shear stress (e.g., by vortexing), ultrasound (e.g., by sonication), pH reduction (e.g., pH titration), and/or exposing the silk particles to an electric field and any combinations thereof.

Also, GXX motifs contribute to 31-helix formation; GXG motifs provide stiffness; and, GPGXX (SEQ ID NO: 22) contributes to beta-spiral formation. In light of these teachings and knowledge in the art (see, for example, review provided by Omenetto and Kaplan Science 329: 528, 2010), those of ordinary skill, reading the present specification, will appreciate the scope of silk fibroin polypeptides and variants thereof that may be useful in practice of particular embodiments of the present invention.

In some embodiments, bio-ink compositions as disclosed herein are or comprise a silk ionomeric composition. In some embodiments, bio-ink compositions as disclosed herein are or comprise ionomeric particles distributed in a solution. (See for example, WO 2011/109691 A2, to Kaplan et al., entitled Silk-Based Ionomeric Compositions, which describes silk-based ionomeric compositions and methods of manufacturing, which is hereby incorporated by reference in its entirety herein).

In some embodiments, bio-ink compositions comprising silk-based ionomeric particles may exist in fluid suspensions (or particulate solutions) or colloids, depending on the concentration of the silk fibroin. In some embodiments, bio-ink compositions comprising ionmeric particles include positively and negatively charged silk fibroin associated via electrostatic interaction.

In some embodiments, silk ionomeric particles are reversibly cross-linked through electrostatic interactions. In some embodiments, silk ionomeric compositions reversibly transform from one state to the other state when exposed to an environmental stimulus. In some embodiments, environmental stimuli silk ionomeric compositions respond to include for example, a change in pH, a change in ionic strength, a change in temperature, a change in an electrical current applied to the composition, or a change on a mechanical stress as applied to the composition. In some embodiments, silk ionomeric compositions transform into a dissociated charged silk fibroin solution.

### Keratins

Keratins are members of a large family of fibrous structural proteins (see, for example, Moll et al, Cell 31:11 1982 that, for example, are found in the outer layer of human skin, and also provide a key structural component to hair and nails. Keratin monomers assemble into bundles to form intermediate filaments, which are tough and insoluble and form strong unmineralized tissues found in reptiles, birds, amphibians, and mammals.

Two distinct families of keratins, type I and type II, have been defined based on homologies to two different cloned human epidermal keratins (see Fuchs et al., Cell 17:573, 1979, which is hereby incorporated by reference in its entirety herein). Like other intermediate filament proteins, keratins contain a core structural domain (typically approximately 300 amino acids long) comprised of four segments in alpha-helical conformation separated by three relatively short linker segments predicted to be in beta-turn confirmation (see Hanukoglu & Fuchs Cell 33:915, 1983, which is hereby incorporated by reference in its entirety herein). Keratin monomers supercoil into a very stable, left-handed superhelical structure; in this form, keratin can multimerise into filaments. Keratin polypeptides typically contain several cysteine residues that can become crosslinked

In some embodiments, bio-ink compositions for use in the practice of the present invention comprise one or more keratin polypeptides.

### Biopolymer Properties

### Molecular Weight

The present disclosure appreciates that preparations of a particular biopolymer that differ in the molecular weight of the included biopolymer (e.g., average molecular weight and/or distribution of molecular weights) may show different properties relevant to practice of the present invention, including, for example, different viscosities and/or flow characteristics, different abilities to cure, etc. In some embodiments, a molecular weight of a biopolymer may impact a self-life of a bio-ink composition. Those of ordinary skill, reading the present disclosure and armed with knowledge in the art, will be able to prepare and utilize various bio-ink compositions with appropriate molecular weight characteristics for relevant embodiments of the invention.

In some particular embodiments, bio-ink compositions for use in accordance with the present invention include biopolymers whose molecular weight is within a range bounded by a lower limit and an upper limit, inclusive. In some embodiments, the lower limit is at least 1 kDa, at least 5 kDa, at least 10 kDa, at least 15 kDa, at least 20 kDa, at least 25 kDa, at least 30 kDa, at least 40 kDa, at least 50 kDa, at least 60 kDa, at least 70 kDa, at least 80 kDa, at least 90 kDa, at least 100 kDa, at least 150 kDa, at least 200 kDa; in some embodiments, the upper limit is less than 500 kDa, less than 450 kDa, less than 400 kDa, less than 350 kDa, less than 300 kDa, less than 250 kDa, less than 200 kDa, less than 175 kDa, less than 150 kDa, less than 120 kDa, less than 100 kDa, less than 90 kDa, less than 80 kDa, less than 70 kDa, less than 60 kDa, less than 50 kDa, less than 40 kDa, less than 30 kDa, less than 25 kDa, less than 20 kDa, less than 15 kDa, less than 12 kDa, less than 10 kDa, less than 9 kDa, less than 8 kDa, less than 7 kDa, less than 6 kDa, less than 5 kDa, less than 4 kDa, less than 3.5 kDa, less than 3 kDa, less than 2.5 kDa, less than 2 kDa, less than 1.5 kDa, or less than about 1.0 kDa, etc.

In some embodiments, a “low molecular weight” bio-ink composition is utilized. In some such embodiments, the composition contains biopolymers within a molecular weight range between about 3.5 kDa and about 120 kDa. To give but one example, low molecular weight silk fibroin compositions, and methods of preparing such compositions as may be useful in the context of the present invention, are described in detail in U.S. provisional application 61/883,732, entitled “LOW MOLECULAR WEIGHT SILK FIBROIN AND USES THEREOF,” the entire contents of which are incorporated herein by reference.

In some embodiments, bio-ink compositions for use in accordance with the present invention are substantially free of biopolymer components outside of a particular molecular weight range or threshold. For example, in some embodiments, a bio-ink composition is substantially free of biopolymer components having a molecular weight above about 400 kDa. In some embodiments, described biopolymer inks are substantially free of protein fragments over 200 kDa. “In some embodiments, the highest molecular weight biopolymers in provided bio-ink compositions have a molecular weight that is less than about 300 kDa-about 400 kDa (e.g., less than about 400 kDa, less than about 375 kDa, less than about 350 kDa, less than about 325 kDa, less than about 300 kDa, etc.).

In some embodiments, bio-ink compositions for use in accordance with the present invention are comprised of polymers (e.g., protein polymers) having molecular weights within the range of about 20 kDa-about 400 kDa, or within the range of about 3.5 kDa and about 120 kDa.

Those skilled in the art will appreciate that bio-ink compositions of a desired molecular weight (i.e., containing biopolymers within a particular molecular weight range and/or substantially free of biopolymers outside of that molecular weight range) may be prepared ab initio, or alternatively may be prepared either by fragmenting compositions of higher-molecular weight compositions, or by aggregating compositions of lower molecular weight polymers.

To give but one example, it is known in the art that different molecular weight preparations of silk fibroin polypeptides may be prepared or obtained by boiling silk solutions for different amounts of time. For example, established conditions (see, for example, Wray, et. al., 99 J. Biomedical Materials Research Part B: Applied Biomaterials 2011, which is hereby incorporated by reference in its entirety herein) are known to generate silk fibroin polypeptide compositions with maximal molecular weights in the range of about 300 kDa-about 400 kDa after about 5 minutes of boiling; compositions with molecular weights about 60 kDa are can be achieved under comparable conditions after about 60 minutes of boiling.

In some particular embodiments, silk fibroin polypeptide compositions of desirable molecular weight can be derived by degumming silk cocoons at or close to (e.g., within 5% of) an atmospheric boiling temperature, where such degumming involves at least about: 1 minute of boiling, 2 minutes of boiling, 3 minutes of boiling, 4 minutes of boiling, 5 minutes of boiling, 6 minutes of boiling, 7 minutes of boiling, 8 minutes of boiling, 9 minutes of boiling, 10 minutes of boiling, 11 minutes of boiling, 12 minutes of boiling, 13 minutes of boiling, 14 minutes of boiling, 15 minutes of boiling, 16 minutes of boiling, 17 minutes of boiling, 18 minutes of boiling, 19 minutes of boiling, 20 minutes of boiling, 25 minutes of boiling, 30 minutes of boiling, 35 minutes of boiling, 40 minutes of boiling, 45 minutes of boiling, 50 minutes of boiling, 55 minutes of boiling, 60 minutes or longer, including, e.g., at least 70 minutes, at least 80 minutes, at least 90 minutes, at least 100 minutes, at least 110 minutes, at least about 120 minutes or longer. As used herein, the term “atmospheric boiling temperature” refers to a temperature at which a liquid boils under atmospheric pressure.

In some embodiments, such degumming is performed at a temperature of: about 30° C., about 35° C., about 40° C., about 45° C., about 50° C., about 55° C., about 60° C., about 65° C., about 70° C., about 75° C., about 80° C., about 85° C., about 90° C., about 95° C., about 100° C., about 105° C., about 110° C., about 115° C., about 120° C., about 125° C., about 130° C., about 135° C., about 140° C., about 145° C., or about at least 150° C.

In some particular embodiments, bio-ink compositions for use in accordance with the present invention is provided, prepared, and/or manufactured from a solution of silk fibroin that has been boiled for at least about 5, 10, 15, 20, 25, 30, 35, 40, 45, 50, 55, 60, 70, 80, 90, 100, 110, 120, 150, 180, 210, 240, 270, 310, 340, 370, 410 minutes or more. In some embodiments, such boiling is performed at a temperature within the range of: about 30° C., about 35° C., about 40° C., about 45° C., about 50° C., about 55° C., about 60° C., about 65° C., about 70° C., about 75° C., about 80° C., about 85° C., about 90° C., about 95° C., about 100° C., about 105° C., about 110° C., about 115° C., about at least 120° C. In some embodiments, such boiling is performed at a temperature below about 65° C. In some embodiments, such boiling is performed at a temperature of about 60° C. or less.

In some embodiments, one or more processing steps of a bio-ink composition for use in accordance with the present invention is performed at an elevated temperature relative to ambient temperature. In some embodiments, such an elevated temperature can be achieved by application of pressure. For example, in some embodiments, elevated temperature (and/or other desirable effectis) can be achieved or simulated through application of pressure at a level between about 10-40 psi, e.g., at about 11 psi, about 12 psi, about 13 psi, about 14 psi, about 15 psi, about 16 psi, about 17 psi, about 18 psi, about 19 psi, about 20 psi, about 21 psi, about 22 psi, about 23 psi, about 24 psi, about 25 psi, about 26 psi, about 27 psi, about 28 psi, about 29 psi, about 30 psi, about 31 psi, about 32 psi, about 33 psi, about 34 psi, about 35 psi, about 36 psi, about 37 psi, about 38 psi, about 39 psi, or about 40 psi.

### Concentration

In some embodiments, bio-ink compositions are prepared, provided, maintained and or utilized within a selected concentration range of biopolymer.

For example, in some embodiments, a bio-ink composition of interest may contain biopolymer (e.g., a polypeptide such as a silk fibroin polypeptide) at a concentration within the range of about 0.1 wt % to about 95 wt %, 0.1 wt % to about 75 wt %, or 0.1 wt % to about 50 wt %. In some embodiments, the aqueous silk fibroin solution can have silk fibroin at a concentration of about 0.1 wt % to about 10 wt %, about 0.1 wt % to about 5 wt %, about 0.1 wt % to about 2 wt %, or about 0.1 wt % to about 1 wt %. In some embodiments, the biopolymer is present at a concentration of about 10 wt % to about 50 wt %, about 20 wt % to about 50 wt %, about 25 wt % to about 50 wt %, or about 30 wt % to about 50 wt %. In some embodiments, a weight percent of silk in solution is about less than 1 wt %, is about less than 1.5 wt %, is about less than 2 wt %, is about less than 2.5 wt %, is about less than 3 wt %, is about less than 3.5 wt %, is about less than 4 wt %, is about less than 4.5 wt %, is about less than 5 wt %, is about less than 5.5 wt %, is about less than 6 wt %, is about less than 6.5 wt %, is about less than 7 wt %, is about less than 7.5 wt %, is about less than 8 wt %, is about less than 8.5 wt %, is about less than 9 wt %, is about less than 9.5 wt %, is about less than 10 wt %, is about less than 11 wt %, is about less than 12 wt %, is about less than 13 wt %, is about less than 14 wt %, is about less than 15 wt %, is about less than 16 wt %, is about less than 17 wt %, is about less than 18 wt %, is about less than 19 wt %, is about less than 20 wt %, is about less than 25 wt %, or is about less than 30 wt %.

In some particular embodiments, the present disclosure provides the surprising teaching that particularly useful bio-ink compositions with can be provided, prepared maintained and/or utilized with a biopolymer concentration that is less than about 10 wt %, or even that is about 5% wt %, about 4 wt %, about 3 wt %, about 2 wt %, about 1 wt % or less, particularly when the biopolymer is or comprises a silk biopolymer.

### Degradation Properties of Silk-Based Materials

Additionally, as will be appreciated by those of skill in the art, much work has established that researchers have the ability to control the degradation process of silk. According to the present disclosure, such control can be particularly valuable in the fabrication of electronic components, and particularly of electronic components that are themselves and/or are compatible with biomaterials. Degradability (e.g., bio-degradability) is often essential for biomaterials used in tissue engineering and implantation. The present disclosure encompasses the recognition that such degradability is also relevant to and useful in the fabrication of silk electronic components.

According to the present disclosure, one particularly desirable feature of silk-based materials is the fact that they can be programmably degradable. That is, as is known in the art, depending on how a particular silk-based material is prepared, it can be controlled to degrade at certain rates. Degradability and controlled release of a substance from silk-based materials have been published (see, for example, WO 2004/080346, WO 2005/012606, WO 2005/123114, WO 2007/016524, WO 2008/150861, WO 2008/118133, each of which is incorporated by reference herein).

Control of silk material production methods as well as various forms of silk-based materials can generate silk compositions with known degradation properties. For example, using various silk fibroin materials (e.g., microspheres of approximately 2 μm in diameter, silk film, silk stents) entrapped agents such as therapeutics can be loaded in active form, which is then released in a controlled fashion, e.g., over the course of minutes, hours, days, weeks to months. It has been shown that layered silk fibroin coatings can be used to coat substrates of any material, shape and size, which then can be used to entrap molecules for controlled release, e.g., 2-90 days.

### Crystalline Silk Materials

As known in the art and as described herein, silk proteins can stack with one another in crystalline arrays. Various properties of such arrays are determined, for example, by the degree of beta-sheet structure in the material, the degree of cross-linking between such beta sheets, the presence (or absence) of certain dopants or other materials. In some embodiments, one or more of these features is intentionally controlled or engineered to achieve particular characteristics of a silk matrix. In some embodiments, silk fibroin-based stents are characterized by crystalline structure, for example, comprising beta sheet structure and/or hydrogen bonding. In some embodiments, provided silk fibroin-based stents are characterized by a percent beta sheet structure within the range of about 0% to about 45%. In some embodiments, silk fibroin-based stents are characterized by crystalline structure, for example, comprising beta sheet structure of about 1%, about 2%, about 3%, about 4%, about 5%, about 6%, about 7%, about 8%, about 9%, about 10%, about 11%, about 12%, about 13%, about 1%, about 1%, about 1%, about 1%, about 1%, about 1%, about 1%, about 1%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, or about 45%.

### Nanosized Crystalline Particles

In some embodiments, silk fibroin-based tracheal stents are characterized in that they include submicron size or nanosized crystallized spheres and/or particles. In some embodiments, such submicron size or nanosized crystallized spheres and/or particles have average diameters ranging between about 5 nm and 200 nm. In some embodiments, submicron size or nanosized crystallized spheres and/or particles have less than 150 nm average diameter, e.g., less than 145 nm, less than 140 nm, less than 135 nm, less than 130 nm, less than 125 nm, less than 120 nm, less than 115 nm, less than 110 nm, less than 100 nm, less than 90 nm, less than 80 nm, less than 70 nm, less than 60 nm, less than 50 nm, less than 40 nm, less than 30 nm, less than 20 nm, less than 15 nm, less than 10 nm, less than 5 nm, or smaller. In some preferred embodiments, submicron size or nanosized crystallized spheres and/or particles have average diameters of less than 100 nm.

Additives, Agents, and/or Functional Moieties

In some embodiments, a bulk material of a stent includes one or more (e.g., one, two, three, four, five or more) additives, agents, and/or functional moieties. Without wishing to be bound by a theory, additives, agents, and/or functional moieties can provide one or more desirable properties to the stent, e.g., strength, flexibility, ease of processing and handling, biocompatibility, bioresorability, lack of air bubbles, surface morphology, and the like. In some embodiments, additives, agents, and/or functional moieties can be covalently or non-covalently linked with silk fibroin and can be integrated homogenously or heterogeneously within the bulk material. In some embodiments, the active agent is absorbed/adsorbed on a surface of the stent.

In some embodiments, additives, agents, and/or functional moieties can be in any physical form. For example, additives, agents, and/or functional moieties can be in the form of a particle (e.g., microparticle or nanoparticle), a fiber, a film, a gel, a mesh, a mat, a non-woven mat, a powder, a liquid, or any combinations thereof. In some embodiments, a silk fibroin tracheal stent comprising additives, agents, and/or functional moieties can be formulated by mixing one or more additives, agents, and/or functional moieties with a silk fibroin-fibroin solution used to make such a stent.

In some embodiments, an additives, agents, and/or functional moieties are covalently associated (e.g., via chemical modification or genetic engineering). In some embodiments, additives, agents, and/or functional moieties are non-covalently associated.

Without limitations, additives, agents, and/or functional moieties can be selected from the group consisting of anti-proliferative agents, biopolymers, nanoparticles (e.g., gold nanoparticles), proteins, peptides, nucleic acids (e.g., DNA, RNA, siRNA, modRNA), nucleic acid analogs, nucleotides, oligonucleotides, peptide nucleic acids (PNA), aptamers, antibodies or fragments or portions thereof (e.g., paratopes or complementarity-determining regions), antigens or epitopes, hormones, hormone antagonists, growth factors or recombinant growth factors and fragments and variants thereof, cell attachment mediators (such as RGD), cytokines, enzymes, small molecules, antibiotics or antimicrobial compounds, toxins, therapeutic agents and prodrugs, small molecules and any combinations thereof.

In some embodiments, an additive, agent, or functional moiety is a polymer. In some embodiments, a polymer is a biocompatible polymer. As used herein, “biocompatible polymer” refers to any polymeric material that does not deteriorate appreciably and does not induce a significant immune response or deleterious tissue reaction, e.g., toxic reaction or significant irritation, over time when implanted into or placed adjacent to the biological tissue of a subject, or induce blood clotting or coagulation when it comes in contact with blood. Exemplary biocompatible polymers include, but are not limited to, a poly-lactic acid (PLA), poly-glycolic acid (PGA), poly-lactide-co-glycolide (PLGA), polyesters, poly(ortho ester), poly(phosphazine), poly(phosphate ester), polycaprolactone, gelatin, collagen, fibronectin, keratin, polyaspartic acid, alginate, chitosan, chitin, hyaluronic acid, pectin, polylactic acid, polyglycolic acid, polyhydroxyalkanoates, dextrans, and polyanhydrides, polyethylene oxide (PEO), poly(ethylene glycol) (PEG), triblock copolymers, polylysine, alginate, polyaspartic acid, any derivatives thereof and any combinations thereof. Other exemplary biocompatible polymers amenable to use according to the present disclosure include those described for example in U.S. Pat. Nos. 6,302,848; 6,395,734; 6,127,143; 5,263,992; 6,379,690; 5,015,476; 4,806,355; 6,372,244; 6,310,188; 5,093,489; 387,413; 6,325,810; 6,337,198; 6,267,776; 5,576,881; 6,245,537; 5,902,800; and 5,270,419, content of all of which is incorporated herein by reference.

In some embodiments, a biocompatible polymer is PEG or PEO. As used herein, term “polyethylene glycol” or “PEG” means an ethylene glycol polymer that contains about 20 to about 2000000 linked monomers, typically about 50-1000 linked monomers, usually about 100-300. PEG is also known as polyethylene oxide (PEO) or polyoxyethylene (POE), depending on its molecular weight. Generally PEG, PEO, and POE are chemically synonymous, but historically PEG has tended to refer to oligomers and polymers with a molecular mass below 20,000 g/mol, PEO to polymers with a molecular mass above 20,000 g/mol, and POE to a polymer of any molecular mass. PEG and PEO are liquids or low-melting solids, depending on their molecular weights. PEGs are prepared by polymerization of ethylene oxide and are commercially available over a wide range of molecular weights from 300 g/mol to 10,000,000 g/mol. While PEG and PEO with different molecular weights find use in different applications, and have different physical properties (e.g. viscosity) due to chain length effects, their chemical properties are nearly identical. Different forms of PEG are also available, depending on the initiator used for the polymerization process—the most common initiator is a monofunctional methyl ether PEG, or methoxypoly(ethylene glycol), abbreviated mPEG. Lower-molecular-weight PEGs are also available as purer oligomers, referred to as monodisperse, uniform, or discrete PEGs are also available with different geometries.

As used herein, PEG is intended to be inclusive and not exclusive. In some embodiments, PEG includes poly(ethylene glycol) in any of its forms, including alkoxy PEG, difunctional PEG, multiarmed PEG, forked PEG, branched PEG, pendent PEG (i.e., PEG or related polymers having one or more functional groups pendent to the polymer backbone), or PEG With degradable linkages therein. Further, a PEG backbone can be linear or branched. Branched polymer backbones are generally known in the art. Typically, a branched polymer has a central branch core moiety and a plurality of linear polymer chains linked to the central branch core. PEG is commonly used in branched forms that can be prepared by addition of ethylene oxide to various polyols, such as glycerol, pentaerythritol and sorbitol. The central branch moiety can also be derived from several amino acids, such as lysine. The branched poly(ethylene glycol) can be represented in general form as R(-PEG-OH)m in which R represents the core moiety, such as glycerol or pentaerythritol, and m represents the number of arms. Multi-armed PEG molecules, such as those described in U.S. Pat. No. 5,932,462, which is incorporated by reference herein in its entirety, can also be used as biocompatible polymers.

Some exemplary PEGs include, but are not limited to, PEG20, PEG30, PEG40, PEG60, PEG80, PEG100, PEG115, PEG200, PEG 300, PEG400, PEG500, PEG600, PEG1000, PEG1500, PEG2000, PEG3350, PEG4000, PEG4600, PEG5000, PEG6000, PEG8000, PEG11000, PEG12000, PEG15000, PEG 20000, PEG250000, PEG500000, PEG100000, PEG2000000 and the like. In some embodiments, PEG is of MW 10,000 Dalton. In some embodiments, PEG is of MW 100,000, i.e. PEO of MW 100,000.

In some embodiments, a polymer is a biodegradable polymer. As used herein, “biodegradable” describes a material which can decompose under physiological conditions into breakdown products. Such physiological conditions include, for example, hydrolysis (decomposition via hydrolytic cleavage), enzymatic catalysis (enzymatic degradation), and mechanical interactions. As used herein, “biodegradable” also encompasses “bioresorbable”, which describes a substance that decomposes under physiological conditions to break down to products that undergo bioresorption into the host-organism, namely, become metabolites of the biochemical systems of the host organism.

As used herein, “bioresorbable” and “bioresorption” encompass processes such as cell-mediated degradation, enzymatic degradation and/or hydrolytic degradation of the bioresorbable polymer, and/or elimination of the bioresorbable polymer from living tissue as will be appreciated by the person skilled in the art.

“Biodegradable polymer”, as used herein, refers to a polymer that at least a portion thereof decomposes under physiological conditions. A polymer can thus be partially decomposed or fully decomposed under physiological conditions.

Exemplary biodegradable polymers include, but are not limited to, polyanhydrides, polyhydroxybutyric acid, polyorthoesters, polysiloxanes, polycaprolactone, poly(lactic-co-glycolic acid), poly(lactic acid), poly(glycolic acid), and copolymers prepared from the monomers of these polymers.

In some embodiments, additives, agents, or functional moieties include a bioinert material. As used herein, a “bioinert” material refers to any material that once placed in vivo has minimal interaction with its surrounding tissue. Exemplary bioinert materials include, but are not limited to, gold, stainless steel, titanium, alumina, partially stabilized zirconia, and ultra-high molecular weight polyethylene.

In some embodiments, additives, agents, or functional moieties can be a silk fibroin particle or powder. Various methods of producing silk fibroin particles (e.g., nanoparticles and microparticles) are known in the art. See for example, PCT Publication No. WO 2011/041395 and No. WO 2008/118133; U.S. App. Pub. No. U.S. 2010/0028451; U.S. Provisional Application Ser. No. 61/719,146, filed Oct. 26, 2012; and Wenk et al. J Control Release, Silk fibroin spheres as a platform for controlled drug delivery, 2008; 132: 26-34, content of all of which is incorporated herein by reference in their entirety.

In some embodiments, additives, agents, or functional moieties include silk fibroin fiber. In some embodiments, silk fibroin fibers could be chemically attached by redissolving part of the fiber in HFIP and attaching to stent. Use of silk fibroin fibers is described in, for example, US patent application publication no. US20110046686, content of which is incorporated herein by reference.

In some embodiments, silk fibroin fibers are microfibers or nanofibers. In some embodiments, additives, agents, or functional moieties are micron-sized silk fibroin fiber (10-600 μm). Micron-sized silk fibroin fibers can be obtained by hydrolyzing degummed silk fibroin or by increasing a boiling time of a degumming process. Alkali hydrolysis of silk fibroin to obtain micron-sized silk fibroin fibers is described for example in Mandal et al., PNAS, 2012, doi: 10.1073/pnas.1119474109; U.S. Provisional Application No. 61/621,209, filed Apr. 6, 2012; and PCT application no. PCT/US13/35389, filed Apr. 5, 2013, content of all of which is incorporated herein by reference. Because regenerated silk fibroin fibers made from HFIP silk fibroin solutions are mechanically strong, the regenerated silk fibroin fibers can also be used as additive.

In some embodiments, silk fibroin fiber is an unprocessed silk fibroin fiber unprocessed silk fibroin fiber is meant silk fibroin, obtained directly from the silk fibroin gland. When silk fibroin, obtained directly from the silk fibroin gland, is allowed to dry, the structure is referred to as silk fibroin I in the solid state. Thus, an unprocessed silk fibroin fiber includes silk fibroin mostly in the silk fibroin I conformation. A regenerated or processed silk fibroin fiber on the other hand includes silk fibroin having a substantial silk fibroin II or beta-sheet crystallinity.

In some embodiments, a conformation of the fibroin in a stent can be altered before, during or after its formation. Induced conformational change alters silk fibroin crystallinity, e.g., Silk fibroin II beta-sheet crystallinity. Without wishing to be bound by a theory, it is believed that degradation of the bulk material or optional release of an additive (e.g., an active agent) from the bulk material varies with the beta-sheet content of the silk fibroin. Conformational change can be induced by any methods known in the art, including, but not limited to, alcohol immersion (e.g., ethanol, methanol), water annealing, shear stress (e.g., by vortexing), ultrasound (e.g., by sonication), pH reduction (e.g., pH titration and/or exposure to an electric field) and any combinations thereof. For example, a conformational change can be induced by one or more methods, including but not limited to, controlled slow drying (Lu et al., 10 Biomacromolecules 1032 (2009)); water annealing (Jin et al., Water-Stable Silk fibroin Films with Reduced β-Sheet Content, 15 Adv. Funct. Mats. 1241 (2005); Hu et al. Regulation of Silk fibroin Material Structure by Temperature-Controlled Water Vapor Annealing, 12 Biomacromolecules 1686 (2011)); stretching (Demura & Asakura, Immobilization of glucose oxidase with Bombyx mori silk fibroin by only stretching treatment and its application to glucose sensor, 33 Biotech & Bioengin. 598 (1989)); compressing; solvent immersion, including methanol (Hofmann et al., Silk fibroin as an organic polymer for controlled drug delivery, 111 J Control Release. 219 (2006)), ethanol (Miyairi et al., Properties of b-glucosidase immobilized in sericin membrane. 56 J. Fermen. Tech. 303 (1978)), glutaraldehyde (Acharya et al., Performance evaluation of a silk fibroin protein-based matrix for the enzymatic conversion of tyrosine to L-DOPA. 3 Biotechnol J. 226 (2008)), and 1-ethyl-3-(3-dimethyl aminopropyl) carbodiimide (EDC) (Bayraktar et al., Silk fibroin as a novel coating material for controlled release of theophylline. 60 Eur J Pharm Biopharm. 373 (2005)); pH adjustment, e.g., pH titration and/or exposure to an electric field (see, e.g., U.S. Patent App. No. US2011/0171239); heat treatment; shear stress (see, e.g., International App. No.: WO 2011/005381), ultrasound, e.g., sonication (see, e.g., U.S. Patent Application Publication No. U.S. 2010/0178304 and International App. No. WO2008/150861); and any combinations thereof. Content of all of the references listed above is incorporated herein by reference in their entirety.

In some embodiments, an additive, agent, and/or functional moiety is a plasticizer. As used herein, a “plasticizer” is intended to designate a compound or a mixture of compounds that can increase flexibility, processability and extensibility of the polymer in which it is incorporated. In some embodiments, a plasticizer can reduce the viscosity of the melt, lower the second order transition temperatures and the elastic modulus of the product. In some embodiments, suitable plasticizers include, but are not limited to, low molecular weight polyols having aliphatic hydroxyls such as ethylene glycol; propylene glycol; propanetriol (i.e., glycerol); glyceryl monostearate; 1,2-butylene glycol; 2,3-butylene glycol; styrene glycol; polyethylene glycols such as diethylene glycol, triethylene glycol, tetraethylene glycol and other polyethylene glycols having a molecular weight of about 1,000 or less; polypropylene glycols of molecular weight 200 or less; glycol ethers such as monopropylene glycol monoisopropyl ether; propylene glycol monoethyl ether; ethylene glycol monoethyl ether; diethylene glycol monoethyl ether; ester-type plasticizers such as sorbitol lactate, ethyl lactate, butyl lactate, ethyl glycolate, allyl glycolate; and amines such as monoethanolamine, diethanolamine, triethanolamine, monisopropanolamine, triethylenetetramine, 2-amino-2-methyl-1,3-propanediol, polymers and the like. In one embodiment, the plasticizer can include glycerol.

In some embodiments, plasticizers may be included in a silk formulation to augment properties or add new functionality. In some embodiments, an addition of 1-50% glycerol increased elasticity and compliance of such a stent. Specifically, a glycerol concentration of 5-10% by weight is most advantageous mechanical properties for this application. Lower concentrations of glycerol do no result in a detectable increase in elasticity, while higher concentrations compromise the stiffness of the stents. In some embodiments, glycerol is diluted with deionized water before being added to the silk solution. In some embodiments, glycerol solution concentrations of 350 mg/mL or lower, may induce gelation when added to silk. In some embodiments, such concentrations makes it nearly impossible to homogenize a solution, and to add in an accurate amount of glycerol. In some embodiments, a glycerol solution concentration of 700 mg/mL is preferred. In some embodiments, once added, a silk/glycerol solution is mixed by gentle inversion, aggressive sonication or vortex mixing can cause preemptive gelation.

In some embodiments, provided silk fibroin tracheal stents include additives, agents, and/or functional moieties, for example, therapeutic, preventative, and/or diagnostic agents.

In some embodiments, a therapeutic agent can be selected from the group consisting of anti-infectives, chemotherapeutic agents, anti-rejection agents, analgesics and analgesic combinations, anti-inflammatory agents, hormones, growth factors, antibiotics, antiviral agents, steroids, bone morphogenic proteins, bone morphogenic-like proteins, epidermal growth factor, fibroblast growth factor, platelet derived growth factor (PDGF), insulin-like growth factor, transforming growth factors, vascular endothelial growth factor, and any combinations thereof.

In some embodiments, an additive is or includes one or more therapeutic agents. In general, a therapeutic agent is or includes a small molecule and/or organic compound with pharmaceutical activity (e.g., activity that has been demonstrated with statistical significance in one or more relevant pre-clinical models or clinical settings). In some embodiments, a therapeutic agent is a clinically-used drug. In some embodiments, a therapeutic agent is or includes an cells, proteins, peptides, nucleic acid analogues, nucleotides, oligonucleotides, nucleic acids (DNA, RNA, siRNA), peptide nucleic acids, aptamers, antibodies or fragments or portions thereof, anesthetic, anticoagulant, anti-cancer agent, inhibitor of an enzyme, steroidal agent, anti-inflammatory agent, anti-neoplastic agent, antigen, vaccine, antibody, decongestant, antihypertensive, sedative, birth control agent, progestational agent, anti-cholinergic, analgesic, anti-depressant, anti-psychotic, β-adrenergic blocking agent, diuretic, cardiovascular active agent, vasoactive agent, anti-glaucoma agent, neuroprotectant, angiogenesis inhibitor, hormones, hormone antagonists, growth factors or recombinant growth factors and fragments and variants thereof, cytokines, enzymes, antibiotics or antimicrobial compounds, antifungals, antivirals, toxins, prodrugs, chemotherapeutic agents, small molecules, drugs (e.g., drugs, dyes, amino acids, vitamins, antioxidants), pharmacologic agents, and combinations thereof.

In some embodiments, an additive, agent, and/or functional moiety is a therapeutic agent. A “therapeutic agent” refers to a biological or chemical agent used for treating, curing, mitigating, or preventing deleterious conditions in a subject. “Therapeutic agent” also includes substances and agents for combating a disease, condition, or disorder of a subject, and includes drugs, diagnostics, and instrumentation. “Therapeutic agent” also includes anything used in medical diagnosis, or in restoring, correcting, or modifying physiological functions. “Therapeutic agent” and “pharmaceutically active agent” are used interchangeably herein.

A therapeutic agent is selected according to the treatment objective and biological action desired. General classes of therapeutic agents include anti-microbial agents such as adrenergic agents, antibiotic agents or antibacterial agents, antiviral agents, anthelmintic agents, anti-inflammatory agents, antineoplastic agents, antioxidant agents, biological reaction inhibitors, botulinum toxin agents, chemotherapy agents, contrast imaging agents, diagnostic agents, gene therapy agents, hormonal agents, mucolytic agents, radioprotective agents, radioactive agents including brachytherapy materials, tissue growth inhibitors, tissue growth enhancers, and vasoactive agents. Therapeutic agent can be selected from any class suitable for the therapeutic objective. In some embodiments, a therapeutic agent is an antithrombotic or fibrinolytic agent selected from the group consisting of anticoagulants, anticoagulant antagonists, antiplatelet agents, thrombolytic agents, thrombolytic agent antagonists, and any combinations thereof.

In some embodiments, a therapeutic agent is thrombogenic agent selected from the group consisting of thrombolytic agent antagonists, anticoagulant antagonists, pro-coagulant enzymes, pro-coagulant proteins, and any combinations thereof. Some exemplary thrombogenic agents include, but are not limited to, protamines, vitamin K1, amiocaproic acid (amicar), tranexamic acid (amstat), anagrelide, argatroban, cilstazol, daltroban, defibrotide, enoxaparin, fraxiparine, indobufen, lamoparan, ozagrel, picotamide, plafibride, tedelparin, ticlopidine, triflusal, collagen, and collagen-coated particles.

In some embodiments, a therapeutic agent is a vasodilator. A vasodilator can be selected from the group consisting of alpha-adrenoceptor antagonists (alpha-blockers), agiotensin converting enzyme (ACE) inhibitors, angiotensin receptor blockers (ARBs), beta2-adrenoceptor agonists (β2-agonists), calcium-channel blockers (CCBs), centrally acting sympatholytics, direct acting vasodilators, endothelin receptor antagonists, ganglionic blockers, nitrodilators, phosphodiesterase inhibitors, potassium-channel openers, renin inhibitors, and any combinations thereof. Exemplary vasodilator include, but are not limited to, prazosin, terazosin, doxazosin, trimazosin, phentolamine, phenoxybenzamine, benazepril, captopril, enalapril, fosinopril, lisinopril, moexipril, quinapril, ramipril, candesartan, eprosartan, irbesartan, losartan, olmesartan, telmisartan, valsartan, Epinephrine, Norepinephrine, Dopamine, Dobutamine, Isoproterenol, amlodipine, felodipine, isradipine, nicardipine, nifedipine, nimodipine, nitrendipine, clonidine, guanabenz, guanfacine, α-methyldopa, hydralazine, Bosentan, trimethaphan camsylate, isosorbide dinitrate, isosorbide mononitrate, nitroglycerin, erythrityl tetranitrate, pentaerythritol tetranitrate, sodium nitroprusside, milrinone, inamrinone (formerly amrinone), cilostazol, sildenafil, tadalafil, minoxidil, aliskiren, nitric oxide, sodium nitrite, nitroglycerin, and analogs, derivatives, prodrugs, and pharmaceutically acceptable salts thereof.

Exemplary pharmaceutically active compound include, but are not limited to, those found in Harrison's Principles of Internal Medicine, 13th Edition, Eds. T. R. Harrison et al. McGraw-Hill N.Y., NY; Physicians' Desk Reference, 50th Edition, 1997, Oradell N.J., Medical Economics Co.; Pharmacological Basis of Therapeutics, 8th Edition, Goodman and Gilman, 1990; United States Pharmacopeia, The National Formulary, USP XII NF XVII, 1990; current edition of Goodman and Oilman's The Pharmacological Basis of Therapeutics; and current edition of The Merck Index, the complete content of all of which are herein incorporated in its entirety.

In some embodiments, active agents can be selected from small organic or inorganic molecules; saccharines; oligosaccharides; polysaccharides; biological macromolecules; peptides; proteins; peptide analogs and derivatives; peptidomimetics; antibodies and antigen binding fragments thereof; nucleic acids; nucleic acid analogs and derivatives; glycogens or other sugars; immunogens; antigens; an extract made from biological materials such as bacteria, plants, fungi, or animal cells; animal tissues; naturally occurring or synthetic compositions; and any combinations thereof. The active agent can be hydrophobic, hydrophilic, or amphiphilic.

Small molecules can refer to compounds that are “natural product-like,” however, the term “small molecule” is not limited to “natural product-like” compounds. Rather, a small molecule is typically characterized in that it contains several carbon-carbon bonds, and has a molecular weight of less than 5000 Daltons (5 kD), preferably less than 3 kD, still more preferably less than 2 kD, and most preferably less than 1 kD. In some cases it is highly preferred that a small molecule have a molecular mass equal to or less than 700 Daltons.

In some embodiments, possible additives, agents, or functional moieties are soluble drugs that could be released into a local environment as the stent degrades, growth factors to stimulate local tissue regeneration, cell adhesion proteins to promote cellular infiltration, cleavable crosslinkers to further control degradation, or patient derived cells.

In some embodiments, a stent includes a biologically active agent. As used herein, “biological activity” or “bioactivity” refers to the ability of a molecule or composition to affect a biological sample. Biological activity can include, without limitation, elicitation of a stimulatory, inhibitory, regulatory, toxic or lethal response in a biological assay. For example, a biological activity can refer to the ability of a compound to modulate the effect/activity of an enzyme, block a receptor, stimulate a receptor, modulate the expression level of one or more genes, modulate cell proliferation, modulate cell division, modulate cell morphology, or any combination thereof. In some instances, a biological activity can refer to the ability of a compound to produce a toxic effect in a biological sample. A stent including an active agent can be formulated by mixing one or more active agents with the silk fibroin-fibroin solution used to make the stent.

Examples of biologically active compounds include, but are not limited to: cell attachment mediators, such as collagen, elastin, fibronectin, vitronectin, laminin, proteoglycans, or peptides containing known integrin binding domains e.g. “RGD” integrin binding sequence, or variations thereof, that are known to affect cellular attachment (Schaffner P & Dard, Cell Mol Life Sci, 2003, 60(1):119-32 and Hersel U. et al., Biomaterials, 2003, 24(24):4385-415); YIGSR peptides; biologically active ligands; and substances that enhance or exclude particular varieties of cellular or tissue ingrowth.

In some embodiments, an active agent is an anti-restenosis or restenosis inhibiting agent. Suitable anti-restenosis agents include: (1) antiplatelet agents including: (a) thrombin inhibitors and receptor antagonists, (b) adenosine disphosphate (ADP) receptor antagonists (also known as purinoceptor₁ receptor antagonists), (c) thromboxane inhibitors and receptor antagonists and (d) platelet membrane glycoprotein receptor antagonists; (2) inhibitors of cell adhesion molecules, including (a) selectin inhibitors and (b) integrin inhibitors; (3) anti-chemotactic agents; (4) interleukin receptor antagonists (which also serve as anti-pain/anti-inflammation agents); and (5) intracellular signaling inhibitors including: (a) protein kinase C (PKC) inhibitors and protein tyrosine kinase inhibitors, (b) modulators of intracellular protein tyrosine phosphatases, (c) inhibitors of src homology₂ (SH2) domains, and (d) calcium channel antagonists. Exemplary specific restenosis-inhibiting agents include microtubule stabilizing agents such as rapamycin, mitomycin C, TAXOL®, paclitaxel (i.e., paclitaxel, paxlitaxel analogs, or paclitaxel derivatives, and mixtures thereof). For example, derivatives suitable for use in the stent include 2′-succinyl-taxol, 2′-succinyl-taxol triethanolamine, 2′-glutaryl-taxol, 2′-glutaryl-taxol triethanolamine salt, 2′-O-ester with N-(dimethylaminoethyl) glutamine, and 2′-O-ester with N-(dimethylaminoethyl) glutamide hydrochloride salt.

In some embodiments, an active agent is an anti-coagulation agent. As used herein, “anti-coagulation agent” refers to any molecule or composition that promotes blood coagulation or activates the blood coagulation cascade or a portion thereof. Exemplary anti-coagulation agents include, for example, phospholipids such as, e.g., negatively charged phospholipids; lipoproteins such as, e.g., thromboplastin, and the like; proteins such as tissue factor, activated serin proteases such as Factors IIa (thrombin), VII, VIIa, VIII, IX, IXa, Xa, XIa, XII, XIIa, von Willebrand factor (vWF), protein C, snake venoms such as PROTAC® enzyme, Ecarin, Textarin, Noscarin, Batroxobin, Thrombocytin, Russell's viper venom (RVV), and the like; polyvalent cations; calcium ions; tissue factor; silica; kaolin; bentonite; diatomaceous earth; ellagic acid; celite; and any mixtures thereof.

In some embodiments, provided stents include for example, antibiotics. Antibiotics suitable for incorporation in stents include, but are not limited to, aminoglycosides (e.g., neomycin), ansamycins, carbacephem, carbapenems, cephalosporins (e.g., cefazolin, cefaclor, cefditoren, cefditoren, ceftobiprole), glycopeptides (e.g., vancomycin), macrolides (e.g., erythromycin, azithromycin), monobactams, penicillins (e.g., amoxicillin, ampicillin, cloxacillin, dicloxacillin, flucloxacillin), polypeptides (e.g., bacitracin, polymyxin B), quinolones (e.g., ciprofloxacin, enoxacin, gatifloxacin, ofloxacin, etc.), sulfonamides (e.g., sulfasalazine, trimethoprim, trimethoprim-sulfamethoxazole (co-trimoxazole)), tetracyclines (e.g., doxycyline, minocycline, tetracycline, etc.), chloramphenicol, lincomycin, clindamycin, ethambutol, mupirocin, metronidazole, pyrazinamide, thiamphenicol, rifampicin, thiamphenicl, dapsone, clofazimine, quinupristin, metronidazole, linezolid, isoniazid, fosfomycin, fusidic acid, β-lactam antibiotics, rifamycins, novobiocin, fusidate sodium, capreomycin, colistimethate, gramicidin, doxycycline, erythromycin, nalidixic acid, and vancomycin. For example, β-lactam antibiotics can be aziocillin, aztreonam, carbenicillin, cefoperazone, ceftriaxone, cephaloridine, cephalothin, moxalactam, piperacillin, ticarcillin and combination thereof.

In some embodiments, provided stents include for example, anti-inflammatories. Anti-inflammatory agents may include corticosteroids (e.g., glucocorticoids), cycloplegics, non-steroidal anti-inflammatory drugs (NSAIDs), immune selective anti-inflammatory derivatives (ImSAIDs), and any combination thereof. Exemplary NSAIDs include, but not limited to, celecoxib (Celebrex®); rofecoxib (Vioxx®), etoricoxib (Arcoxia®), meloxicam (Mobic®), valdecoxib, diclofenac (Voltaren®, Cataflam®), etodolac (Lodine®), sulindac (Clinori®), aspirin, alclofenac, fenclofenac, diflunisal (Dolobid®), benorylate, fosfosal, salicylic acid including acetylsalicylic acid, sodium acetylsalicylic acid, calcium acetylsalicylic acid, and sodium salicylate; ibuprofen (Motrin), ketoprofen, carprofen, fenbufen, flurbiprofen, oxaprozin, suprofen, triaprofenic acid, fenoprofen, indoprofen, piroprofen, flufenamic, mefenamic, meclofenamic, niflumic, salsalate, rolmerin, fentiazac, tilomisole, oxyphenbutazone, phenylbutazone, apazone, feprazone, sudoxicam, isoxicam, tenoxicam, piroxicam (Feldene®), indomethacin (Indocin®), nabumetone (Relafen®), naproxen (Naprosyn®), tolmetin, lumiracoxib, parecoxib, licofelone (ML3000), including pharmaceutically acceptable salts, isomers, enantiomers, derivatives, prodrugs, crystal polymorphs, amorphous modifications, co-crystals and combinations thereof.

In some embodiments, additives, agents, and/or functional moieties include a nitric oxide or a prodrug thereof.

In some embodiments, provided stents include, for example, polypeptides (e.g., proteins), including but are not limited to: one or more antigens, cytokines, hormones, chemokines, enzymes, and any combination thereof as an agent and/or functional group. Exemplary enzymes suitable for use herein include, but are not limited to, peroxidase, lipase, amylose, organophosphate dehydrogenase, ligases, restriction endonucleases, ribonucleases, DNA polymerases, glucose oxidase, laccase, and the like.

In some embodiments, provided stents include, for example, antibodies. Suitable antibodies for incorporation in stents include, but are not limited to, abciximab, adalimumab, alemtuzumab, basiliximab, bevacizumab, cetuximab, certolizumab pegol, daclizumab, eculizumab, efalizumab, gemtuzumab, ibritumomab tiuxetan, infliximab, muromonab-CD3, natalizumab, ofatumumab omalizumab, palivizumab, panitumumab, ranibizumab, rituximab, tositumomab, trastuzumab, altumomab pentetate, arcitumomab, atlizumab, bectumomab, belimumab, besilesomab, biciromab, canakinumab, capromab pendetide, catumaxomab, denosumab, edrecolomab, efungumab, ertumaxomab, etaracizumab, fanolesomab, fontolizumab, gemtuzumab ozogamicin, golimumab, igovomab, imciromab, labetuzumab, mepolizumab, motavizumab, nimotuzumab, nofetumomab merpentan, oregovomab, pemtumomab, pertuzumab, rovelizumab, ruplizumab, sulesomab, tacatuzumab tetraxetan, tefibazumab, tocilizumab, ustekinumab, visilizumab, votumumab, zalutumumab, and zanolimumab.

In some embodiments, an active agent is an enzyme that hydrolyzes silk fibroin. Without wishing to be bound by a theory, such enzymes can be used to control degradation of a stent after implantation into a subject. Controlled degradation of silk fibroin-fibroin based scaffolds with enzymes embedded therein is described in, for example, U.S. Provisional Application No. 61/791,501, filed Mar. 15, 2013, content of which is incorporated herein by reference in its entirety.

In some embodiments, the bulk material of the stent can include a cell. Stent with the bulk material comprising a cell can be used for organ repair, organ replacement or regeneration. Cells amenable to be incorporated into the composition include, but are not limited to, stem cells (embryonic stem cells, mesenchymal stem cells, neural stem cells, bone-marrow derived stem cells, hematopoietic stem cells, and induced pluripotent stem cells); pluripotent cells; chrondrocytes progenitor cells; pancreatic progenitor cells; myoblasts; fibroblasts; chondrocytes; keratinocytes; neuronal cells; glial cells; astrocytes; pre-adipocytes; adipocytes; vascular endothelial cells; hair follicular stem cells; endothelial progenitor cells; mesenchymal cells; smooth muscle progenitor cells; osteocytes; parenchymal cells such as hepatocytes; pancreatic cells (including Islet cells); cells of intestinal origin; and combination thereof, either as obtained from donors, from established cell culture lines, or even before or after molecular genetic engineering. Without limitations, the cells useful for incorporation into the composition can come from any source, for example human, rat or mouse. In some embodiments, the cell can from a subject into which the stent is to be implanted.

In some embodiments, a cell is a genetically modified cell. A cell can be genetically modified to express and secrete a desired compound, e.g. a bioactive agent, a growth factor, differentiation factor, cytokines, and the like. Methods of genetically modifying cells for expressing and secreting compounds of interest are known in the art and easily adaptable by one of skill in the art.

In some embodiments, differentiated cells that have been reprogrammed into stem cells can also be used. For example, human skin cells reprogrammed into embryonic stem cells by the transduction of Oct3/4, Sox2, c-Myc and Klf4 (Junying Yu, et. al., Science, 2007, 318, 1917-1920 and Takahashi K. et. al., Cell, 2007, 131, 1-12).

In some embodiments, when using a stent with cells, it can be desirable to add other materials to promote the growth, differentiation or proliferation of the cell. Exemplary materials known to promote cell growth include, but not limited to, cell growth media, such as Dulbecco's Modified Eagle Medium (DMEM), fetal bovine serum (FBS), non-essential amino acids and antibiotics, and growth and morphogenic factors such as fibroblast growth factor (e.g., FGF 1-9), transforming growth factors (TGFs), vascular endothelial growth factor (VEGF), epidermal growth factor (EGF), platelet derived growth factor (PDGF), insulin-like growth factor (IGF-I and IGF-II), bone morphogenetic growth factors (e.g., BMPs 1-7), bone morphogenetic-like proteins (e.g., GFD-5, GFD-7, and GFD-8), transforming growth factors (e.g., TGF-α, TGF-β nerve growth factors, and related proteins. Growth factors are known in the art, see, e.g., Rosen & Thies, CELLULAR & MOL. BASIS BONE FORMATION & REPAIR (R. G. Landes Co.).

In some embodiments, cells suitable for use herein include, but are not limited to, progenitor cells or stem cells, smooth muscle cells, skeletal muscle cells, cardiac muscle cells, epithelial cells, endothelial cells, urothelial cells, fibroblasts, myoblasts, chondrocytes, chondroblasts, osteoblasts, osteoclasts, keratinocytes, hepatocytes, bile duct cells, pancreatic islet cells, thyroid, parathyroid, adrenal, hypothalamic, pituitary, ovarian, testicular, salivary gland cells, adipocytes, and precursor cells.

In some embodiments, provided stents include, for example, organisms, such as, a bacterium, fungus, plant or animal, or a virus. In some embodiments, an active agent may include or be selected from neurotransmitters, hormones, intracellular signal transduction agents, pharmaceutically active agents, toxic agents, agricultural chemicals, chemical toxins, biological toxins, microbes, and animal cells such as neurons, liver cells, and immune system cells. The active agents may also include therapeutic compounds, such as pharmacological materials, vitamins, sedatives, hypnotics, prostaglandins and radiopharmaceuticals.

In some embodiments, provided stents include, for example, agents useful for wound healing include stimulators, enhancers or positive mediators of the wound healing cascade which 1) promote or accelerate the natural wound healing process or 2) reduce effects associated with improper or delayed wound healing, which effects include, for example, adverse inflammation, epithelialization, angiogenesis and matrix deposition, and scarring and fibrosis.

In some embodiments, provided stents include, for example, an optically or electrically active agent, including but not limited to, chromophores; light emitting organic compounds such as luciferin, carotenes; light emitting inorganic compounds, such as chemical dyes; light harvesting compounds such as chlorophyll, bacteriorhodopsin, protorhodopsin, and porphyrins; light capturing complexes such as phycobiliproteins; and related electronically active compounds; and combinations thereof.

Without wishing to be bound by a theory, incorporating an active agent in a bulk material of a stent enables delivery of an active agent in a controlled released manner. Maintaining an active agent in an active form throughout in the silk fibroin-fibroin matrix enables it to be active upon release from the stent. Controlled release of active agent permits active agent to be released sustainably over time, with controlled release kinetics. In some embodiments, an active agent is delivered continuously to the site where treatment is needed, for example, over several weeks. Controlled release over time, for example, over several days or weeks, or longer, permits continuous delivery of the bioactive agent to obtain preferred treatments. In some embodiments, controlled delivery is advantageous because it protects bioactive agents from degradation in vivo in body fluids and tissue, for example, by proteases.

Controlled release of an active agent from the stent can be designed to occur over time, for example, over 12 hours or 24 hours. Time of release may be selected, for example, to occur over a time period of about 12 hours to 24 hours; about 12 hours to 42 hours; or, e.g., about 12 to 72 hours. In another embodiment, release can occur for example on the order of about 1 day to 15 days. Controlled release time can be selected based on the condition treated. For example, longer times can be more effective for wound healing, whereas shorter delivery times can be more useful for some cardiovascular applications.

Controlled release of an active agent from a stent in vivo can occur, for example, in the amount of about 1 ng to 1 mg/day. In some embodiments, controlled release can occur in the amount of about 50 ng to 500 ng/day, about 75 ng to 250 ng/day, about 100 ng to 200 ng/day, or about 125 ng to 175 ng/day.

In some embodiments, provided silk fibroin tracheal stents include additives, agents, and/or functional moieties at a total amount from about 0.01 wt % to about 99 wt %, from about 0.01 wt % to about 70 wt %, from about 5 wt % to about 60 wt %, from about 10 wt % to about 50 wt %, from about 15 wt % to about 45 wt %, or from about 20 wt % to about 40 wt %, of the total silk composition. In some embodiments, ratio of silk fibroin to additive in the composition can range from about 1000:1 (w/w) to about 1:1000 (w/w), from about 500:1 (w/w) to about 1:500 (w/w), from about 250:1 (w/w) to about 1:250 (w/w), from about 200:1 (w/w) to about 1:200 (w/w), from about 25:1 (w/w) to about 1:25 (w/w), from about 20:1 (w/w) to about 1:20 (w/w), from about 10:1 (w/w) to about 1:10 (w/w), or from about 5:1 (w/w) to about 1:5 (w/w).

In some embodiments, provided silk fibroin tracheal stents include additives, agents, and/or functional moieties at a molar ratio relative to polymer (i.e., a polymer:additive ratio) of, e.g., at least 1000:1, at least 900:1, at least 800:1, at least 700:1, at least 600:1, at least 500:1, at least 400:1, at least 300:1, at least 200:1, at least 100:1, at least 90:1, at least 80:1, at least 70:1, at least 60:1, at least 50:1, at least 40:1, at least 30:1, at least 20:1, at least 10:1, at least 7:1, at least 5:1, at least 3:1, at least 1:1, at least 1:3, at least 1:5, at least 1:7, at least 1:10, at least 1:20, at least 1:30, at least 1:40, at least 1:50, at least 1:60, at least 1:70, at least 1:80, at least 1:90, at least 1:100, at least 1:200, at least 1:300, at least 1:400, at least 1:500, at least 600, at least 1:700, at least 1:800, at least 1:900, or at least 1:100.

In some embodiments, moiety polymer:additive ratio is, e.g., at most 1000:1, at most 900:1, at most 800:1, at most 700:1, at most 600:1, at most 500:1, at most 400:1, at most 300:1, at most 200:1, 100:1, at most 90:1, at most 80:1, at most 70:1, at most 60:1, at most 50:1, at most 40:1, at most 30:1, at most 20:1, at most 10:1, at most 7:1, at most 5:1, at most 3:1, at most 1:1, at most 1:3, at most 1:5, at most 1:7, at most 1:10, at most 1:20, at most 1:30, at most 1:40, at most 1:50, at most 1:60, at most 1:70, at most 1:80, at most 1:90, at most 1:100, at most 1:200, at most 1:300, at most 1:400, at most 1:500, at most 1:600, at most 1:700, at most 1:800, at most 1:900, or at most 1:1000.

In some embodiments, moiety polymer:additive ratio is, e.g., from about 1000:1 to about 1:1000, from about 900:1 to about 1:900, from about 800:1 to about 1:800, from about 700:1 to about 1:700, from about 600:1 to about 1:600, from about 500:1 to about 1:500, from about 400:1 to about 1:400, from about 300:1 to about 1:300, from about 200:1 to about 1:200, from about 100:1 to about 1:100, from about 90:1 to about 1:90, from about 80:1 to about 1:80, from about 70:1 to about 1:70, from about 60:1 to about 1:60, from about 50:1 to about 1:50, from about 40:1 to about 1:40, from about 30:1 to about 1:30, from about 20:1 to about 1:20, from about 10:1 to about 1:10, from about 7:1 to about 1:7, from about 5:1 to about 1:5, from about 3:1 to about 1:3, or about 1:1.

In some embodiments, a ratio of silk fibroin to a total amount of additive, agent, and/or functional moiety in a bulk material can range from 100:1 to 1:100. For example, the ratio of silk fibroin to additive can range from 50:1 to 1:50, from 25:1 to 1:25, from 20:1 to 1:20, from 15:1 to 1:15, from 10:1 to 1:10, or from 5:1 to 1:5. In some embodiments, a ratio of silk fibroin to additive, agent, and/or functional moiety can be from 5:1 to 1:1. In one embodiment, a ratio of silk fibroin to additive, agent, and/or functional moiety can be 3:1. A ratio can be molar ratio, weight ratio, or volume ratio.

A total amount of active agent in a bulk material can be from about 0.1 wt % to about 0.99 wt %, from about 0.1 wt % to about 70 wt %, from about 5 wt % to about 60 wt %, from about 10 wt % to about 50 wt %, from about 15 wt % to about 45 wt %, or from about 20 wt % to about 40 wt %, of a total weight of bulk material.

### Nucleic Acids

In some embodiments, provided stents include additives, for example, nucleic acid agents. In some embodiments, a stent may release nucleic acid agents. In some embodiments, a nucleic acid agent is or includes a therapeutic agent. In some embodiments, a nucleic acid agent is or includes a diagnostic agent. In some embodiments, a nucleic acid agent is or includes a prophylactic agent.

It would be appreciate by those of ordinary skill in the art that a nucleic acid agent can have a length within a broad range. In some embodiments, a nucleic acid agent has a nucleotide sequence of at least about 40, for example at least about 60, at least about 80, at least about 100, at least about 200, at least about 500, at least about 1000, or at least about 3000 nucleotides in length. In some embodiments, a nucleic acid agent has a length from about 6 to about 40 nucleotides. For example, a nucleic acid agent may be from about 12 to about 35 nucleotides in length, from about 12 to about 20 nucleotides in length or from about 18 to about 32 nucleotides in length.

In some embodiments, nucleic acid agents may be or include deoxyribonucleic acids (DNA), ribonucleic acids (RNA), peptide nucleic acids (PNA), morpholino nucleic acids, locked nucleic acids (LNA), glycol nucleic acids (GNA), threose nucleic acids (TNA), and/or combinations thereof.

In some embodiments, a nucleic acid has a nucleotide sequence that is or includes at least one protein-coding element. In some embodiments, a nucleic acid has a nucleotide sequence that is or includes at least one element that is a complement to a protein-coding sequence. In some embodiments, a nucleic acid has a nucleotide sequence that includes one or more gene expression regulatory elements (e.g., promoter elements, enhancer elements, splice donor sites, splice acceptor sites, transcription termination sequences, translation initiation sequences, translation termination sequences, etc.). In some embodiments, a nucleic acid has a nucleotide sequence that includes an origin of replication. In some embodiments, a nucleic acid has a nucleotide sequence that includes one or more integration sequences. In some embodiments, a nucleic acid has a nucleotide sequence that includes one or more elements that participate in intra- or inter-molecular recombination (e.g., homologous recombination). In some embodiments, a nucleic acid has enzymatic activity. In some embodiments, a nucleic acid hybridizes with a target in a cell, tissue, or organism. In some embodiments, a nucleic acid acts on (e.g., binds with, cleaves, etc.) a target inside a cell. In some embodiments, a nucleic acid is expressed in a cell after release from a provided composition. In some embodiments, a nucleic acid integrates into a genome in a cell after release from a provided composition.

In some embodiments, nucleic acid agents have single-stranded nucleotide sequences. In some embodiments, nucleic acid agents have nucleotide sequences that fold into higher order structures (e.g., double and/or triple-stranded structures). In some embodiments, a nucleic acid agent is or includes an oligonucleotide. In some embodiments, a nucleic acid agent is or includes an antisense oligonucleotide. Nucleic acid agents may include a chemical modification at the individual nucleotide level or at the oligonucleotide backbone level, or it may have no modifications.

In some embodiments of the present disclosure, a nucleic acid agent is an siRNA agent. Short interfering RNA (siRNA) includes an RNA duplex that is approximately 19 basepairs long and optionally further includes one or two single-stranded overhangs. An siRNA may be formed from two RNA molecules that hybridize together, or may alternatively be generated from a single RNA molecule that includes a self-hybridizing portion. It is generally preferred that free 5′ ends of siRNA molecules have phosphate groups, and free 3′ ends have hydroxyl groups. The duplex portion of an siRNA may, but typically does not, contain one or more bulges consisting of one or more unpaired nucleotides. One strand of an siRNA includes a portion that hybridizes with a target transcript. In certain preferred embodiments of the invention, one strand of the siRNA is precisely complementary with a region of the target transcript, meaning that the siRNA hybridizes to the target transcript without a single mismatch. In other embodiments of the invention one or more mismatches between the siRNA and the targeted portion of the target transcript may exist. In most embodiments of the invention in which perfect complementarity is not achieved, it is generally preferred that any mismatches be located at or near the siRNA termini.

Short hairpin RNA refers to an RNA molecule comprising at least two complementary portions hybridized or capable of hybridizing to form a double-stranded (duplex) structure sufficiently long to mediate RNAi (typically at least 19 base pairs in length), and at least one single-stranded portion, typically between approximately 1 and 10 nucleotides in length that forms a loop. The duplex portion may, but typically does not, contain one or more bulges consisting of one or more unpaired nucleotides. As described further below, shRNAs are thought to be processed into siRNAs by the conserved cellular RNAi machinery. Thus shRNAs are precursors of siRNAs and are, in general, similarly capable of inhibiting expression of a target transcript.

In describing siRNAs it will frequently be convenient to refer to sense and antisense strands of the siRNA. In general, the sequence of the duplex portion of the sense strand of the siRNA is substantially identical to the targeted portion of the target transcript, while the antisense strand of the siRNA is substantially complementary to the target transcript in this region as discussed further below. Although shRNAs contain a single RNA molecule that self-hybridizes, it will be appreciated that the resulting duplex structure may be considered to include sense and antisense strands or portions. It will therefore be convenient herein to refer to sense and antisense strands, or sense and antisense portions, of an shRNA, where the antisense strand or portion is that segment of the molecule that forms or is capable of forming a duplex and is substantially complementary to the targeted portion of the target transcript, and the sense strand or portion is that segment of the molecule that forms or is capable of forming a duplex and is substantially identical in sequence to the targeted portion of the target transcript.

For purposes of description, the discussion below may refer to siRNA rather than to siRNA or shRNA. However, as will be evident to one of ordinary skill in the art, teachings relevant to the sense and antisense strand of an siRNA are generally applicable to the sense and antisense portions of the stem portion of a corresponding shRNA. Thus in general the considerations below apply also to shRNAs.

An siRNA agent is considered to be targeted to a target transcript for the purposes described herein if 1) the stability of the target transcript is reduced in the presence of the siRNA or shRNA as compared with its absence; and/or 2) the siRNA or shRNA shows at least about 90%, more preferably at least about 91%, 92%, 93%, 94%, 95%, 96%, 97%, 98%, 99%, or 100% precise sequence complementarity with the target transcript for a stretch of at least about 15, more preferably at least about 17, yet more preferably at least about 18 or 19 to about 21-23 nucleotides; and/or 3) one strand of the siRNA or one of the self-complementary portions of the shRNA hybridizes to the target transcript under stringent conditions for hybridization of small (<50 nucleotide) RNA molecules in vitro and/or under conditions typically found within the cytoplasm or nucleus of mammalian cells. Since the effect of targeting a transcript is to reduce or inhibit expression of the gene that directs synthesis of the transcript, an siRNA, shRNA, targeted to a transcript is also considered to target the gene that directs synthesis of the transcript even though the gene itself (i.e., genomic DNA) is not thought to interact with the siRNA, shRNA, or components of the cellular silencing machinery. Thus in some embodiments, an siRNA, shRNA, that targets a transcript is understood to target the gene that provides a template for synthesis of the transcript.

In some embodiments, an siRNA agent can inhibit expression of a polypeptide (e.g., a protein). Exemplary polypeptides include, but are not limited to, matrix metallopeptidase 9 (MMP-9), neutral endopeptidase (NEP) and protein tyrosine phosphatase 1B (PTP1B).

### Growth Factor

In some embodiments, provided stents include additives, for example, growth factor. In some embodiments, a stent may release growth factor. In some embodiments, a stent may release multiple growth factors. In some embodiments growth factor known in the art include, for example, adrenomedullin, angiopoietin, autocrine motility factor, basophils, brain-derived neurotrophic factor, bone morphogenetic protein, colony-stimulating factors, connective tissue growth factor, endothelial cells, epidermal growth factor, erythropoietin, fibroblast growth factor, fibroblasts, glial cell line-derived neurotrophic factor, granulocyte colony stimulating factor, granulocyte macrophage colony stimulating factor, growth differentiation factor-9, hepatocyte growth factor, hepatoma-derived growth factor, insulin-like growth factor, interleukins, keratinocyte growth factor, keratinocytes, lymphocytes, macrophages, mast cells, myostatin, nerve growth factor, neurotrophins, platelet-derived growth factor, placenta growth factor, osteoblasts, platelets, proinflammatory, stromal cells, T-lymphocytes, thrombopoietin, transforming growth factor alpha, transforming growth factor beta, tumor necrosis factor-alpha, vascular endothelial growth factor and combinations thereof.

In some embodiments, provided stents include additives, for example, that are particularly useful for healing. Exemplary agents useful as growth factor for defect repair and/or healing can include, but are not limited to, growth factors for defect treatment modalities now known in the art or later-developed; exemplary factors, agents or modalities including natural or synthetic growth factors, cytokines, or modulators thereof to promote bone and/or tissue defect healing. Suitable examples may include, but not limited to 1) topical or dressing and related therapies and debriding agents (such as, for example, Santyl® collagenase) and Iodosorb® (cadexomer iodine); 2) antimicrobial agents, including systemic or topical creams or gels, including, for example, silver-containing agents such as SAGs (silver antimicrobial gels), (CollaGUARD™, Innocoll, Inc) (purified type-I collagen protein based dressing), CollaGUARD Ag (a collagen-based bioactive dressing impregnated with silver for infected wounds or wounds at risk of infection), DermaSIL™ (a collagen-synthetic foam composite dressing for deep and heavily exuding wounds); 3) cell therapy or bioengineered skin, skin substitutes, and skin equivalents, including, for example, Dermograft (3-dimensional matrix cultivation of human fibroblasts that secrete cytokines and growth factors), Apligraf® (human keratinocytes and fibroblasts), Graftskin® (bilayer of epidermal cells and fibroblasts that is histologically similar to normal skin and produces growth factors similar to those produced by normal skin), TransCyte (a Human Fibroblast Derived Temporary Skin Substitute) and Oasis® (an active biomaterial that includes both growth factors and extracellular matrix components such as collagen, proteoglycans, and glycosaminoglycans); 4) cytokines, growth factors or hormones (both natural and synthetic) introduced to the wound to promote wound healing, including, for example, NGF, NT3, BDGF, integrins, plasmin, semaphoring, blood-derived growth factor, keratinocyte growth factor, tissue growth factor, TGF-alpha, TGF-beta, PDGF (one or more of the three subtypes may be used: AA, AB, and B), PDGF-BB, TGF-beta 3, factors that modulate the relative levels of TGFβ3, TGFβ1, and TGFβ2 (e.g., Mannose-6-phosphate), sex steroids, including for example, estrogen, estradiol, or an oestrogen receptor agonist selected from the group consisting of ethinyloestradiol, dienoestrol, mestranol, oestradiol, oestriol, a conjugated oestrogen, piperazine oestrone sulphate, stilboestrol, fosfesterol tetrasodium, polyestradiol phosphate, tibolone, a phytoestrogen, 17-beta-estradiol; thymic hormones such as Thymosin-beta-4, EGF, HB-EGF, fibroblast growth factors (e.g., FGF1, FGF2, FGF7), keratinocyte growth factor, TNF, interleukins family of inflammatory response modulators such as, for example, IL-10, IL-1, IL-2, IL-6, IL-8, and IL-10 and modulators thereof; INFs (INF-alpha, -beta, and -delta); stimulators of activin or inhibin, and inhibitors of interferon gamma prostaglandin E2 (PGE2) and of mediators of the adenosine 3′,5′-cyclic monophosphate (cAMP) pathway; adenosine A1 agonist, adenosine A2 agonist or 5) other agents useful for wound healing, including, for example, both natural or synthetic homologues, agonist and antagonist of VEGF, VEGFA, IGF; IGF-1, proinflammatory cytokines, GM-CSF, and leptins and 6) IGF-1 and KGF cDNA, autologous platelet gel, hypochlorous acid (Sterilox® lipoic acid, nitric oxide synthase3, matrix metalloproteinase 9 (MMP-9), CCT-ETA, alphavbeta6 integrin, growth factor-primed fibroblasts and Decorin, silver containing wound dressings, Xenaderm™, papain wound debriding agents, lactoferrin, substance P, collagen, and silver-ORC, placental alkaline phosphatase or placental growth factor, modulators of hedgehog signaling, modulators of cholesterol synthesis pathway, and APC (Activated Protein C), keratinocyte growth factor, TNF, Thromboxane A2, NGF, BMP bone morphogenetic protein, CTGF (connective tissue growth factor), wound healing chemokines, decorin, modulators of lactate induced neovascularization, cod liver oil, placental alkaline phosphatase or placental growth factor, and thymosin beta 4. In certain embodiments, one, two three, four, five or six agents useful for wound healing may be used in combination. More details can be found in U.S. Pat. No. 8,247,384, the contents of which are incorporated herein by reference.

It is to be understood that agents useful for growth factor for healing (including for example, growth factors and cytokines) above encompass all naturally occurring polymorphs (for example, polymorphs of the growth factors or cytokines). Also, functional fragments, chimeric proteins comprising one of said agents useful for wound healing or a functional fragment thereof, homologues obtained by analogous substitution of one or more amino acids of the wound healing agent, and species homologues are encompassed. It is contemplated that one or more agents useful for wound healing may be a product of recombinant DNA technology, and one or more agents useful for wound healing may be a product of transgenic technology. For example, platelet derived growth factor may be provided in the form of a recombinant PDGF or a gene therapy vector comprising a coding sequence for PDGF.

In some embodiments, the active agent is a growth factor or cytokine. A non-limiting list of growth factors and cytokines includes, but is not limited, to stem cell factor (SCF), granulocyte-colony stimulating factor (G-CSF), granulocyte-macrophage stimulating factor (GM-CSF), stromal cell-derived factor-1, steel factor, VEGF, TGFβ, platelet derived growth factor (PDGF), angiopoeitins (Ang), epidermal growth factor (EGF), bFGF, HNF, NGF, bone morphogenic protein (BMP), fibroblast growth factor (FGF), hepatocye growth factor, insulin-like growth factor (IGF-1), interleukin (IL)-3, IL-1α, IL-1β, IL-6, IL-7, IL-8, IL-11, and IL-13, colony-stimulating factors, thrombopoietin, erythropoietin, fit3-ligand, and tumor necrosis factors (TNFα and TNFβ). Other examples are described in Dijke et al., “Growth Factors for Wound Healing”, Bio/Technology, 7:793-798 (1989); Mulder G D, Haberer P A, Jeter K F, eds. Clinicians' Pocket Guide to Chronic Wound Repair. 4th ed. Springhouse, Pa.: Springhouse Corporation; 1998:85; Ziegler T. R., Pierce, G. F., and Herndon, D. N., 1997, International Symposium on Growth Factors and Wound Healing: Basic Science & Potential Clinical Applications (Boston, 1995, Serono Symposia USA), Publisher: Springer Verlag.

In some embodiments, the active agent can be selected from anti-infectives such as antibiotics and antiviral agents; chemotherapeutic agents (i.e. anticancer agents); anti-rejection agents; anti-proliferative agents; analgesics and analgesic combinations; anti-inflammatory agents; erythropoietin (EPO); interferon α and γ; interleukins; tumor necrosis factor α and β; insulin, antibiotics; adenosine; cytokines; integrins; selectins; cadherins; insulin; hormones such as steroids; cytotoxins; prodrugs; immunogens; or lipoproteins.

In some embodiments, provided stents include additives, for example, that are particularly useful as diagnostic agents. In some embodiments, diagnostic agents include gases; commercially available imaging agents used in positron emissions tomography (PET), computer assisted tomography (CAT), single photon emission computerized tomography, x-ray, fluoroscopy, and magnetic resonance imaging (MRI); and contrast agents. Examples of suitable materials for use as contrast agents in MM include gadolinium chelates, as well as iron, magnesium, manganese, copper, and chromium. Examples of materials useful for CAT and x-ray imaging include iodine-based materials.

In some embodiments, provided stents include additives, for example, radionuclides that are particularly useful as therapeutic and/or diagnostic agents. Among the radionuclides used, gamma-emitters, positron-emitters, and X-ray emitters are suitable for diagnostic and/or therapy, while beta emitters and alpha-emitters may also be used for therapy. Suitable radionuclides for forming thermally-responsive conjugates in accordance with the invention include, but are not limited to, ¹²³I, ¹²⁵I, ¹³⁰I, ¹³¹I, ¹³³I, ¹³⁵I, ⁴⁷Sc, ⁷²As, ⁷²Se, ⁹⁰Y, ⁸⁸Y, ⁹⁷Ru, ¹⁰⁰Pd, ¹⁰¹mRh, ¹¹⁹Sb, ¹²⁸Ba, ¹⁹⁷Hg, ²¹¹At, ²¹²Bi, ²¹²Ph, ¹⁰⁹Pd, ⁶⁷Ga, ⁶⁸Ga, ⁶⁷Cu, ⁷⁵Br, ⁷⁷Br, ⁹⁹mTc, ¹⁴C, ¹³N, ¹⁵O, ³²P, ³³P, and ¹⁸F. In some embodiments, a diagnostic agent may be a fluorescent, luminescent, or magnetic moiety.

Fluorescent and luminescent moieties include a variety of different organic or inorganic small molecules commonly referred to as “dyes,” “labels,” or “indicators.” Examples include fluorescein, rhodamine, acridine dyes, Alexa dyes, cyanine dyes, etc. Fluorescent and luminescent moieties may include a variety of naturally occurring proteins and derivatives thereof, e.g., genetically engineered variants. For example, fluorescent proteins include green fluorescent protein (GFP), enhanced GFP, red, blue, yellow, cyan, and sapphire fluorescent proteins, reef coral fluorescent protein, etc. Luminescent proteins include luciferase, aequorin and derivatives thereof. Numerous fluorescent and luminescent dyes and proteins are known in the art (see, e.g., U.S. Patent Application Publication No.: 2004/0067503; Valeur, B., “Molecular Fluorescence: Principles and Applications,” John Wiley and Sons, 2002; Handbook of Fluorescent Probes and Research Products, Molecular Probes, 9^{th} edition, 2002; and The Handbook A Guide to Fluorescent Probes and Labeling Technologies, Invitrogen, 10^{th} edition, available at the Invitrogen web site; both of which are incorporated herein by reference).

### Tunable Silk Inverse Opals

In some embodiments, the present disclosure provides inverse opals. In some embodiments, the present disclosure provides silk inverse opals (SIOs).

In some embodiments, silk inverse opals as provided herein are or comprise amorphous silk fibroin. In some embodiments, silk inverse opals as provided herein are or include silk fibroin characterized by a presence of β-sheet formation. In some embodiments, silk inverse opals as provided herein are or comprise degraded silk polypeptide chains.

In some embodiments, amorphous silk-based large-scale inverse opals are demonstrated. In some embodiments, the present disclosure provides large scale (i.e. centimeter length scales) inverse opals. In some embodiments, a size of an inverse opal is dependent on a size of a substrate on which it is prepared. In some embodiments, a size of an inverse opal is dependent on a size of spheres used when forming cavities within an inverse opals' structure. In some embodiments, a size of an inverse opal is dependent on a crystalline lattice of arranged spheres used to template such an inverse opal structure.

In some embodiments, silk inverse opals as provided herein include periodic nanoscale cavities. In some embodiments, periodic nanoscale cavities have an average diameter in a range of about 200 nm to about 300 nm. In some embodiments, periodic nanoscale cavities are between about a nm in diameter and over a thousand nanometers in diameter. In some embodiments, an average cavity diameter is in a range of between about 1 nm and 2000 nm. In some embodiments, submicron size or nanosized cavities have an average diameter, e.g., about 5 nm, about 10 nm, about 15 nm, about 20 nm, about 25 nm, about 30 nm, about 35 nm, about 40 nm, about 50 nm, about 60 nm, about 70 nm, about 80 nm, about 90 nm, about 100 nm, about 125 nm, about 150 nm, about 175, about 200 nm, about 225 nm, about 250 nm, about 275, about 300 nm, about 325 nm, about 350 nm, about 375, about 400 nm, about 425 nm, about 450 nm, about 475, about 500 nm, about 525 nm, about 550 nm, about 575, about 600, about 650, about 700, about 750, about 800, about 850, about 900, about 950, about 1000, about 1500, or about 2000 nm or more.

In some embodiments, silk inverse opals as provided herein include lattice constants. In some embodiments, a lattice constant A is in a range of a couple of nanometers to at least 1000 nm. In some embodiments, a lattice constant is a distance of about 5 nm, about 10 nm, about 15 nm, about 20 nm, about 25 nm, about 30 nm, about 35 nm, about 40 nm, about 45 nm, about 50 nm, about 60 nm, about 70 nm, about 80 nm, about 90 nm, about 100 nm, about 125 nm, about 150 nm, about 175, about 200 nm, about 225 nm, about 250 nm, about 275, about 300 nm, about 325 nm, about 350 nm, about 375, about 400 nm, about 425 nm, about 450 nm, about 475, about 500 nm, about 525 nm, about 550 nm, about 575, about 600, about 650, about 700, about 750, about 800, about 850, about 900, about 950, about 1000, about 1500, or about 2000 nm or more.

In some embodiments, the present disclosure provides mechanically flexible inverse opals. In some embodiments, silk inverse opal materials as provided herein are capable of a bend radius in excess of 90°.

In some embodiments, inverse opals as provided herein are biocompatible and biodegradable.

In some embodiments, the present disclosure provides inverse opals with tunable, geometrically defined structural color.

In some embodiments, structural color, stop-band, or Photonic Band Gap (“PBG”) is highly sensitive to water vapor and UV irradiation. In some embodiments, structural color is reconfigured by touchless exposure to either water vapor or UV light through inducing controllable conformational changes on nanoscale.

In some embodiments, spherical shaped cavities shrink or compress to form oblate shaped cavities following exposure. In some embodiments, such cavities display anisotropic behavior. In some embodiments, increased exposure results in an enhanced effect.

In some embodiments, when exposure includes water vapor exposure, exposure times are about less than one second to about 5 seconds. In some embodiments, exposure times are less than 1 second, less than 2 seconds, less than 3 seconds, less than 4 seconds, less than 5 seconds, less than 6 seconds, less than 7 seconds, less than 8 seconds, less than 9 seconds, or about 10 seconds or less. In some embodiments, water vapor exposure times are less than a time to cause material dissolution.

In some embodiments, when nanoscale periodic cavities in multiple layers are exposed to water vapor, a result is uniform anisotropic shrinkage of such nanoscale periodic cavities.

In some embodiments, when exposure includes exposure to ultra violet radiation, exposure times are about 15 minutes to 5 hours. In some embodiments, exposure times are less than 15 minutes, less than 30 minutes, less than 45 minutes, less than 1 hour, less than 1.5 hours, less than 2 hours, less than 2.5 hours, less than 3 hours, less than 3.5 hours, less than 4 hours, less than 4.5 hours, less than 5 hours, less than 5.5 hours, less than 6 hours, less than 7 hours, less than 8 hours, less than 9 hours, less than 10 hours, or more.

In some embodiments, when nanoscale periodic cavities in multiple layers are exposed to ultra violet radiation, a result is non-uniform anisotropic shrinkage of such nanoscale periodic cavities.

In some embodiments, when nanoscale periodic cavities in multiple layers are exposed to water vapor, a result is uniform anisotropic shrinkage of such nanoscale periodic cavities.

In some embodiments, multicolored photonic macro- or micro-patterns are shown by selectively applying water vapor or UV irradiation through a stencil or shadow mask.

In some embodiments, theoretical simulations are paired with experimental results of spectral responses of SIOs. Based on this, sub-mm, multispectral patterns are defined.

In some embodiments, tuning of colorimetric responses is demonstrated by filling an SIO structure with liquids. In some embodiments, liquids for filling have different molecular sizes.

In some embodiments, silk inverse opals as provided herein are have controllable geometries. In some embodiments, geometry is controlled by silk conformational changes. In some embodiments, geometry is controlled by microscale patterning. In some embodiments, geometry is controlled by macroscale patterning using a stencil. In some embodiments, geometry is controlled by macroscale patterning through colloidal assembly. In some embodiments, geometry is controlled by reconfiguring silk inverse opals. In some embodiments, index of refraction is altered.

In some embodiments, structural color changes are exhibited in a range from the UV to the IR portion of the spectrum.

### Methods of Making Silk Inverse Opals

In some embodiments, large scale SIOs were fabricated by using polystyrene (PS) colloidal photonic crystal multilayers as template. In some embodiments, fabrication procedures resemble those shown in FIG. 1 at panel B.

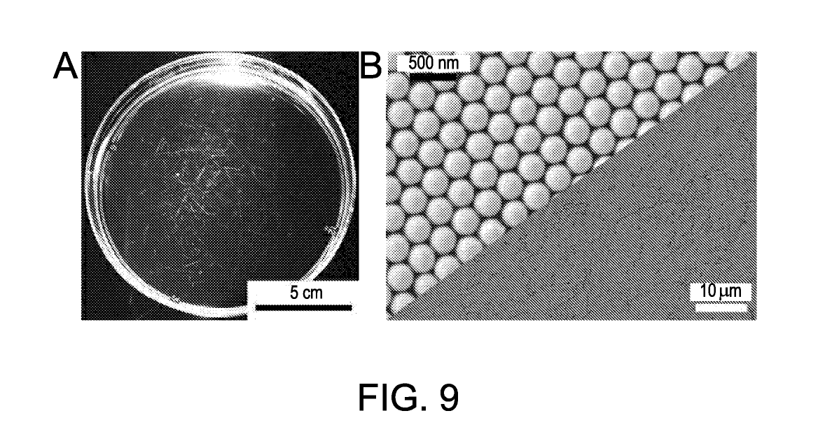

In some embodiments, PS spheres with diameters of 210 and 300 nm self-assembled and formed large scale crystalline monolayers (around 85 cm²) at a water/air interface, for example after they were introduced to water surface as shown in FIG. 9 at panel A. In some embodiments, an ordered monolayer was scooped and transferred from a water surface to a hydrophilic substrate to form a crack-free and close-packed PS sphere monolayer array over a large area, for example as shown in FIG. 9 at panel B.

Based on this, in some embodiments, large scale colloidal crystal multilayers with controllable number of layers were prepared by layer-by-layer (LbL) scooping transfer of a floating monolayer at a water/air interface.

In some embodiments, an LbL transfer method as used herein allows formation of large-scale, defect-free colloidal crystal multilayers. (See Oh et al., 21 J. Mater. Chem., 14167 (2011)). In some embodiments, favorable material characteristics of silk fibroin, including robust mechanical properties and nanoscale processability, guarantee complete replication of a template structure and formation of high-quality inverse opals.

In some embodiments, silk solution extracted from B. mori silkworm cocoons was then cast into a PS template and allowed to solidify into an amorphous silk film.

In some embodiments, a silk inverse opal structure was obtained by immersing such a silk film into toluene to remove templated PS spheres.

In some embodiments, a size of SIO film is determined by a size of PS colloidal crystal template, which depends on substrate dimensions which are used to introduce PS sphere suspension to a water surface and a water container. In some embodiments, for example, larger SIOs (such as those described herein) were easily realized by using larger transferring substrates and water containers.

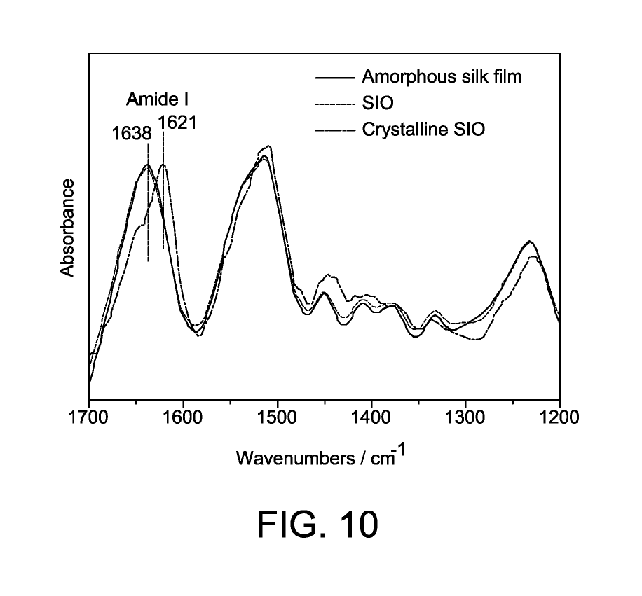

In some embodiments, secondary structure of SIO films was investigated by means of attenuated total reflectance Fourier-transform infrared spectroscopy (ATR-FTIR). As shown in FIG. 10, an FTIR spectrum of an SIO film was indicative of an amorphous silk film with an absorption peak in amide I band centered at 1638 cm⁻¹, indicating a presence of water in a film and typical random coil conformation of an amorphous protein. (See Kim et al., 9 Nat. Nanotech., 306 (2014). Additionally, the FTIR spectrum of SIO film also confirms that templated PS spheres are all removed and there is no residual toluene in resultant films.

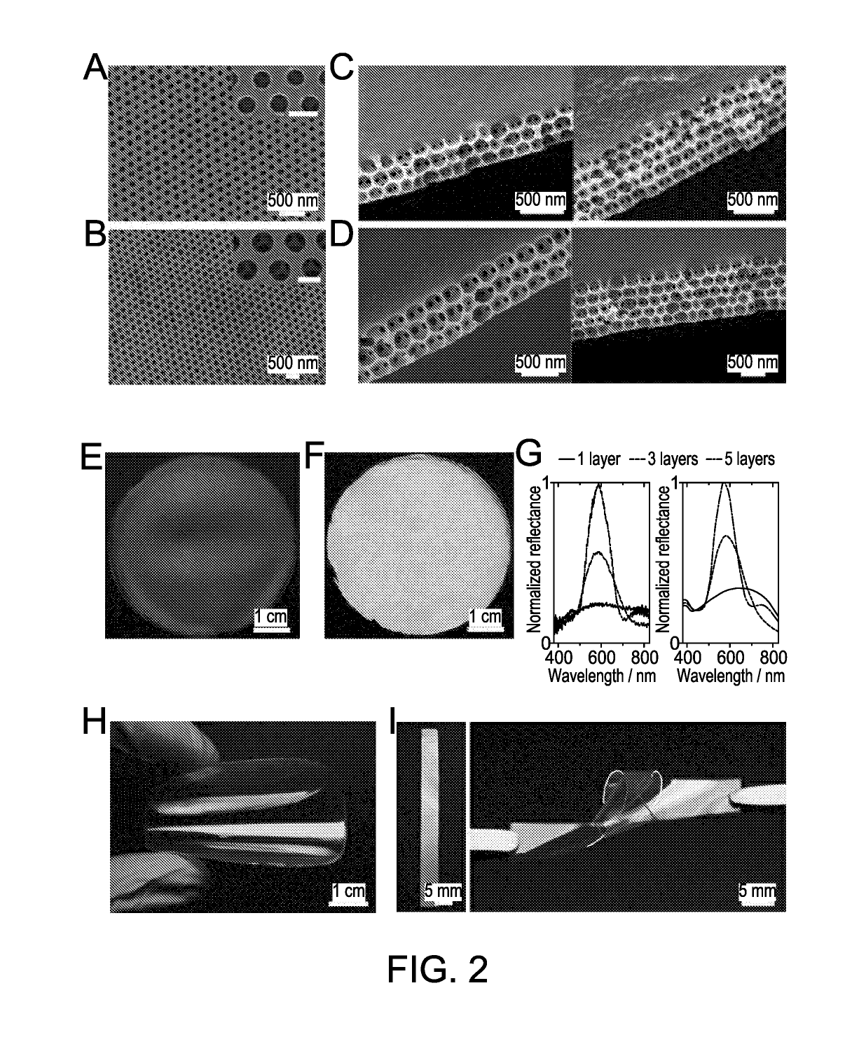

In some embodiments, large scale SIOs, such as those present here form a close-packed face-centered-cubic (fcc) lattice. Nanostructures of large scale SIOs are shown in FIG. 2 at panel A-FIG. 2 at panel D. Scanning electron microscopy (SEM) images of a surface of SIOs show highly ordered hexagonal arrays of air cavities (where PS spheres were originally located) over a large area, which is a (111) plane of an fcc. Lattice constant (A), defined as a center-to-center distance of air cavities, is the same as each diameter of PS sphere used, i.e. Λ=210 nm and Λ=300 nm, respectively.

FIG. 2 at panel A and FIG. 2 at panel B, the inserts display a triangular lattice holes underneath top air cavities, which are resultant of former contacts between spheres. Cross-sectional images of SIOs, either composed of three or five sphere layers (see FIG. 2 at panel C and FIG. 2 at panel D), also show ordered hollow silk fibroin structure with air holes on a wall. All SIOs considered here are three sphere layers if not otherwise indicated.

In some embodiments, due to diffraction of incident light induced by ordering nanostructure of SIO, structural colors could be observed. In some embodiments, distinct structural colors were obtained by using PS spheres with different diameters to adjust lattice constants of SIOs.

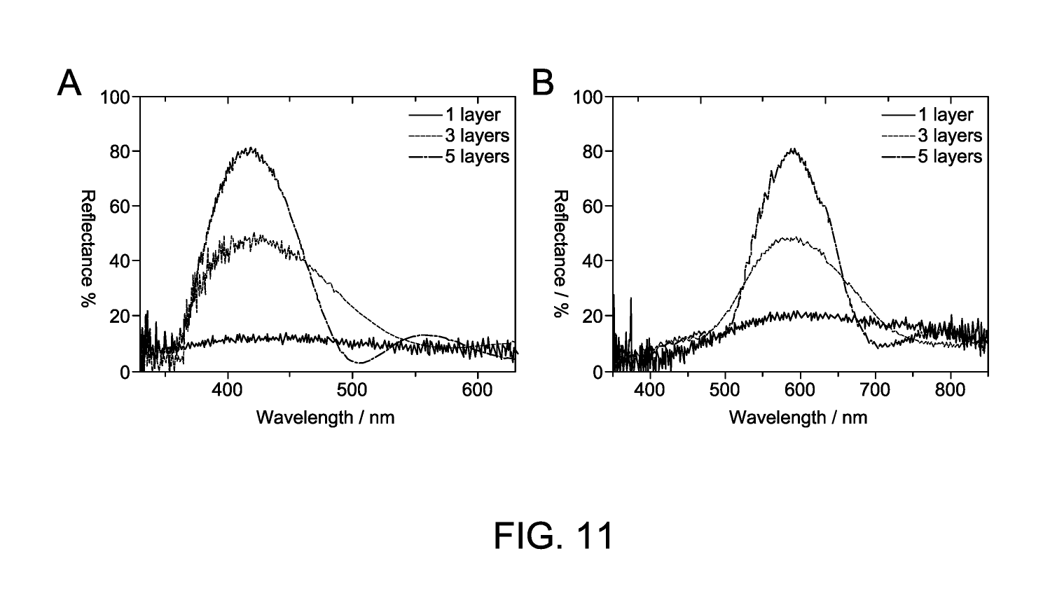

As shown in FIG. 2 at panel E and FIG. 2 at panel F, large scale (˜5.2 cm in diameter), high quality SIO films with blue-violet and yellow structural colors were prepared by using PS with diameters of 210 and 300 nm, respectively. Reflectance spectra taken at normal incidence show that peaks are centered at Λ=420 nm and Λ=590 nm for blue-violet as shown in FIG. 11 at panel A and yellow SIO (FIG. 2 at panel G and FIG. 11 at panel B), respectively. Absolute reflectance spectra as shown in FIG. 11 displays intensity of reflectance of five-layer SIO reach above 80%, indicating high reflectivity of SIO. In a finite system, these high reflectance regions (known as stop-bands) are reminiscent of PBGs that would characterize an ideally infinite 3D periodic structure. Thus, as can be observed in FIG. 2 at panel G or FIG. 11, SIOs with different number of layers but same period display the same peak central wavelength. Yet, as expected reflectance within a stop-band increases with a number of layers, while a width of a stop-band, which is due to a finite size of a sample in a vertical direction, decreases. These results are confirmed by an r, such that a wavelength of structural color is tunable with exposure time (RCWA) calculations shown in FIG. 2 at panel G, which are in agreement with experimental curves.

In some embodiments, resulting freestanding silk opals exhibit outstanding mechanical properties and are flexible. SIOs provided herein were easily bent as shown in FIG. 2 at panel H with bending angles larger than 90° or knotted as shown in FIG. 2 at panel I, and no macroscopic crack on its nanostructured surface and no structural color change were observed after repeated bending for more than 100 times or after knotting.

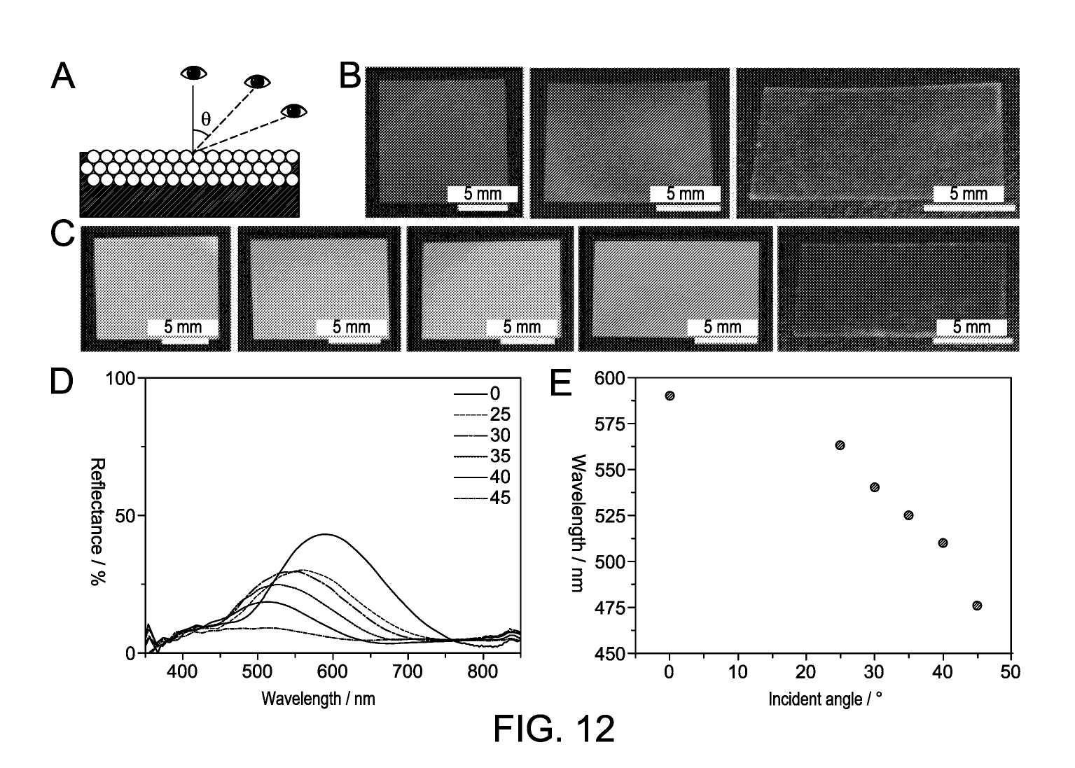

In some embodiments, during bending or knotting, SIO films show different structural colors because of angular dependence of a PBG. A detailed analysis of angular dependence of color of SIO films is shown in FIG. 12.

In some embodiments, methods provided herein has added utility, lending itself to inkjet printing approaches. In some embodiments, methods of preparing include inkjet printing to fabricate SIO patterns.

In some embodiments, silk solutions were printed onto PS colloidal crystal multilayers using previously demonstrated approaches to prepare SIO patterns. In some embodiments however, after removing PS spheres, structural color emerges. In some embodiments, inhomogeneous color of SIO patterns may be caused by uneven surface of printed silk thin layers.

In some embodiments, method of fabrication of inverse opals as provided herein are biocompatible and biodegradable.

### Methods of Tuning SIOs

While an ability to fabricate large-scale biomaterial-based inverse opals is remarkable, in some embodiments a capacity to reconfigure inverse opals by inducing structural changes in a protein matrix provides unusual photonic versatility to these articles.

In some embodiments, methods of preparation of large scale, macro defect free, and highly flexible silk inverse opal (SIO) with controllable layers are provided herein.

In some embodiments, methods include locally tuning a photonic stop-band. In some embodiments, reconfiguration is affected by water vapor exposure or by ultra violet radiation exposure.

In some embodiments, the present disclosure provides methods of generating high-resolution multicolor patterns with high reflectivity and controllability through a simple patterning procedures. In some embodiments, multispectral photonic macro- or micro-patterns are demonstrated by selectively applying water vapor or UV irradiation through a shadow mask.

In some embodiments, water vapor exposure and UV light exposure used are non-contacting patterning methods. In some embodiments, shadow masks are used to create different patterns. In some embodiments, close contact between a stencil and a sample is helpful to make high quality patterns.

### Water Exposure

In some embodiments, water and/or moisture affects structural properties of silk. In some embodiments, interaction between silk proteins and water molecules leads either to beta-sheet formation when a film is exposed to water vapor or can cause material dissolution under certain conditions (i.e. an amorphous, alpha-helix dominated silk structure) if immersed in water.

In some embodiments, an ability to controllably affect silk structure is used, such as here, to tune a nanoscale lattice of a SIO. In some embodiments, when SIOs are exposed to water vapor. In some embodiments, when SIOs are exposed to water vapor, their structural color is gradually blue-shifted with an increase of water vapor treating time. A color shift is shown to occur in a few seconds.

In some embodiments, exposing provided silk inverse opals to water vapor includes exposing for about less than one second to about 5 seconds. In some embodiments, exposure times are less than 1 second, less than 2 seconds, less than 3 seconds, less than 4 seconds, less than 5 seconds, less than 6 seconds, less than 7 seconds, less than 8 seconds, less than 9 seconds, or about 10 seconds or less. In some embodiments, water vapor exposure times are less than a time to cause material dissolution.

In some embodiments, by using a stencil to selectively expose different regions of a sample to water vapor for different amounts of time, it is possible to controllably pattern a SIO. (See FIG. 1 at panel B(vii)).

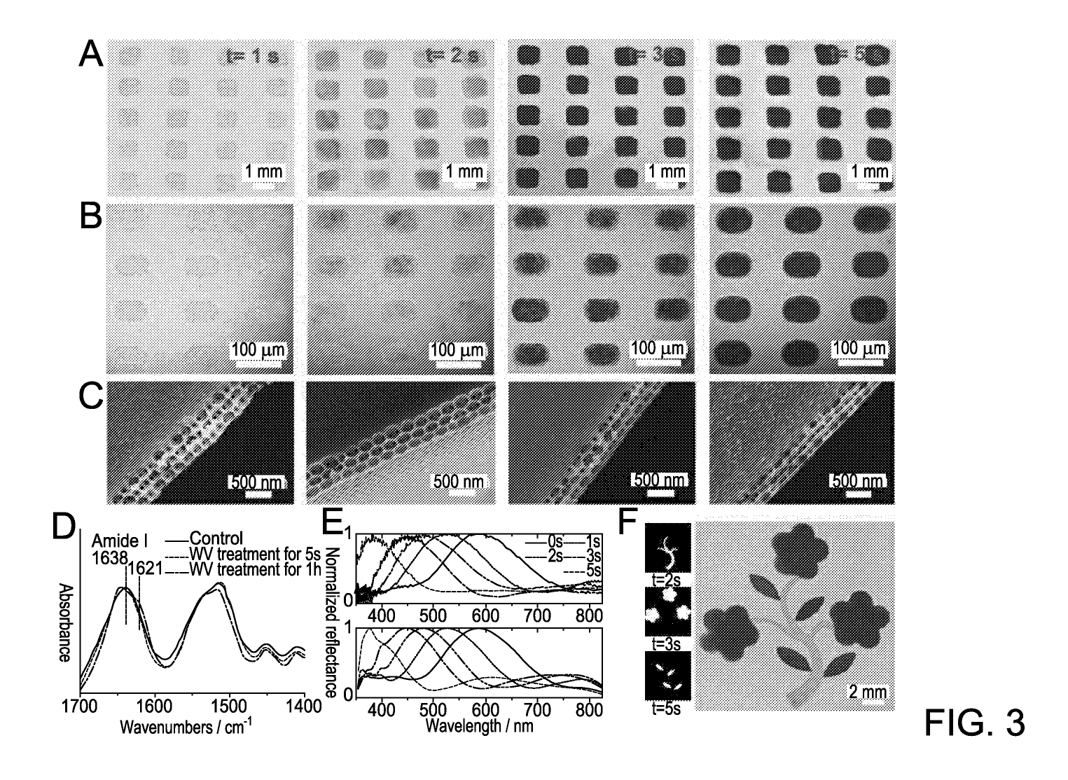

Controllable patterning is illustrated in FIG. 3 at panel A and FIG. 3 at panel B, where macro- and micro-patterns with green, light blue, blue and violet colors were generated by exposing SIOs with initial lattice constants Λ=300 nm to water vapor (generated by heated water at 40° C.) for 1, 2, 3 and 5 s, respectively. In some embodiments, a size of such patterns is tunable from macro to micro scale depending on stencil dimensions.

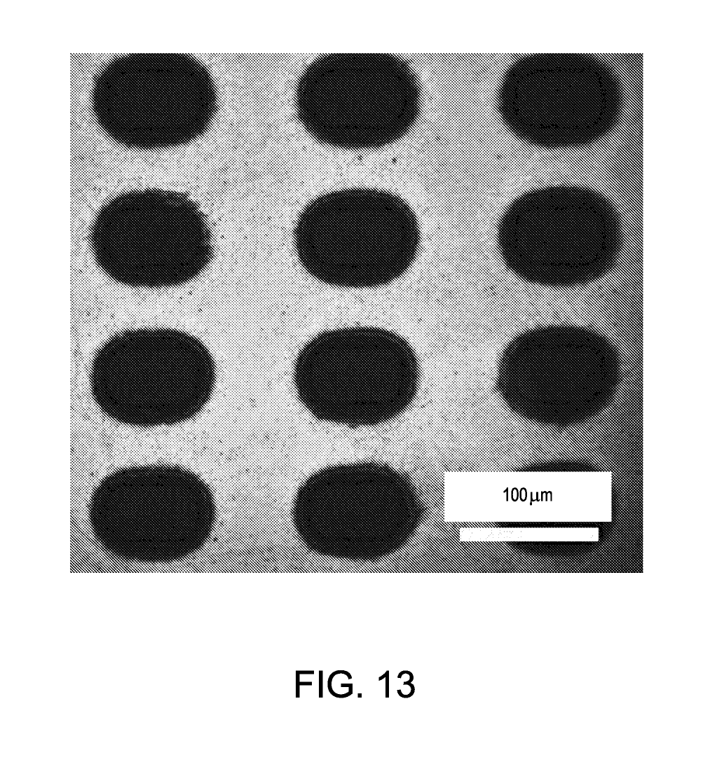

In some embodiments, longer treating times ultimately collapse a structure eliminating structural color as shown in FIG. 13.

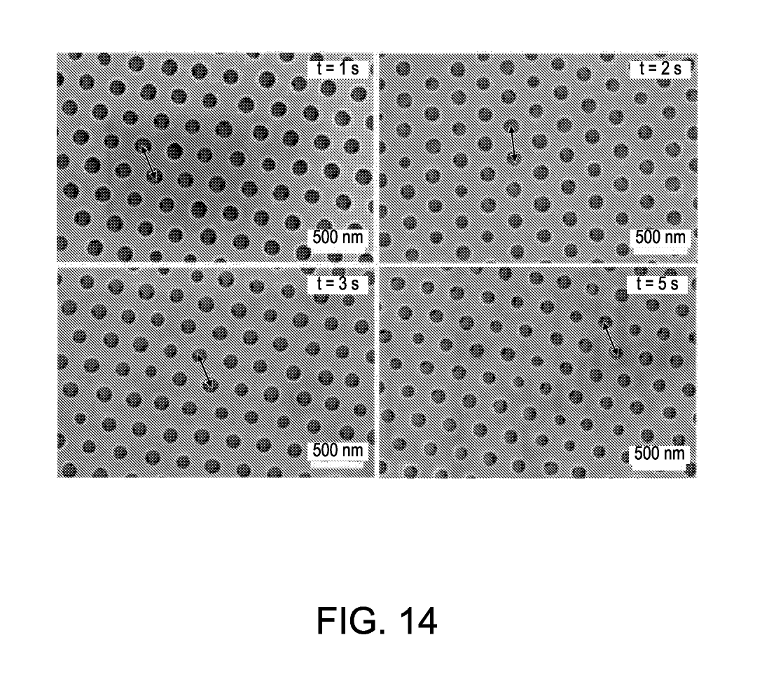

In some embodiments, close contact between a stencil and a sample results in high quality patterns. In some embodiments, cross sectional images of water vapor treated SIOs show that a lattice is gradually compressed along a vertical direction of a SIO film ([111] direction) during water vapor treatment. As shown in FIG. 3 at panel C, air cavities are deformed from initial spherical shape to oblate shape with an increase of water vapor treating time. This transformation is almost consistent for all the three layers, which gives a uniform inter plane distance along the vertical direction. Besides, surface SEM images of SIOs indicate that there is hardly any lateral shrinkage of lattice as shown in FIG. 14.

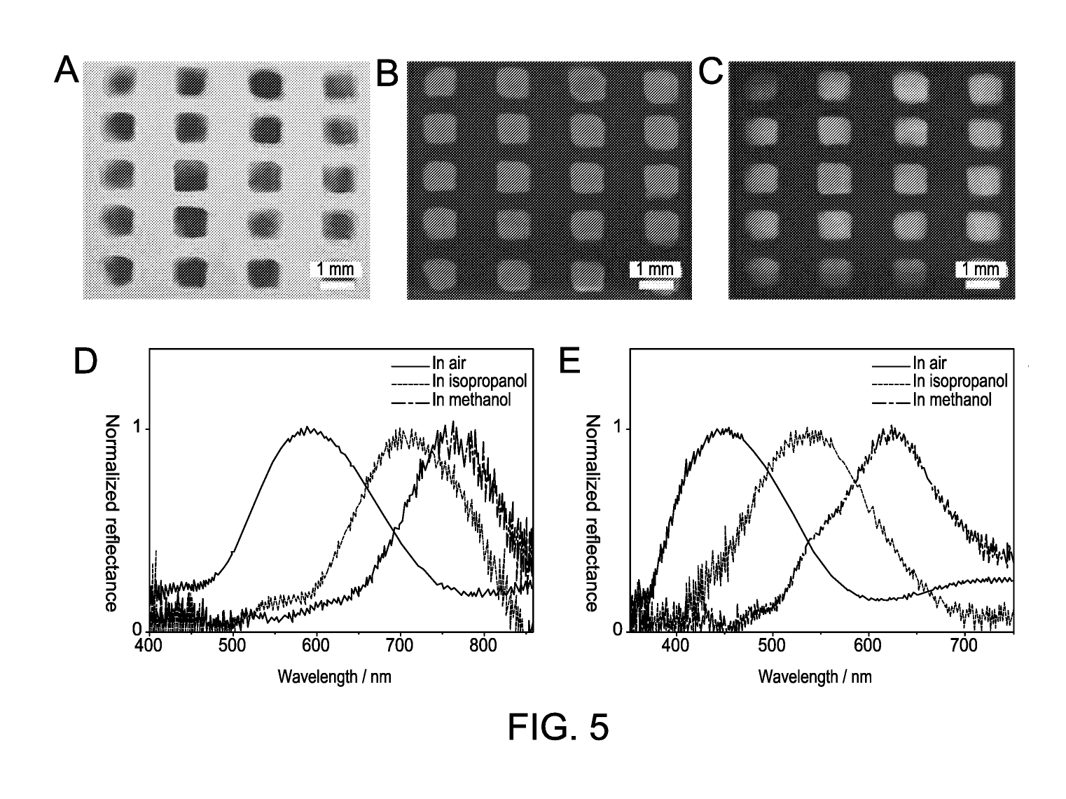

In some embodiments, behavior of water vapor induced shrinkage of SIOs can be understood by interaction between water molecules and polar groups of silk fibroin chains that result in conformational change from random coil to ft-sheet structure. (See Hu et al., 12 Biomacromolecules, 1686 (2011). It is believed that water molecules infiltrate a silk matrix over a course of treatment and soften silk fibroin chains. (See Fu et al., 42 Macromolecules, 7877 (2009)). Since, in this case, in contrast to previous approaches, (see Kim et al., 6 Nat. Photonics, 817 (2012)), SIO film is mainly composed of amorphous protein with random coil structure as shown in FIG. 5, molecular chains are free to rearrange during conformational change induced by water vapor, leading to a change of free volume of silk matrix and thus compression of a lattice in a weak vertical direction due to restrictions on lateral shrinkage imposed by a bottom thick silk substrate, as reported previously. (See Phillips et al., 26 Chem. Mater., 1622 (2014)).

In some embodiments, provided structural change or reconfiguration is irreversible because rearranged molecular chains are partially fixed by crosslinked crystalline domains and thus effectively locks in photonic crystal lattice. It should be noted that there is no detectable secondary structure change after transient water vapor treatment due to the limited sensitivity of FTIR. However, observable conformational transition (from random coil to β-sheet) happens after water vapor treatment for 1 h as shown in FIG. 3 at panel D. We also found crystalline SIO films induced by methanol treatment before remove PS spheres is less sensitive to water vapor, which is mainly because crystalline domains (ft-sheet nanocrystals, as shown in FIG. 10) restrict shrinkage of SIO due to their water insolubility. (See Wang et al., 14 Biomacromolecules, 3936 (2013)). It should be noted that humidity content in SIO during quick water vapor treatment is not high enough to cause swelling of silk matrix. (See Diao et al., 23 Adv. Funct. Mater., 5373 (2013).

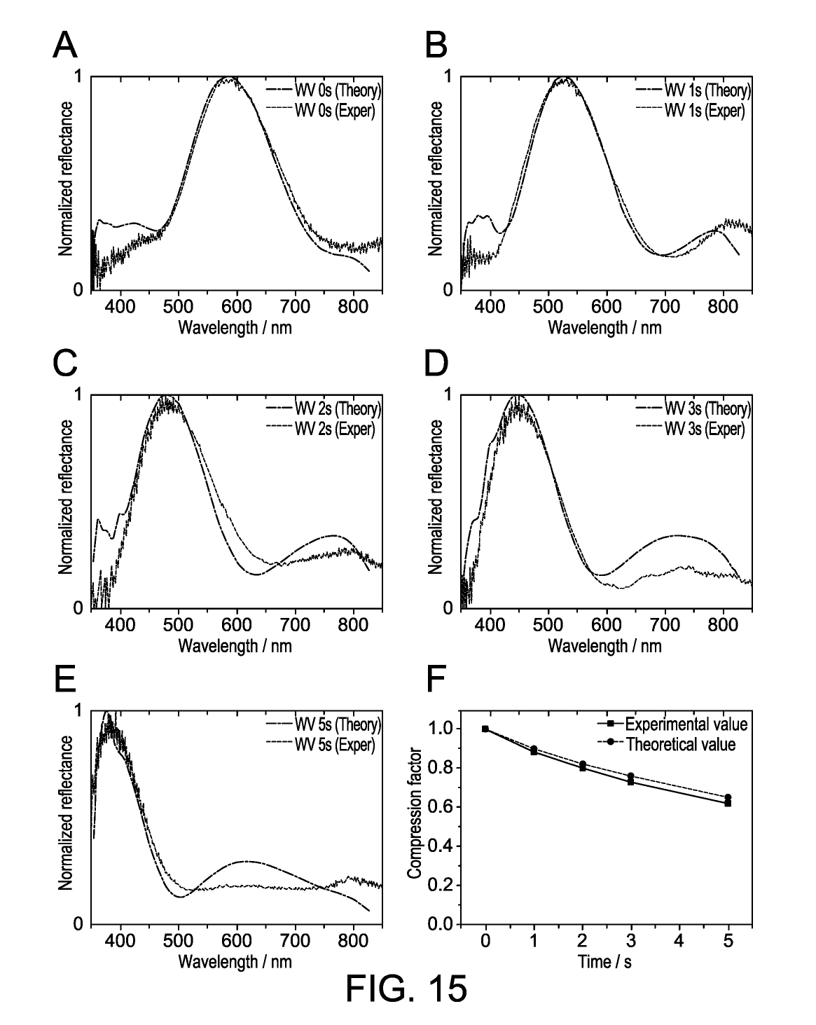

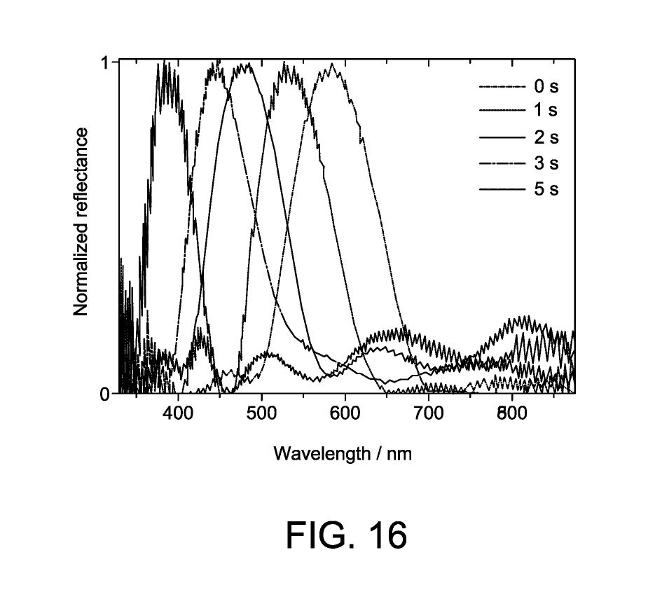

In some embodiments, anisotropic shrinkage of SIO gives rise to a blue-shift of a stop-band, as shown in FIG. 3 at panel E. Stop-band varies from 530, 485, 450 to 385 nm when treating time increases from 1, 2, 3 to 5 s. Reflectance spectra of water vapor treated SIOs are in agreement with our RCWA results (see FIG. 3 at panel E or see also FIG. 15 at panel A—FIG. 15 at panel E), which have been obtained by including a uniform compression factor (CF) in a theoretical model. Estimated CFs for different exposure time match those obtained from SEM images as shown in FIG. 15 at panel F. It should be mentioned that a same shift of a stop-band can be obtained for SIOs with a larger number of layers, as shown in FIG. 16 for five-layer SIOs.

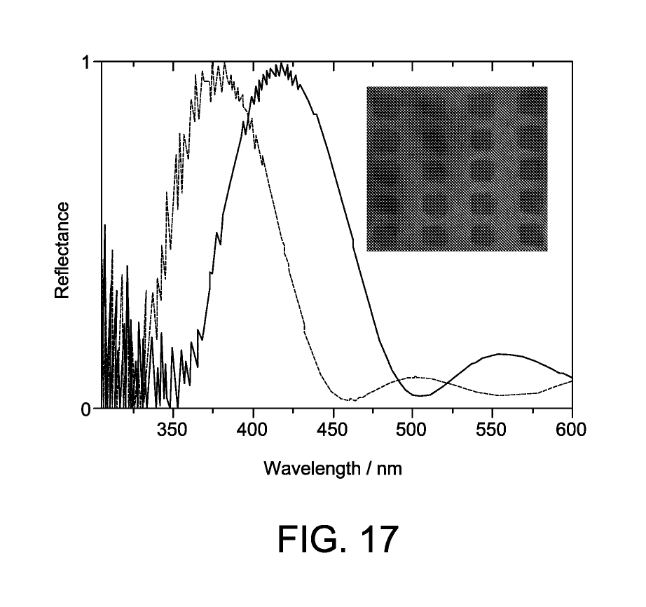

In some embodiments, macroscale multicolor patterning was realized by selectively exposing part of SIO to water vapor for different times. As a demonstration, a pattern of flower with light blue Λ=485 nm branches, blue Λ=450 nm petals, and violet Λ=385 nm leaves was formed using three different stencils, as shown in FIG. 3 at panel F. In fact, multiple multicolor patterns can be prepared using this method. SIO with a Λ=210 nm also shows blue-shift of stop-band after water vapor treatment as shown in FIG. 17, with associated color changes from blue-violet Λ=420 nm to violet Λ=380 nm.

In some embodiments, for water vapor treatment, lateral diffusion of water vapor within an inverse opal will limit resolution, especially for long time treatment. In some embodiments, quick response of SIO to water vapor (seconds) however provides a possibility to get high resolution patterns.

### UV Exposure

In some embodiments, silk structure in SIOs is also affected by exposure to ultraviolet radiation. In some embodiments, defining structural color in SIOs makes use of silk structure modification induced by exposure to ultraviolet radiation (UV).

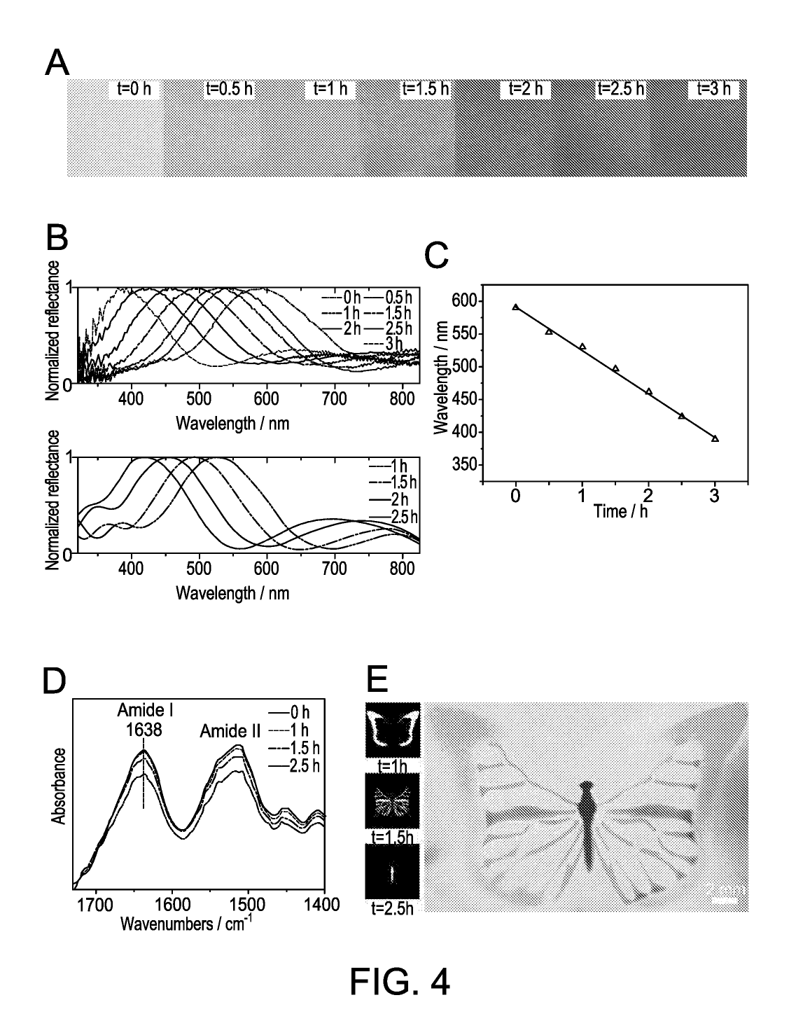

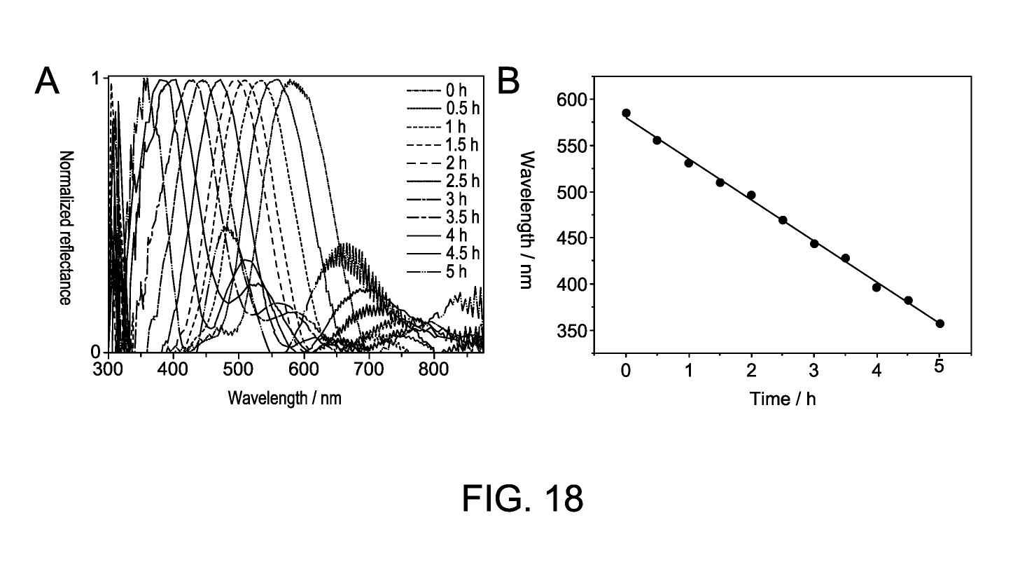

FIG. 4 at panel A and FIG. 4 at panel B show blue-shift of structural color and a corresponding normalized reflectance spectra for a SIO with Λ=300 nm as a function of UV irradiation time. Corresponding reflectance spectra further confirm this change. By plotting a relationship diagram between center wavelength of bandgap and UV irradiation time, a center wavelength is almost linearly blue-shifted with increasing irradiation time, that is a central wavelength is observed and its stop-band decreases linearly with an irradiation time, as shown in FIG. 4 at panel C. This rather simple calibration curve allows for precise control of SIO color. Five-layer SIOs show a similar blue-shift behavior as shown in FIG. 18.

To reveal an origin of UV induced bandgap (or color) shift, we observed and compared morphology of SIO before and after UV exposure.

In some embodiments, exposing provided silk inverse opals to ultra violet radiation, exposure times are about 15 minutes to 5 hours. In some embodiments, exposure times are less than 15 minutes, less than 30 minutes, less than 45 minutes, less than 1 hour, less than 1.5 hours, less than 2 hours, less than 2.5 hours, less than 3 hours, less than 3.5 hours, less than 4 hours, less than 4.5 hours, less than 5 hours, less than 5.5 hours, less than 6 hours, less than 7 hours, less than 8 hours, less than 9 hours, less than 10 hours, or more. In some embodiments, ultra violet exposure times are less than a time to cause photodegradation of silk fibroin.

Cross-sectional SEM images show that a lattice is gradually compressed along a [111] direction with increasing irradiation time as shown in FIG. 4 at panel D, similarly to a case of water vapor treated SIOs. However, in this case, air cavities of different layers do not shrink uniformly, especially for a bottom layer contacted with a silk substrate, which is less compressed than its top two layers. In some embodiments, this seems to indicate that structure modification is mainly associated with UV absorption, which is more likely to happen in layers of SIO closer to an irradiation source. In some embodiments, a first layer is exposed to UV light directly, and a second layer may be irradiated due to an existence of holes on top of a first layer while underlying layers are screened from UV irradiation.

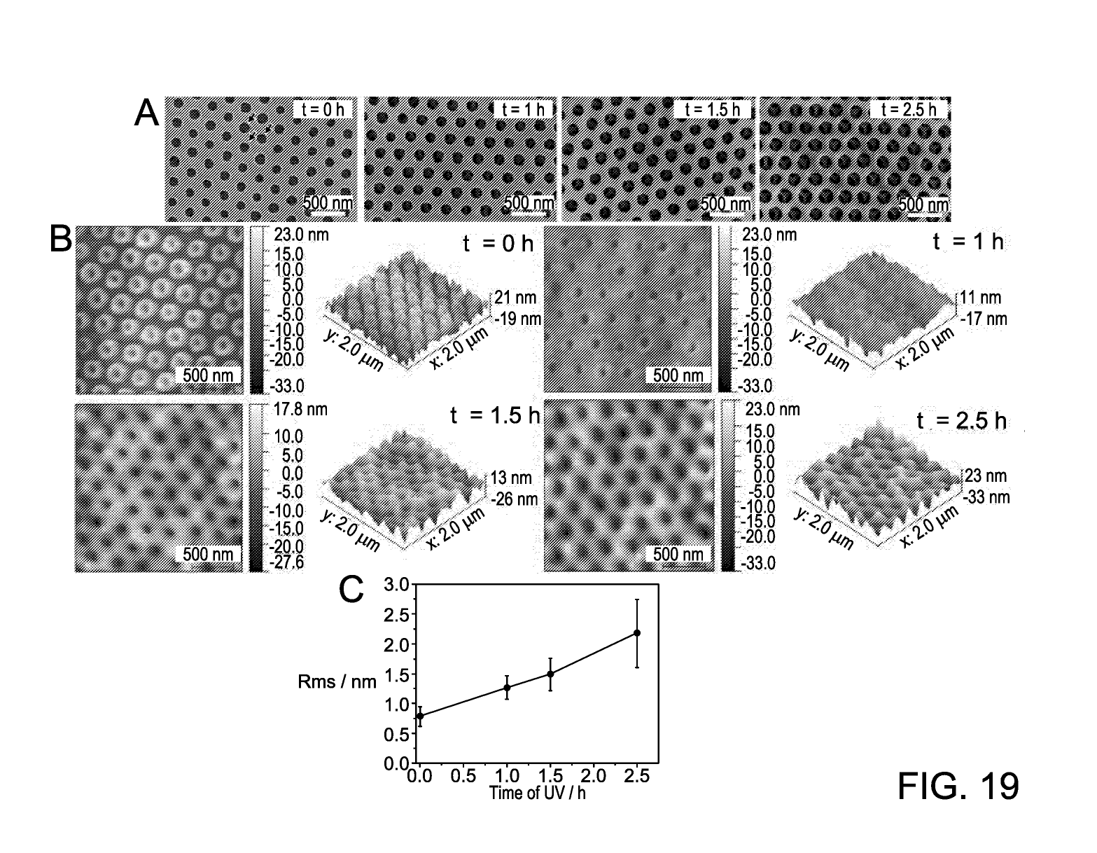

We observe that, since SIO period is about 200-300 nm, propagation and absorption of UV light in SIO may be also controlled by a proper choice of opal cell length and UV wavelength. Surface SEM images as shown in FIG. 19 at panel A display that for a first SIO layer an average diameter of air cavities increases from 142, 160, 179 to 202 nm as irradiation time increases from 0, 1, 1.5 to 2.5 h, while lattice constant remains nearly unchanged. It is observed that small protrusions around cavities (indicated by arrows) gradually fade away with increase of irradiation time (etched by UV) due to photodegradation of the silk fibroin. To further evaluate an effect of UV radiation on the nanoscale, atomic force microscopy (AFM) measurements were taken to evaluate surface roughness as a function of UV exposure. As shown in FIG. 19 at panel B, the AFM images confirm surface morphology changes observed from SEM images and show that surface roughness increases with an increase of irradiation time as shown in FIG. 19 at panel C.

In some embodiments, no color change was observed either when an SIO film was heated on a hot plate with temperature similar to that generated by a UV lamp during exposure or when an unpatterned surface of a SIO was exposed to UV directly, excluding an influence of temperature on structural color change of SIO.

As above provided, in some embodiments UV light with wavelength lower than 280 nm has been shown to be able to induce peptide chain scission and photodegradation of silk fibroin initially at weaker C—N bonds, and further lead to molecular rearrangement of silk fibroin.

FTIR results show that UV irradiation causes a slight decrease of absorption peaks in FTIR spectrum as shown in FIG. 4 at panel E, which is consistent with previous reported results. (See Sionkowska et al. 96 Polym. Degrad. Stab., 523 (2011)). Based on these facts, we believe molecular rearrangement with peptide scission as shown in FIG. 1 at panel A could account for a morphology change of SIOs, and its associated stop-band tuning.

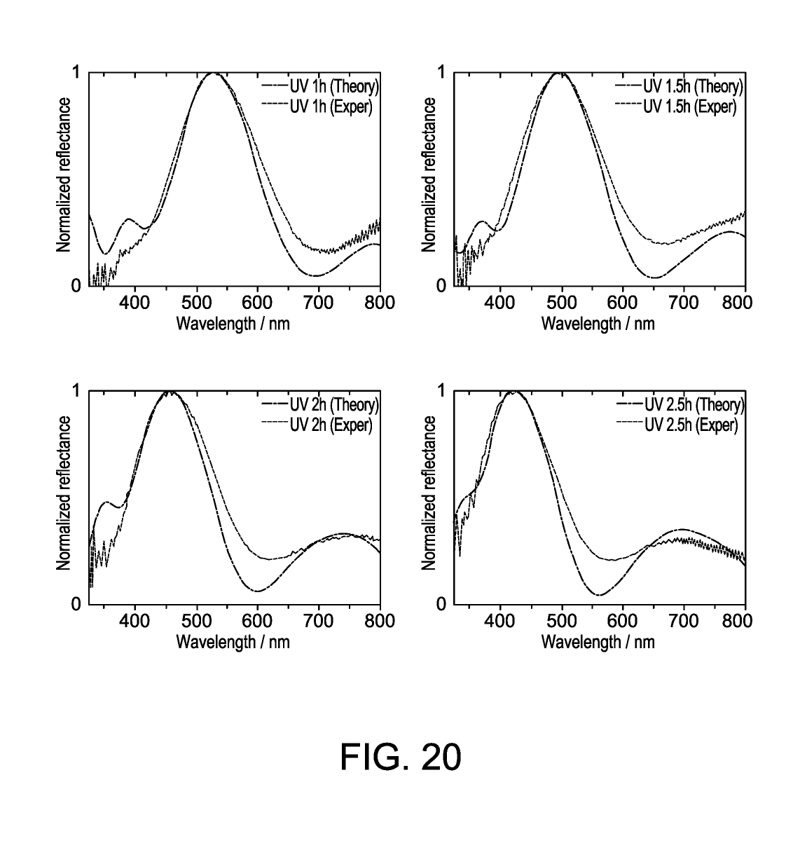

It should be notice that only by considering different CFs for each SIO layer in our theoretical model (Table 2), calculated reflectance spectra agree with experimental curves as shown in FIG. 4 at panel B or see FIG. 20. This suggests that anisotropic shrinkage of SIO is indeed a primary reason for a change of structural color of SIO. As in water vapor exposure, dependence of stop-band position on UV exposition time enables local control of SIO structural color as shown in FIG. 1 at panel B(vii). As a demonstration, we generated a butterfly pattern with green Λ=535 nm wing periphery, light blue Λ=495 nm wing veins, and blue-violet Λ=420 nm trunk by exposing each image part to UV for different time, as shown in FIG. 4 at panel F.

TABLE 2
Parameters used for reflectance spectral simulation of SIOs after UV
irradiation. Parameters were measured from cross-sectional SEM
images of SIOs after UV irradiation.

| | Layer 1 | | Layer 2 | | Layer 3 | |
|---|---|---|---|---|---|---|
| Time | CF | h (nm) | CF | h (nm) | CF | h (nm) |
| 1 h | 0.85 | 256.7 | 0.94 | 283.88 | 0.94 | 283.88 |
| 1.5 h | 0.81 | 244.62 | 0.86 | 259.72 | 0.90 | 271.8 |
| 2 h | 0.72 | 217.44 | 0.81 | 244.62 | 0.90 | 271.8 |
| 2.5 h | 0.68 | 205.36 | 0.72 | 217.44 | 0.90 | 271.8 |

In some embodiments, UV exposure resolution is theoretically limited by a radiation wavelength used to process an SIO and diffraction by a mask. In some embodiments, in practice UV dose is another limiting factor, where lower doses are associated with higher resolution.

In some embodiments, a thickness of an SIO will also affect pattern quality. In some embodiments, thinner is better because longer water vapor or UV expose time is needed to get the same effect for thicker sample, which will more or less reduce resolution.

### Varying Refractive Index

In some embodiments, properties of a PhC can be tuned not only by changing its morphology, but also by varying refractive index of constituent materials. In some embodiments, it is simple for a SIO, as it can be infiltrated. (See Kim et al., 6 Nat. Photonics, 817 (2012)). To demonstrate this concept, patterned SIO by water vapor was exposed to isopropanol (n≈1.38) and methanol (n≈1.33), which have a sufficiently low surface tension to allow for penetration of a liquid into a structure.

In both cases, we have a significant increase of refractive index in opal voids, resulting in a red-shift of stop-bands (for both a region exposed and unexposed to water vapor). Results are presented in FIG. 5. For a SIO Λ=300 nm having initially a yellow/blue color pattern, pictures as well as the reflectance spectra show a clear structural color change as shown in FIG. 5 at panel A—FIG. 5 at panel C corresponding to the stop-band red-shift as shown in FIG. 5 at panel D and FIG. 5 at panel E when the SIO is immersed in isopropanol or methanol.

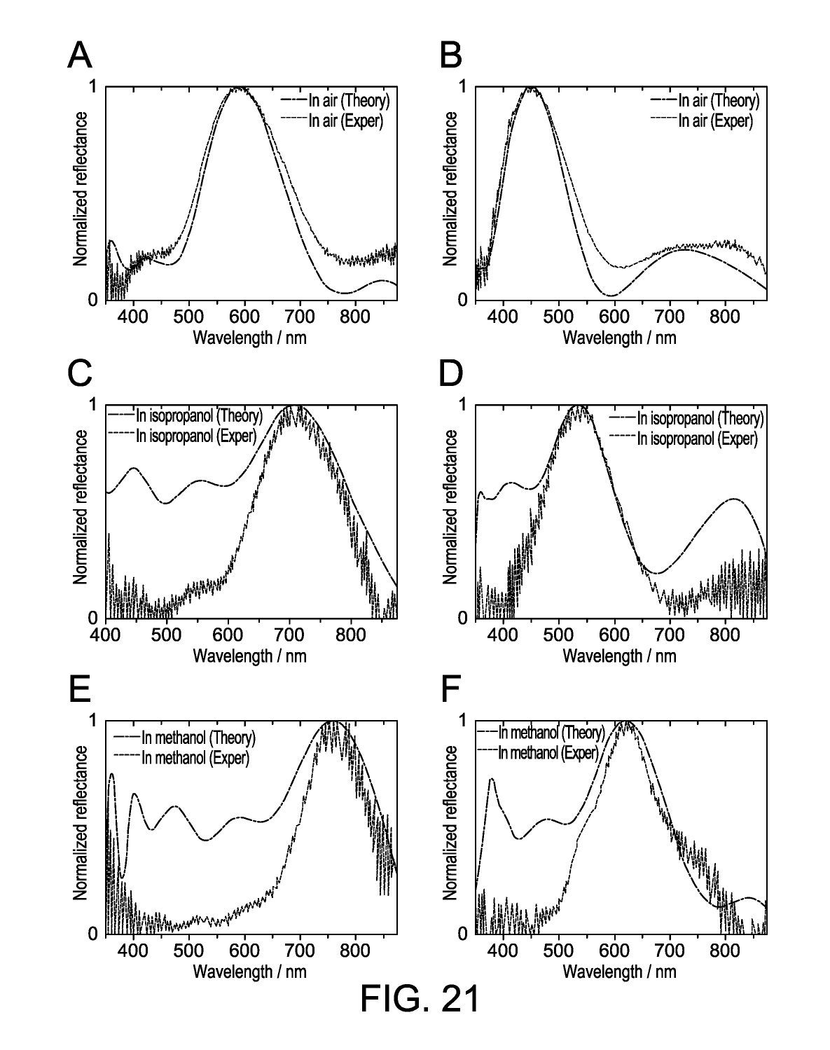

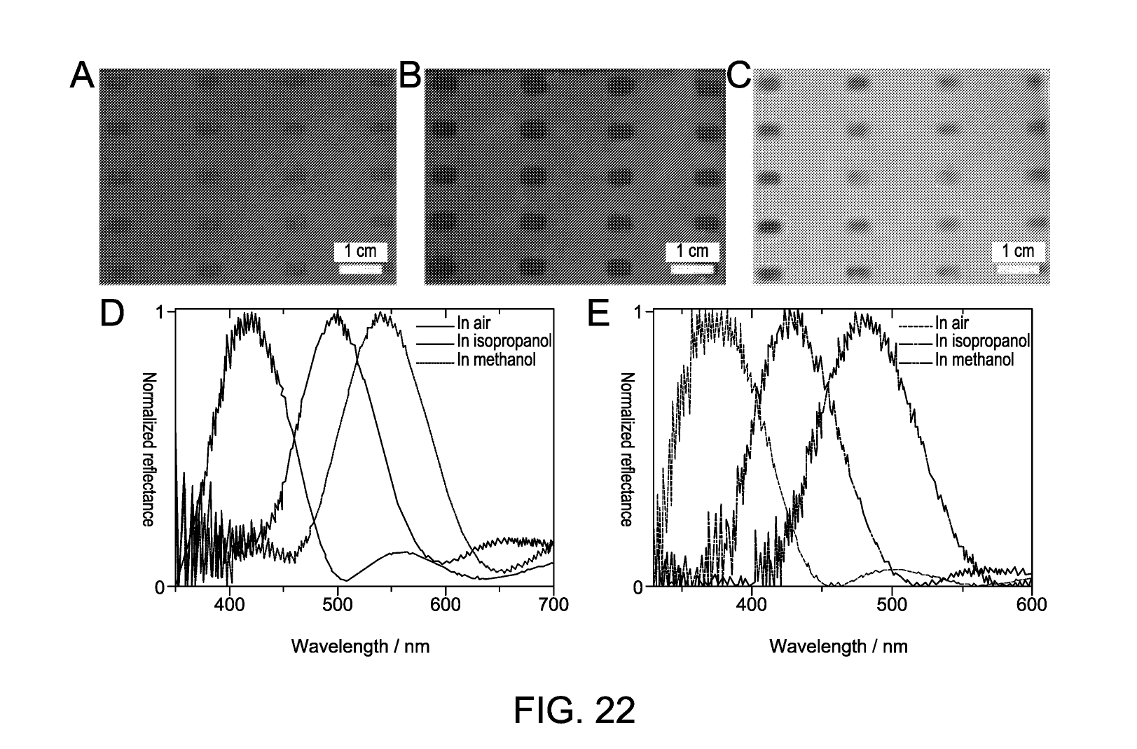

However, structural color of both native and water vapor treated SIOs in methanol are surprisingly more red-shifted than those in isopropanol. This suggests that silk might undergo different swelling in isopropanol and methanol. We believe that, since isopropanol hardly penetrates silk matrix due to its large molecular size, in the former case the red-shift is caused solely by air cavities filling. This is further confirmed by theoretical calculations for both untreated and water vapor exposed SIOs as shown in FIG. 21. On the contrary, methanol can easily insinuate itself into a silk matrix because its molecular size matches a free volume of silk. (See Wang et al., 14 Biomacromolecules, 3936 (2013)). In this case, SIO can swell, yielding a further stop-band red-shift. By theoretically analyzing this extra shift, we estimate a 10.2% volume expansion for both untreated and water vapor exposed SIOs. Water vapor patterned SIO with Λ=210 nm shows similar red-shift behavior in isopropanol and methanol as shown in FIG. 22.

In summary, we have demonstrated preparation of cm length scale, and highly ordered silk inverse opals by a facile colloidal crystal templating method. SIO films show vivid iridescent colors and are highly flexible due to robust mechanical properties of silk. An ability to controllably alter silk's conformation allows modulating photonic lattice and defining structural colors by touchless water vapor and UV light exposure. We show that this spectral change is due to a controllable anisotropic shrinkage of SIO, which allows tuning stop-band almost over an entire visible range. This anisotropic shrinkage can be locally controlled by using masks to generate multi-spectral patterns with sub-mm features. Stop-band position in multispectral SIOs can be red-shifted by infiltrating structure with liquids. In particular, we found that substances with smaller molecular size can induce swelling of silk matrix and thus a larger stop-band shift. Precise spectral response and spatial controllability of structural color of large scale SIO, combined with silk versatility, (see Omenetto et al., 329 Science, 528 (2010); see also Tao et al., 24 Adv. Mater., 2824 (2012) are promising new avenues for photonic applications of increased utility for sensing, transduction, and spectral modulation in a versatile biopolymer format adding a layer of control over spectral responses and light localization in biopolymer-based photonic structures. Rapid and irreversible response to water vapor of SIOs can optically detect and record surrounding humidity, potentially serving as colorimetric probes for environmentally controlled areas, such as food storage spaces, which cannot be achieved by using reversible humidity sensors. An ability to have ‘petri-dish’ sized programmable, biocompatible nanopatterns could enable an interesting direction in cell-binding experiments where 3D geometries of different sizes can be designed to study cellular adhesion interface. (See Tseng et al., 2 ACS Omega, 470 (2017)).

The advantages of our patterning procedures presented here are: (i) stop-band adjustment of SIOs is dominated by conformational change of silk fibroin; (ii) SIOs are directly, and non-contact patterned without intermediate steps resulting in remarkably large defect-free areas, in contrast with previously reported methods that require contact, pressure, and are consequently subject to resolution limitations (see Lee et al., 26 Adv. Funct. Mater., 4587 (2016) and Cho et al., 25 Adv. Funct. Mater., 6041 (2015)) (iii) water-based patterning allows interfacing easily with biological environments; and (iv) when using UV instead of water, a very low radiation dose is used to pattern SIOs (hundreds of times lower than previous reports, (see for example Lee et al., 26 Adv. Funct. Mater., 4587 (2016)). In addition, there is a key distinction between the case presented here, where an amorphous starting conformation allows for lattice programmability, and the previously reported silk inverse opal, (see Kim et al., 6 Nat. Photonics, 817 (2012) where a silk matrix is physically cross-linked and, as such, could not be altered after formation (if not through harsh modifications).

### EXEMPLIFICATION

The following examples illustrate some embodiments and aspects of the invention. It will be apparent to those skilled in the relevant art that various modifications, additions, substitutions, and the like can be performed without altering the spirit or scope of the invention, and such modifications and variations are encompassed within the scope of the invention as defined in the claims which follow. The following examples do not in any way limit the invention.

### Example 1

### Silk Fibroin Solution Preparation

Silk fibroin was extracted from the silk cocoons of the Bombyx mori silkworm with a process previously described. (See Rockwood et al., 6 Nat. Protoc., 1612 (2011)). Briefly, cocoons were cut in small pieces and boiled for 30 min in a 0.02 M Na₂CO₃ water solution to remove the hydrophilic sericin layer. After rinsing with distilled water and then drying in a chemical hood for 2 days, the silk fibers were dissolved in a 9.3 M LiBr solution at 60° C. for 4 hours, followed by dialysis against distilled water using a dialysis tube (Fisherbrand, MWCO 3.5K) for 3 days to obtain a 7 wt %-8 wt % silk fibroin solution in water.

### Example 2

### SIO Preparation

The SIO was prepared by using large-scale close-packed PS sphere (modified by carboxylic acid group on the surface, Interfacial Dynamics Co.) arrays as template. A diluted suspension of 4% aqueous PS sphere suspension was prepared in a mixture with an equal volume of ethanol. A few drops of the suspension were introduced to the water surface in a large container using the partially immersed Si wafer, which was pretreated by an O₂ plasma treatment to realize a hydrophilic surface. To help the direct crystallization process, a few drops of sodium hydroxide solution and sodium dodecyl sulfate (SD S) were added to the water phase before introducing PS spheres to adjust the surface tension of water. After introducing, the spheres immersed into the subphase were removed and a few drops of SDS were added again, thus large-scale close-packed monolayer array was formed on the water surface. A hydrophilic substrate (O₂ plasma treated PS wafer) was immersed into the subphase and elevated under a shallow angle to transfer the monolayer from the water surface to the substrate (scooping transfer). After drying, multilayers colloidal crystals could be obtained by repeating these procedures. It should be mentioned that the colloids which have been transferred to the substrate remain close-packed while the substrate is being re-submerged into the water container to transfer another layer and the PS monolayer on the water surface keeps unchanged during this insertion. The silk solution was added to the colloidal crystals to fill the air voids after immersing the template in water for a few minutes to remove SDS. The sample was set to dry for 24 h (25° C., 30% relative humidity) to form a free-standing silk/PS composite film with the thickness of 50 μm. The PS spheres within the composite film were removed by immersing the film into toluene for 24 h.

### Example 3

### Water Vapor Treatment

For water vapor treatment, the SIOs were put on top of the heated water surface (about 40° C.) with the nanostructured surface of SIO directly exposed to water vapor over a controlled time. The distance between sample and water surface was set as 5 mm. Stencils with various designs and sizes were applied on the surface of SIO film to leave desired pattern on the SIO after mask removal. It should be mentioned that the sensitivity of SIO to water vapor increases with the increase of water temperature if the distance between sample and water surface is constant since higher temperatures increase the permeation of water molecules into silk films.

### Example 4

### UV Irradiation

UV irradiation was carried out by using VL-215.G UV germicidal lamps with a wavelength of 254 nm and intensity of 76 μW cm⁻². The distance between sample and UV lamp was about 1 cm. Shadow masks with designed shapes were used to prepare UV patterned SIOs.

### Example 5

### Inkjet Printing of Silk Inks:

Dimatix Materials Printer DMP 2831 (from FUJIFILM), which is based on piezoelectric inkjet technology, was used for silk inks printing. The silk inks used here were 120 min boiled silk solution with the concentration of 3 wt %. The printing process was performed at room temperature using 5 nozzles (diameter 21 μm) with 20 μm spacing, ˜27 V firing voltage with standoff height of 0.5 mm, and a custom waveform to ensure optimal droplet formation. 3 layers of silk solution were deposited on 5 layers PS colloidal crystals on a glass slide with 20 seconds interlayer delay.

### Example 6

### Measurement

### SEM:

SEM was used to analyze the surface and cross sectional morphology of SIO films. To observe the cross sectional structure, the samples were cleaved via cryofracture. All samples were sputtered with a 5 nm thick layer of gold using an EMS 300T D Dual Head Sputter Coater before being observed under a Zeiss Supra55VP at 5 kV. Image analysis software (ImageJ) was used to determine the cross-sectional thickness of SIOs.

### Reflectance Spectra:

All reflectance spectra were recorded using a fiber-optic spectrometer (USB-2000, Ocean Optics). The distance between sample and the fiber tip was fixed at 1 mm. The reference signal was collected using an aluminum mirror (reflectance: 100%).

### FTIR:

ATR-FTIR spectroscopy of SIOs and flat silk film was performed with a Jasco FTIR-6200 Spectrometer, equipped with a multiple reflection, horizontal MIRacle™ attachment (Ge crystal, from Pike Tech., Madison, Wis.). All the FTIR spectra were acquired in the range of 4000-600 cm⁻¹ at 4 cm⁻¹ resolution with an average of 64 scans.

### AFM:

AFM was used to investigate the change of surface morphology and surface roughness of SIOs. AFM images of the SIO films were acquired with a Cypher AFM (Asylum Research) in tapping mode using an Arrow UHF silicon probe (BRUKER, MPP-21120-10). To calculate the surface roughness, five 500 nm-long areas on images were sampled.

### Example 7

### Theoretical Method

All the theoretical simulations described in this article were carried out using rigorous coupled-wave analysis (RCWA), and more specifically a scattering-matrix FORTRAN code developed at the University of Pavia. The implementation of the RCWA is analogous to that presented in the seminal article by Whittaker and Culshaw, (see Whittaker et al., 60 Phys. Rev. B, 2610 (1999)) to which the reader is addressed for further information. This method is suitable for multilayered structures with in-plane periodicity: Maxwell's equations are solved in the plane using Fourier-modal expansion, and interface and scattering matrices (SM), after which the method was named, are then employed to relate the amplitudes of incoming and outgoing—or “scattered”—waves on each side of the layer under scrutiny, which enforces the appropriate boundary conditions. This procedure can be applied to patterned multilayered structures (see Balestreri et al., 74 Phys. Rev. E, 036603 (2006)) and enables the calculation of their reflectance and transmission spectra. The RCWA requires the layers to be homogeneous along the stacking direction and each layer to have the same reciprocal lattice; the original implementation was then improved by Liscidini et al. (see Liscidini et al., 77 Phys. Rev. B, 035324 (2008) by considering also systems with asymmetric unit cells and composed of birefringent materials.

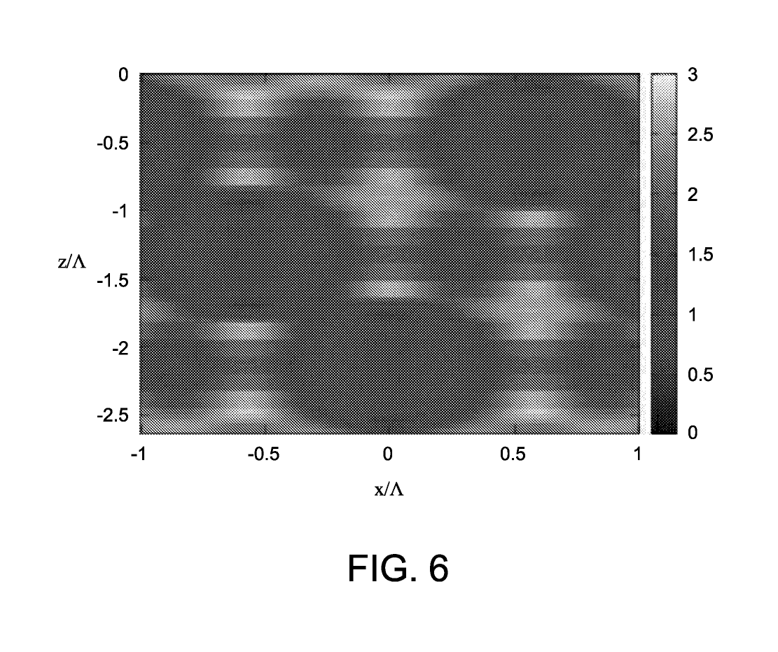

A direct opal is a face-centered cubic stacking of dielectric spheres, and inverse opals are a direct opal of air voids in a denser matrix. Along the [111] direction of the fcc stacking, the distance between the spheres is smaller than the diameter, since spherical caps originating from adjacent layers overlap; thus, each layer of spheres can be divided into two overlapping regions and one non-overlapping region as shown in FIG. 6. The planar lattice in non-overlapping regions is a triangular lattice of circular sections, whereas the lattice in overlapping regions is a honeycomb lattice; this lattice mismatch essentially introduces a phase factor due to the lattice shift, and the presence of a basis, as in the honeycomb lattice, does not change the reciprocal lattice. In addition to this, a stacking of spheres is clearly not a homogeneous system, but the homogeneity required by the scattering-matrix procedure can be recovered by subdividing the sphere in a series of concentric cylinders (see Balestreri et al., 74 Phys. Rev. E, 036603 (2006) each overlapping region was divided in 5 cylinders, as it was checked that a finer subdivision yielded essentially the same spectra. The RCWA requires expanding the solutions of Maxwell equation on a basis of NPW plane waves. The finite number of plane waves leads to an approximated result, whose accuracy depends on NPW. We performed various tests and found that for this system convergence is obtained for NPW=13.

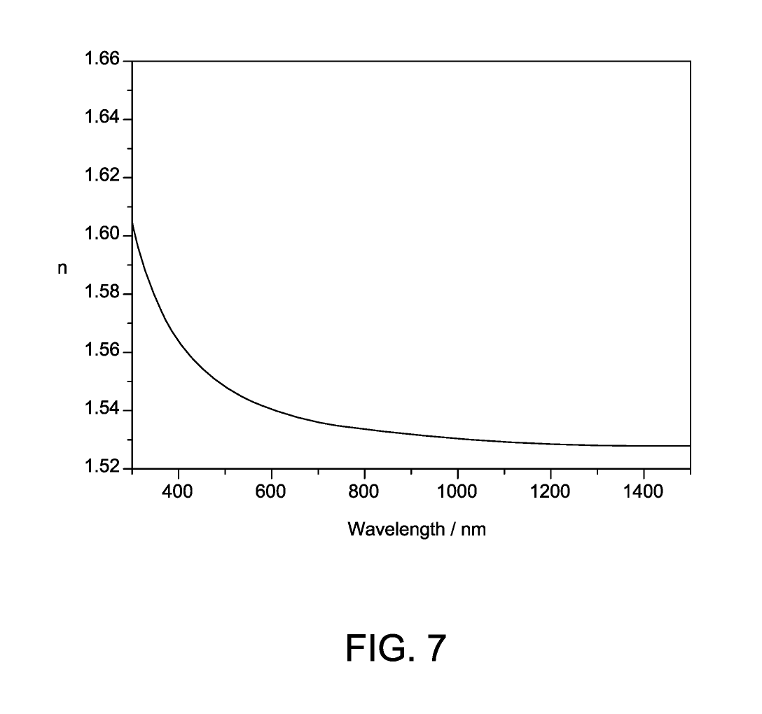

The nominal cell length of the air voids in our SIOs was Λ=300 nm; this was increased to Λ=302 nm in the simulations in order to improve the alignment of the experimental and theoretical curves. Chromatic dispersion of the refractive index of silk was taken into account as shown in FIG. 7.

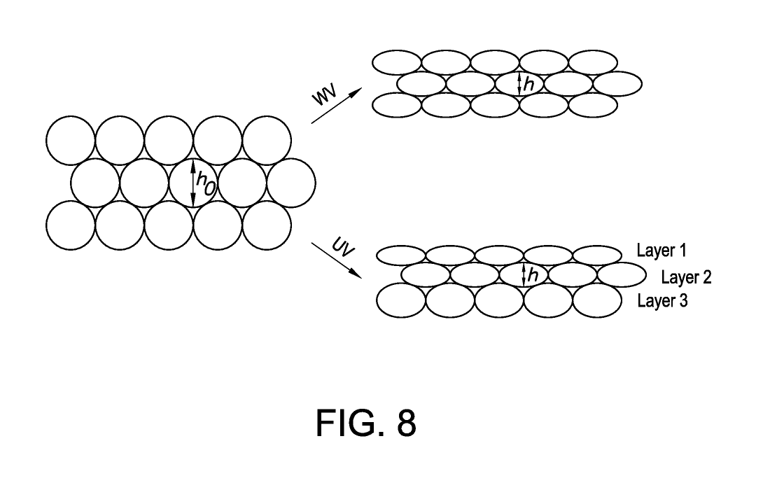

The water-vapor scenario was modeled by means of a uniform compression of the opal structure along the [111] direction, with no horizontal compensation as shown in FIG. 8. The SIO was considered to be on a 50 μm silk substrate. Finally, all the theoretical curves were smoothed by the convolution with a Gaussian with standard deviation σ=0.05, which takes into account for the sample slight inhomogeneity over measurement area. The CF is the only fit parameter, and the theoretic values are in substantial agreement with the SEM images of the samples.

For the UV scenario, the model considered different CFs for each SIO layer as shown in FIG. 8. The values were extrapolated from the SEM images.

The infiltration of the SIO with isopropanol (η˜1.38) or methanol (η˜1.33) was simulated by increasing the refractive index of the air voids and allowing for an additional swelling of the silk matrix in the case of methanol. In order to model the water vapor patterned SIO, a uniform compression for each layer of the structure in the [111] direction was assumed.

Other embodiments are within the scope and spirit of the invention. Features implementing functions may also be physically located at various positions, including being distributed such that portions of functions are implemented at different physical locations.

Further, while the description above refers to the invention, the description may include more than one invention.

References cited in the present disclosure are all hereby incorporated by reference in their entirety for all purposes herein.

### Other Embodiments and Equivalents

While the present disclosure has explicitly discussed certain particular embodiments and examples of the present disclosure, those skilled in the art will appreciate that the invention is not intended to be limited to such embodiments or examples. On the contrary, the present disclosure encompasses various alternatives, modifications, and equivalents of such particular embodiments and/or example, as will be appreciated by those of skill in the art.

Accordingly, for example, methods and diagrams of should not be read as limited to a particular described order or arrangement of steps or elements unless explicitly stated or clearly required from context (e.g., otherwise inoperable). Furthermore, different features of particular elements that may be exemplified in different embodiments may be combined with one another in some embodiments.

What is claimed is:

1. An article of manufacture, comprising:
a silk inverse opal that exhibits structural color when it is exposed to incident electromagnetic radiation;
the silk inverse opal, comprising nanoscale periodic cavities characterized by their lattice constants,
wherein a lattice constant for at least some of the nanoscale periodic cavities is smaller in one dimension of its unit cell following exposure to water vapor or ultra violet radiation; and
wherein the exhibited structural color of the silk inverse opal is blue shifted following the exposure.

2. The article of manufacture of claim 1, wherein the nanoscale periodic cavities have a spherical shape.

3. The article of manufacture of any of the preceding claims, wherein the spherical nanoscale periodic cavities have substantially a same diameter.

4. The article of manufacture of any of the preceding claims, wherein the silk inverse opal has an average lattice constant in a range of between about 100 nm and about 600 nm.

5. The article of manufacture of any of the preceding claims, wherein the silk inverse opal has a face-centered cubic structure.

6. The article of manufacture of any of the preceding claims, wherein silk inverse opal exhibits vertical anisotropic shrinkage in the (111) plane of the face-centered cubic structure.

7. The article of manufacture of any of the preceding claims, wherein at least one dimension of the article is greater than a centimeter.

8. The article of manufacture of any of the preceding claims, wherein the article is characterized in that when a mechanical stress is applied at its edges, the silk inverse opal exhibits a bend radius of at least 90°.

9. The article of manufacture of any of the preceding claims, wherein the silk inverse opal comprises a pattern defined by nanoscale periodic cavities exhibiting anisotropic behavior.

10. The article of manufacture of any of the preceding claims, wherein the silk inverse opal comprises multiple layers of nanoscale periodic cavities.

11. The article of manufacture of any of the preceding claims, wherein the silk is or comprises amorphous silk fibroin.

12. The article of manufacture of any of the preceding claims, wherein the silk is or comprises silk fibroin characterized by a presence of β-sheet formation.

13. The article of manufacture of any of the preceding claims, wherein the silk is or comprises degraded silk polypeptide chain.

14. The article of manufacture of any of the preceding claims, wherein no residual toluene is present in the articles.

15. The article of manufacture of any of the preceding claims, wherein the silk inverse opal exhibits no change in its structural color after repeated bending or knotting of the article.

16. The article of manufacture of any of the preceding claims, wherein the silk inverse opal exhibits no macroscopic cracking after repeated bending or knotting of the article.

17. The article of manufacture of any of the preceding claims, wherein spherical nanoscale periodic cavities are oblate following exposure.

18. The article of manufacture of any of the preceding claims, wherein spherical nanoscale periodic cavities are uniformly anisotropic across layers following exposure.

19. The article of manufacture of any of the preceding claims, wherein spherical nanoscale periodic cavities are non-uniformly anisotropic across layers following exposure.

20. The article of manufacture of any of the preceding claims, wherein spherical nanoscale periodic cavities are uniformly anisotropic across layers following water vapor exposure.

21. The article of manufacture of any of the preceding claims, wherein spherical nanoscale periodic cavities are non-uniformly anisotropic across layers following exposure to ultra violet radiation.

22. The article of manufacture of any of the preceding claims, wherein a lattice constant for at least some of the nanoscale periodic cavities of a (111) silk inverse opal is smaller in a vertical direction following exposure to water vapor or ultra violet radiation.

23. The article of manufacture of any of the preceding claims, wherein following the exposure the silk is crosslinked and irreversible.

24. The article of manufacture of any of the preceding claims, wherein an extent of a change in lattice constant is tunable with exposure time.

25. The article of manufacture of any of the preceding claims, wherein an extent of a change in lattice constant is tunable with water vapor exposure time.

26. The article of manufacture of any of the preceding claims, wherein an extent of a change in lattice constant is tunable with ultra violet radiation exposure time.

27. The article of manufacture of any of the preceding claims, further comprising a liquid.

28. The article of manufacture of any of the preceding claims, further comprising a liquid filling the nanoscale periodic cavities.

29. The article of manufacture of any of the preceding claims, wherein when the liquid fills the nanoscale periodic cavities, it changes an index of refraction of the article.

30. The article of manufacture of any of the preceding claims, wherein when the liquid fills the nanoscale periodic cavities, the structural color of the silk inverse opal red-shifts.

31. A method of forming the article of manufacture of claim 1, comprising steps of:
preparing a silk fibroin solution;
inducing a plurality of spherical units to self-assemble into a lattice having at least one layer;
applying the silk fibroin solution to the lattice such that the silk fibroin solution fills voids between the plurality spherical units;
drying the silk fibroin solution into a silk film;
removing the plurality of spherical units;
exposing the article to water vapor or ultra violet radiation.

32. The method of claim 31, further comprising: prior to the exposing step, a step of placing a stencil over the silk film.

33. The method of any of the preceding claims, wherein the stencil comprises a pattern.

34. The method of any of the preceding claims, wherein the exposing step is or comprises water vapor exposure for a period.

35. The method of any of the preceding claims, wherein the exposing step is or comprises ultra violet radiation exposure for a period.

36. The method of any of the preceding claims, wherein the step of exposing the article to water vapor comprises exposing for a time between about 1 second and about 10 seconds.

37. The method of any of the preceding claims, wherein the step of exposing the article to ultra violet radiation comprises exposing for a time between about 1 second and about 5 hours.

38. The method of any of the preceding claims, wherein when exposed to water vapor for increasingly longer exposure times, the structural color of the silk inverse opal is gradually blue shifted with the longer times, such that a wavelength of the structural color is tunable with exposure time.

39. The method of any of the preceding claims, wherein when exposed to ultra violet radiation for increasingly longer exposure times, the structural color of the silk inverse opal is gradually blue shifted with the longer times, such that a wavelength of the structural color is tunable with exposure time.

40. The method of any of the preceding claims, wherein modeling with rigorous coupled-wave analysis (RCWA) predicts a wavelength of the structural color for an exposure time for a silk inverse opal.

41. The method of any of the preceding claims, further comprising adding a liquid to the article following the step of exposing.

42. The method of any of the preceding claims, wherein a liquid added following the step of exposing red-shifts the article's structural color wavelength.

43. The method of any of the preceding claims, further comprising a step of tuning an extent of the red-shift of the article's structural color wavelength by adding a liquid with a different molecular size.

44. The method of any of the preceding claims, wherein a larger molecular size liquid red-shifts the article's structural color wavelength less than a smaller molecular size liquid.

45. The method of any of the preceding claims, wherein the plurality of spherical units are polystyrene spheres.

46. The method of any of the preceding claims, wherein the step of inducing comprises inducing one layer, three layers, or five layers.
